(19) United States
(12) Patent Application Publication
(10) Pub. No.: US 2024/0369616 A1
(43) Pub. Date: Nov. 7, 2024

(54) AUTOMATED TEST EQUIPMENT, DEVICE UNDER TEST, TEST SETUP METHODS USING A TRIGGER LINE

(71) Applicant: Advantest Corporation, Tokyo (JP)

(72) Inventors: Klaus-Dieter HILLIGES, Stuttgart (DE); Markus BÜCKER, Duisburg (DE); Marcus SCHULZE-WESTENHORST, Duisburg (DE); Olaf PÖPPE, Tübingen (DE); Thomas GLOS, Duisburg (DE)

(21) Appl. No.: 18/658,506

(22) Filed: May 8, 2024

Related U.S. Application Data
(63) Continuation of application No. PCT/EP2021/080990, filed on Nov. 8, 2021.

(51) Int. Cl. G01R 31/28

(52) U.S. Cl. CPC G01R 31/2834; G01R 31/2851

(57) ABSTRACT

An automated test equipment for testing a device under test comprises a trigger line which is controllable by the device under test (or, equivalently, by a test case which may, for example, be executed on the device under test). The automated test equipment is configured to update one or more tester resources in response to an activation of the trigger line by the device under test (or, equivalently, by a test case which may, for example, be executed on the device under test). A device under test, methods and a computer program are also described

### CROSS-REFERENCE TO RELATED APPLICATIONS

This application is a continuation of copending International Application No. PCT/EP2021/080990, filed Nov. 8, 2021, which is incorporated herein by reference in its entirety.

Embodiments according to the invention are related to an automated test equipment for testing one or more devices under test.

Further embodiments according to the invention are related to a device under test.

Further embodiments according to the invention are related to a test setup.

Further embodiments according to the invention are related to a method for operating an automated test equipment.

Further embodiments according to the invention are related to a method for testing a device under test.

Further embodiments according to the invention are related to a computer program.

Generally speaking, embodiments according to the invention are related to a production tester control by an on-chip-system-test.

### BACKGROUND OF THE INVENTION

Automated test equipment (ATE) is a platform for a production test and post-silicon validation with fast, automated test case execution and flexible control of the devices under test (DUTs) external test conditions.

Production tests of digital integrated circuits are done traditionally on ATE by structural tests. Cycle accurate input patterns are applied to the device under (DUT) and by comparing of the resulting output patterns with the expected patterns the failing devices are detected.

The internal structure of DUTs is moving to complex system on-chip (SoC) devices containing many subsystems with multi-processor, memory and peripheral units interconnected by network on-chip fabrics. Even a coverage of 99.5% by structural tests results in millions of untested transistors in those SOCs, which led to the introduction of the on-chip-system-test (OCST).

OCSTs are executed as real time scenarios by embedded software on the processor environment of the DUTs and closing the test gaps by functional performance checks of critical use cases including all subsystems of the SoC.

Legacy Approach to Upload OCST/Functional Tests by Test Pattern

In the following, a legacy approach to upload OCST/functional test by a pattern test will be described.

FIG. 4 shows a common approach on ATE systems to upload the software (SW) of the functional test case (TC) in the memory of the device under test (DUT). The SW is uploaded by sequences of cycle accurate pattern applied to the memory interface on the DUT. A drawback is the time consuming conversion of the SW-code into pattern sequences and the limitation of the download speed by the maximum clock rate of the digital channels.

To conclude, FIG. 4 shows an OCST/functional test upload and control by test pattern. For example, an automated test equipment 410 may comprise tester resources 420 which are coupled with a work station 422 that runs an ATE test program 424. For example, digital channels, which may, for example, be part of the test resources, may be used for a pattern based OCST upload and for a control via digital channels. In other words, digital channels may, for example, be used to upload a test program (e.g. an OCST-test-case 432) to the device under test 430. For this purpose, the digital channels of the ATE may be programmed to provide patterns which control the upload of the program (e.g. of the OCST-test-case) to a device under test. Moreover, additional tester resources, like, for example, digital channels, and/or analog channels and/or supply lines may be used to provide signals for the device under test, like for example, input signals and/or one or more supply voltages. Moreover, test resources 420 may also be used to receive one or more signals from the device under test 430 and to evaluate these signals from the device under test. For example, appropriate supply voltages may be provided to the device under test and there may be also a interaction between the automated test equipment and the device under test using respective tester resources. Moreover, the test resources may optionally also be used to perform measurements, to thereby evaluate the device under test.

To conclude, the upload of the OCST test case may be performed by the automated test equipment using appropriate tester resources, and there may be an interaction between the automated test equipment and the device under test using tester resources of the automated test equipment.

OCST/Functional Test Upload and Control by High Speed IO

In the following, an OCST/functional test upload and control by high speed IO will be described.

An evolution of the functional test case handling is the usage of the HSIO interfaces (e.g. USB, PCle, ETH) of the device under test (DUT) in native mode. This means, for example, that the test case software (SW) is now uploaded and, for example, controlled by a fully protocol supported high-speed interface and not anymore by cycle oriented deterministic patterns. To support the HSIO interface, a driver may need to be installed previously on the device under test (DUT), e.g. uploaded and activated by JTAG.

FIG. 5 shows a schematic representation of a functional test upload and control by high speed IO. In this concept, there may, for example, be an automated test equipment 510, which comprises tester resources 520 and a work station 522. Moreover, there is a device under test 530. For example, an ATE test program may effect an OCST-TC upload (e.g. an on-chip-system-test test-case upload). Moreover, the test program may also effect an execution control. For example, both the OCST-TC upload and the execution control may be performed using a high-speed-input-output (HSIO), like, for example, a universal-serial-bus interface, a “peripheral component interconnect express” interface (PCle) or via an Ethernet interface (ETH). Thus, the typical protocol-based high speed input-output interface may be used for the upload of the test case TC and for the control of the execution of the test case. In this regard, it should be noted that the OCST test case 532 is typically a software, which is executed using (or on) the device under test 540 (e.g., using one or more of the processors of the device under test 530).

In addition, the device under test 530 may be connected with the tester resources 520, wherein, for example, digital channels and/or analog channels and/or supply lines may be used. For example, ATE controlled signals for the DUT supply, test interaction and measurement may be used. In other words, the tester resources may, for example, comprise one or more device power supplies, which may, for example, provide one or more supply voltages for the device under test. Moreover, the tester resources may, for example, comprise one or more digital channels which provide digital signals to the device under test and/or receive digital signals from the device under test. For example, the automated test equipment 510 may use the one or more digital channels for an interaction with the device under test 530, and the automated test equipment 510 may optionally also make measurements using the digital channels. Moreover, the test resources 520 may, for example, comprise one or more analog channels which may, for example, be used to provide one or more analog signals to the device under test 530 and/or to receive one or more analog signals from the device under test 530. Moreover, the one or more analog channels may optionally also be used to make measurements, for example in order to assess signals received from the device under test 530.

To conclude, an OCST/functional test upload and control by high speed IO has been described taking reference to FIG. 5.

FIG. 6 shows a schematic representation of a variant by using a separate controller for OCST/functional test.

The arrangement 600 of FIG. 6, is an automated test equipment 610, which comprises tester resources 620 and a work station 622. Moreover, in the test arrangement 600 according to FIG. 6 there is also a device under test 630, on which an OCST test case 632 may be executed.

However, in addition to the test arrangement 500 according to FIG. 5, the test arrangement 600 according to FIG. 6 comprises an on-chip-system-test controller 640 which may, for example, be part of the automated test equipment 610. The on-chip-system-test controller may, for example, be coupled to the work station 622, for example using a high-speed input-output interface HSIO (e.g. USB, PCle, or ETH). For example, the ATE test program 624, which is executed on the workstation 622, may communicate with the OCST controller 640 via an interface (e.g., via a HSIO interface) to initiate, support or control an OCST-TC upload and/or an execution control. For example, the ATE-test-program may provide a representation of an OCST-test case (TC) to the OCST controller 640 and may, for example, instruct the OCST controller 640 to upload said OCST-test case to the device under test 640. Subsequently, the OCST controller 640 may, for example, perform the OCST-test case upload to the device under test 630. Moreover, the ATE-test program 624 may communicate with the OCST controller (e.g. via the HSIO-interface) to control an execution of a test case. For example, the communication between the ATE test program 624 and OCST controller 640 may be bi-directional (e.g. as indicated by a bidirectional arrow). Moreover, the OCST-controller 640 may be configured to communicate with the OCST test case 632, which is executed on the device under test 630, to control an execution of the test case. The communication between the OCST controller 640 and the OCST test case 632 may, for example, be bi-directional (e.g. as indicated by a bidirectional arrow).

Moreover, the functionality of the tester resources 620 may be similar to the functionality of the tester resources 520 in the test arrangement 500 which has been described above. In other words, the tester resources 620 may, for example, comprise one or more device power supplies and one or more digital channels and/or analog channels. Thus, the tester resources may be adapted to provide ATE controlled signals for DUT supply and for a test interaction and measurement.

Accordingly, the device under test may be tested in the test arrangement 600. To conclude, FIG. 6 shows a variant by using a separate controller for OSCT/functional test.

Moreover, it should be noted that any of the features, functionalities and details described in this section may optionally be used in embodiments according to the invention (as far as they are not in contradiction with the embodiments according to the invention). It should be noted that such features, functionalities and details may be introduced into any of the embodiments according to the invention both individually and taken in combination.

However, in view of the conventional approaches, there is a desire to have a concept for testing a device under test which provides for an improved tradeoff between on-chip-system-test functionality, on-chip-system-test test development effort and implementation effort.

### SUMMARY

According to an embodiment, an automated test equipment for testing a device under test may have: a trigger line which is controllable by the device under test, wherein the automated test equipment is configured update one or more tester resources in response to an activation of the trigger line by the device under test.

Another embodiment may have a device under test, wherein the device under test is configured to provide to an automated test equipment a trigger signal, to thereby trigger an update of one or more tester resources, via a dedicated trigger line.

According to another embodiment, an automated test equipment for testing a device under test may have: a trigger line which is controllable by a test case, wherein the automated test equipment is configured update one or more tester resources in response to an activation of the trigger line by the test case.

An embodiment according to the invention creates an automated test equipment for testing one or more devices under test. The automated test equipment is configured to receive, from a device under test (or, equivalently, from a test case) a command (e.g., in the form of a message) requesting an update of one or more tester resources. Moreover, the automated test equipment is configured to update one or more tester resources in response to the command provided by the device under test (or, equivalently, by the test case), and the automated test equipment is configured to provide an acknowledge signaling (or acknowledgement signaling) (e.g., an acknowledge message) to the device under test, to thereby signal a completion of a tester resource update requested by the device under test.

This embodiment of the invention is based on the finding that a test case development and a test case execution is significantly facilitated using such a concept. For example, using such a concept, an execution of the test case can easily be synchronized with an operation of the automated test equipment, without the need for a specific adaptation of the ATE test program (which may be executed on the automated test equipment). For example, a test case running on the device under test can be programmed to provide the command requesting the update of the one or more tester resources, and the test case running on the device under test can also evaluate the acknowledge signaling. However, since the evaluation of the command by the ATE may be “standardized” process (which may, for example, be equal for different test cases), and since the acknowledge signaling may be a “standardized” response to the command requesting an update of one or more tester resources, the provision of the acknowledge signaling by the automated test equipment may not require a specific adaptation of the automated test equipment (or of the ATE test program executed on the ATE) to the test case currently executed on the device under test. Thus, it may not be necessary to make any specific adaptations to the ATE test program when adding an instruction to issue a command requesting an update of one or more tester resources to a test case to be executed on the device under test. Consequently, a test development is facilitated significantly, since an adaptation (or update) of the one or more test resources may be fully under control of the test case (while, for example, the ATE and the test program executed on the ATE merely act as “slaves” executing the command provided by the test case).

Moreover, by providing an acknowledgement signaling, the automated test equipment allows the device under test to operate synchronously with the update of the tester resource. Consequently, a delay between the command requesting the update of the one or more test resources and the actual completion of the tester resource update, which may typically be unknown to the device under test and which may also be non-deterministic in some cases, can easily be dealt with by the device under test. Thus, the provision of the acknowledge signaling by the automated test equipment, to thereby signal the completion of the tester resource update requested by the device under test, allows the verification engineer to design reliable test cases to be executed on the device under test without having detailed knowledge about the functionality of the automated test equipment and without modifying code of the automated test equipment test program. Consequently, the automated test equipment described here allows for a central design of test cases and also allows for a reliable and fast execution of the test cases on the device under test (e.g., without the need to add unnecessary precautionary delays for awaiting an update of the tester resources, but instead using the acknowledge signaling).

In an embodiment, the automated test equipment is configured to receive, from a device under test (or, equivalently, from a test case) a command in the form of a parameterized messages, wherein a parameter of the message describes a desired setting of a tester resource (e.g., a desired supply voltage, a desired clock frequency, a desired signal characteristic, or the like).

By providing the automated test equipment with the functionality to evaluate messages having a predefined syntax, and comprising one or more parameters describing a desired setting of a tester resource, it may be unnecessary to specifically adapt an ATE test program to the test of a specific device under test. Rather, it is sufficient that the ATE test program provides a functionality to handle “standardized” parameterized messages (e.g. parameterized messages following a predetermined syntax, e.g. designating a tester resource to be modified and a desired new setting), while a verification engineer designing a test case to be executed on the device under test only needs to know the syntax of the commands that can be handled by the automated test equipment (e.g., by the ATE test program of the automated test equipment), or even only needs to know the syntax of an API function generating a command. Thus, the provision of a functionality to handle parameterized messages in the automated test equipment significantly facilitates a test development and eliminates the need to specifically adapt the ATE test program to a test of a specific device under test. Moreover, a verification engineer can also quickly and efficiently adapt a test case to be executed on the device under test to varying desired settings of the test resource.

In an embodiment, the automated test equipment is configured to provide the acknowledgement signaling in the form of a message. It has been found that transmission of messages (e.g., of messages having a predefined format including, for example, a message header, one or more bits identifying a command, one or more bits identifying a parameter, an optional error correction information and an optional message terminator) can be efficiently made over an interface between an automated test equipment and a device under test. For example, such a transmission of messages can be performed efficiently over a high speed interface and (or HSIO interface) between the automated test equipment and the device under test. Moreover, it has been found that a transmission of a message, for example in a message format that is appropriate for the specific interface type, can be performed efficiently using interface drivers adapted to the specific interface type. Accordingly, a certain (e.g. high-speed) interface may, for example, be used both for the transmission of the parameterized message and for the transmission of the acknowledgement signaling, and also for other data exchange between the automated test equipment and the device under test. Thus, a certain interface can be shared for a transmission of messages of different types, which eliminates the need for dedicated signaling lines (e.g., for the acknowledgement signaling).

Moreover, it should be noted that the concept of using both a command in the form of a parameterized message and an acknowledgement signal in the form of a message relaxes timing requirements, such that it is possible to use (e.g. parameterized) messages which may be handled by interface drivers and by interfaces having a non-deterministic timing behavior. For example, by giving the device under test the chance to wait for the acknowledgement signaling before proceeding with a test execution, a slight delay in a message transmission (both of the command message and of the acknowledgement signaling message) does not significantly affect the execution of the test case on the device under test and, in particular, does not endanger an synchronism between the execution of the test case and the desired update of the one or more test resources.

In an embodiment, the automated test equipment is configured to receive the command from the device under test (or, equivalently, from the test case) (e.g., a message from the device under test) via a (protocol-based) high bandwidth interface (e.g., via a high speed interface; e.g., via a USB interface, or a PCI interface, or a PCI-express interface, or a PCI-express compliant interface, or a thunderbolt interface or an Ethernet interface, or an IEEE-1394 interface, or a SATA interface or an IEEE-1149 interface or an IEEE-1500 interface, or an IEEE-1687 interface). Alternatively or in addition, the automated test equipment is configured to provide the acknowledgement signaling (e.g., the acknowledgement message) to the device under test via a (protocol-based) high bandwidth interface (e.g., via a high speed interface; e.g., via a USB interface, or a PCI interface, or a PCI-express interface, or a PCI-express compliant interface, or a thunderbolt interface, or an Ethernet interface, or an IEEE-1394 interface, or a SATA interface or an IEEE-1149 interface or an IEEE-1500 interface, or an IEEE-1687 interface). By using such a high bandwidth interface for the transmission of the command from the device under test towards the automated test equipment and/or for the transmission of the acknowledgement signaling from the automated test equipment to the device under test, delays can be kept reasonably small and said interfaces can also be reused. For example, the high speed interfaces mentioned above may be reused for the upload of the on-chip-system-test software to the device under test and/or for the download of result data from the device under test to the automated test equipment. However, it has been found that, during the execution of a test case, said high bandwidth interfaces may typically have sufficient bandwidth available for the transmission of a command from the device under test to the automated test equipment and for the transmission of the acknowledgement signaling from the automated test equipment to the device under test. It has been found that said interfaces are typically mostly loaded before the start of an on-chip-system-test and after the completion of the on-chip-system-test (e.g. for the transmission of test results). Thus, a high speed interface, which is typically also used for other purposes in the test of an on-chip-system, and for which a driver is therefore available both at the side of the automated test equipment and at the side of the device under test, is well-suited for the transmission of commands and for the transmission of the acknowledgement signaling. Moreover, some types of high speed (or high bandwidth) interfaces even allow for a reservation of time slots, which allows for a close-to-real-time (or close-to-time-deterministic) forwarding of the command from the device under test to the automated test equipment and/or for the forwarding of the acknowledgement signaling from the automated test equipment to the device under test. Moreover, the above mentioned high bandwidth interface typically provides a close-to-real-time transmission even in the absence of a reserved time slot due to the high available bandwidth.

In an embodiment, the automated test equipment is configured to update one or more tester resources during an execution of a test case on the device under test (e.g., a system-on-the-chip) in response to the command by the device under test (or, equivalently, by the test case) (e.g., under the control of the test case executed on the device under test). However, it has been found that updating the one or more tester resources during the execution of a test case on the device under test is possible without significant problems using the inventive approach. For example, the test case may issue the command requesting the update of the one or more test resources, and may then either continue with an execution of test case routines which are insensitive to an update of the one or more tester resources (and then, later on, check for the reception of the acknowledge signaling) or may pause to wait for a reception of the acknowledge signaling. Thus, it is no longer necessary that the automated test equipment provides any additional control signals to the device under test in order to complete an update of a tester resource, except for a provision of the acknowledgement signaling. For example, it can be avoided that the automated test equipment provides explicit signaling or control signals in order to interrupt a test case execution before the resource update or to start a test case execution after a resource update. Consequently, delays which would be caused by an explicit control of a test case execution by the automated test equipment, can be avoided by providing the acknowledge signaling from the automated test equipment to the device under test. In particular, the test case execution can continue during the resource update, which helps reduce valuable test time. Also, waiting for the acknowledge signaling can be performed under the control of the test case executed on the DUT, such that it is not necessary to interrupt execution of a test case being executed on the DUT.

In an embodiment, the automated test equipment is configured to provide an application programming interface (API) for usage by a test case which is executed on the device under test. The application programming interface is configured to provide one or more routines (e.g., methods or functions) for transmission of commands requesting an adaptation (or update) of one or more tester resources from the device under test (or, equivalently, from the test case) to the automated test equipment. Alternatively or in addition, the application programming interface is configured to provide one or more routines (e.g., methods or functions) for a temporal synchronization between the device under test and the automated test equipment (e.g., one or more routines for pausing program execution (e.g., of a test case executed on the device under test) until reception of a signaling indicating a completion of a tester resource update).

By providing an application programming interface for use by a test case, the automated test equipment can significantly support the development of a test case. By providing one or more routines for a transmission of commands requesting adaptation (or update) of one or more tester resources from the device under test to the automated test equipment, it is unnecessary for the verification engineer to know internals of the automated test equipment or details regarding the syntax of the commands. Rather, it is sufficient for the verification engineer to add one or more routines from the application programming interface into the test program (e.g. to the test case to be executed on the dut), which is typically easy in case the routines are well-documented. Also, the application programming interface may be designed in such a manner that a test program development is actually independent from the actual tester hardware or from a software revision of the software on the automated test equipment. Consequently, the verification engineer has a very efficient tool, and a development of test cases during which one or more tester resources are updated is very simple and does not require to deal with details of the test program running on the automated test equipment. The same also holds for the provision of one or more routines for a temporal synchronization between the device under test and the automated test equipment. Such routines may easily be included into the test case (to be executed on the device under test) by the verification engineer without requiring that the verification engineer has detailed knowledge about the internals of the automated test equipment or about the ATE test program. Thus, by providing an appropriate ATE, the synchronization between the test case and the update of tester resources may be effected in a simple manner, wherein the test program development may even be independent from the actual tester hardware and/or from the software revision of the ATE software. This allows for an efficient software development with reduced error risks and high portability.

In an embodiment, the automated test equipment comprises an on-chip-system-test (OCST) controller and a test program executor executing a test program and one or more test resources (e.g., one or more device power supplies, and/or one or more analog or digital signal generators). The on-chip-system-test controller is configured to receive the command (e.g., in the form of a message) requesting an update of the one or more tester resources from the device under test (or, equivalently, from the test case) (e.g., via a high bandwidth interface) and to forward the command (e.g., the message) to the test program executor executing a test program. Moreover, the test program comprises a message handler configured to effect (e.g., execute) an update of one or more tester resources in response to the (forwarded) command (e.g., in the form of a forwarded message), e.g., after decoding and/or interpreting the forwarded message (e.g., in dependence on one or more parameters included in the forward message).

Using such a concept, it is possible to have the basic functionality to control tester resources (also sometimes designated herein as test resources) implemented in the test program executor, while specific support for on-chip-system-tests is provided by the on-chip-system-test controller. For example, the test program executor may exercise the (control over the tester resources in a manner which is defined by the test program (wherein the test program may, for example, define a handling of commands for an update of tester resources received from the device under test). Accordingly, the fundamental functionality of the automated test equipment can be defined by the ATE test program, which allows to configure the automated test equipment in a manner that is well adapted to a current test scenario. On the other hand, the on-chip-system-test controller may provide specific functionalities, which are relevant for an on-chip-system-test, in a more efficient manner than the test program executor. For example, the on-chip-system-test controller may efficiently (e.g., using dedicated hardware support) implement high speed interfacing functionalities which are relevant for the on-chip-system-test. For example, the on-chip-system-test controller may comprise hardware implementations of high speed input output interfaces that are well suited for communication with the device under test, which may be a system-on-a-chip. By having efficient (and possibly hardware-supported) implementations for the communication with the device under test, the on-chip-system-test controller relaxes the requirements for the test program executor and may, for example, take over a handling of communication protocols for communication with the device under test. Moreover, the on-chip-system-test controller may also support additional functionalities required for on-chip-system-test, like an upload of a test case to one or more devices under test and/or a download of test results from one or more devices under test and/or an evaluation of test results. For example, the on-chip-system-test controller may significantly support any protocol based data exchange with the device under test, which is typically difficult to handle with conventional tester resources.

Moreover, the on-chip-system-test controller may be well-suited for receiving a command requesting an update of one or more test resources from a device under test, in particular if such a command is transmitted using an interface technology and/or a communication protocol which can be handled better by the on-chip-system-test controller when compared to the test program executor. Accordingly, by exploiting the performance of the on-chip-system-test controller for a reception of the command requesting an update of the tester resources, a high bandwidth communication can be applied for the transmission of said command, and a usage of other tester resources, which may have difficulties to implement a protocol based high speed communication, can be avoided. The on-chip-system-test controller may, for example, extract the command from a high speed communication protocol and forward the command (e.g., in its original form or in a translated form) to the test program executor, wherein it should be noted that the on-chip-system-test controller may typically be linked by a high data rate ATE-internal interface with the test program executor. Accordingly, the “conventional” tester resources and also the test program executor are not required to take over the typically very challenging task to receive high speed communication from the device under test, but rely on the on-chip-system-test controller as a powerful intermediary. Moreover, the test program executor can typically receive the communication from the on-chip-system-test controller with little effort, and the test program running on the test program executor may evaluate this forwarded command in a manner that is flexibly configurable by the ATE test program. In other words, the on-chip-system-test controller may serve as a forwarding instance, which may also take over the protocol-handling for the communication with the device under test, and the test program executor may control the actual tester resources under the control of the ATE test program, wherein said ATE test program may, in turn, evaluate the command forwarded by the on-chip-system-test controller and translate the command into tester-internal (e.g. hardware-related) commands for configuring the tester resources of the automated test equipment. Consequently, a very efficient sharing of tasks within the automated test equipment can be achieved, which allows for the handling of the commands in a resource-efficient manner.

In an embodiment, the message handler is configured to translate a command (e.g., a message) comprising a symbolic reference (e.g., “VCC2) of a tester resource (e.g., of a supply voltage or of a signal) into a tester-hardware-related tester resource adjustment (e.g., into an instruction setting a (physical) resource channel of the automated test equipment to a desired value).

By using such a concept, the command, which is generated by the test case running on the device under test, does not need to be aware of the specific hardware of the automated test equipment, and also does not need to be aware of any ATE-internal commands for controlling test resources. Rather, the test case running on the device under test can rely on symbolic references, which are easy to understand for the verification engineer. Moreover, the translation of these symbolic references into tester-hardware-related control commands is effected by the message handler in a configurable manner, such that an association between a symbolic reference and a physical tester resource may, for example, be defined in the ATE test program executed by the tester program executor. Consequently, testers having different actual physical tester resource configurations can be adapted for usage with a given test case by a one-time adaptation of the ATE test program, to properly handle a given test case using certain symbolic references. Consequently, a test case does not need to be re-written, and even does not need to be modified, when the actual physical tester hardware changes. Consequently, the ATE test program, which is executed by the test program executor of the ATE, constitutes a physical abstraction mechanism, which significantly facilitates a test of devices under test on different automated test equipment.

In an embodiment, the message handler is configured to generate the acknowledgement message and to provide the generated acknowledgement message to the on-chip-system-test controller (e.g., after a completion of the update of the one or more tester resources requested by the device under test). Moreover, the on-chip-system-test controller is configured to forward the acknowledgement message provided by the message handler to the device under test, or to provide an acknowledgement message to the device under test in response to the acknowledgement message provided by the message handler.

By using such a concept, the acknowledge message can be generated in the test program executor, which typically has very close physical access to the tester resources and which typically also can reliably determine when an update of the tester resources has been completed. Thus, it has been found that the message handler is best suited to generate the acknowledgement message, while the on-chip-system-test controller is best suited for forwarding the acknowledgement message, wherein this forwarding of the acknowledgement message may, for example, comprise a protocol handling for communication with the device under test. Consequently, a typically fast communication between the message handler and the on-chip-system-test controller and a high speed communication towards the device under test, which is enabled (or best supported) by the on-chip-system-test controller, can be used. Thus, a fast mechanism for the transmission of the acknowledgement message can be implemented with an efficient use of the available resources.

In an embodiment, the automated test equipment is configured to execute a test program, wherein the test program is configured to initialize test resources of the automated test equipment, to allow for a start of a test program execution on the device under test. Moreover, the test program is configured to effect further updates of the test resources under the control of the device under test (e.g., under the control of one or more on-chip-system-test test cases executed on the device under test). Accordingly, a sharing of tasks between the ATE test program and the test case running on the device under test can be achieved. A start up condition, which is best suited for a reliable start-up of the device under test, can be effected by the ATE test program, for example at a time when there is not even a test case running on the device under test. Later on, different test conditions, which are caused by the update of the test resources under the control of the device under test, can then be reached, e.g., under the superordinate control of the test case. Accordingly, challenging tests, which may, for example, result in a test of the device under test under marginal conditions, may be controlled by the test case. It has been found that such a concept makes a test development particularly simple and reliable.

In an embodiment, the automated test equipment comprises an on-chip-system-test controller. The automated test equipment comprises one or more tester resources (e.g., one or more device power supplies, and/or one or more analog or digital signal generators). The on-chip-system-test controller is coupled (e.g., directly coupled; e.g., coupled in a manner bypassing the test program executor) to the one or more tester resources. Moreover, the on-chip-system-test controller is configured to provide control signals (e.g., via a data bus and/or via one or more synchronization lines and/or via a synchronization bus) to the one or more tester resources, in order to update the one or more tester resources in response to a command from the device under test (or, equivalently, from the test case).

Using such a concept, it is possible to have a very fast update of the one or more tester resources in response to the command from the device under test. For example, the on-chip-system-test controller may be adapted to have a very fast communication with the device under test, e.g., using a high speed interface (e.g., HSIO). The on-chip-system-test controller may be configured to handle a protocol of a high speed interface, to thereby allow for a fast communication between the on-chip-system-test controller and the device under test with moderate effort. Thus, the on-chip-system-test controller is well adapted to receive a command requesting an update of one or more tester resources from the device under test. Moreover, by providing the on-chip-system-test controller with an interface that allows for a direct control of one or more tester resources, for example without an involvement of a test program executor or of a work station controlling the automated test equipment, the on-chip-system-test controller can effect an update of one or more tester resources very quickly in response to the command issued by the device under test (e.g., via the high speed interface). For example, the on-chip-system-test controller may be provided with direct access to an interface (e.g., a data bus) which allows for a configuration (or re-configuration) of one or more tester resources. Thus, a latency of the update of the one or more tester resources in response to a command from the device under test can be reduced when compared to other solutions in which, for example, a test program executor is also involved in the update of the one or more tester resources.

In an embodiment, the on-chip-system-test controller is configured to translate a command (e.g., a message) comprising a symbolic reference (e.g., “VCC2”) of a tester resource (e.g., of a supply voltage or of a signal) into a tester-hardware-related tester resource adjustment (e.g., into an instruction setting a (physical) resource channel of the automated test equipment to a desired value).

By using such a translation of a symbolic reference into a tester-hardware-rated tester resource adjustment, the development of the test program can be facilitated significantly for the verification engineer. For example, the verification engineer designing the test case only needs to make reference to the symbolic reference and does not need to be aware of the specific physical configuration of the automated test equipment. Moreover, a test case may therefore be executable on automated test equipment of different configurations (e.g. without modification). Thus, the concept to use a translation of commands has quite significant advantages for the test development and for the test execution. Moreover, reference is also made to the above explanations regarding the command translation in the test program executor.

In an embodiment, the on-chip-system-test controller is coupled with the one or more tester resources via a data bus and via a synchronization line or synchronization bus. The on-chip-system-test controller is configured to prepare (e.g., initialize) a new setting (e.g., a new voltage) of a selected tester resource (e.g., a device power supply, whose output voltage is to be changed) via the data bus in dependence of (or on) a message parameter (e.g., a message parameter defining the new voltage) of the command received from the device under test (or, equivalently, from the test case) (e.g., in order to define an upcoming characteristic of the selected tester resources). Moreover, the on-chip-system-test controller is configured to activate the prepared new setting of the selected tester resource via the synchronization line or via the synchronization bus (e.g., using a synchronization bus event or a synchronization bus message). Using such a concept, the on-chip-system-test controller can obtain a very precise knowledge when an update of the test resource is actually prepared.

While the communication of the desired new setting via the data bus in dependence on message parameters of the command received from the device under test may not allow for a precise determination of a point in time when the update of the test resource actually takes place, there is typically a very well-predictable timing relationship between an activation of a synchronization line or a data transmission via a synchronization bus and a time when the tester resource is actually updated. Accordingly, the acknowledge message can be generated by the on-chip-system-test controller with high reliability, and without the need to add an unnecessary delay “just to be on the safe side”. Accordingly, such a concept allows for fast test execution and therefore helps to reduce the cost of test.

In an embodiment, the on-chip-system-test controller is configured to provide the acknowledge signaling (e.g., in the form of an acknowledge message) to the device under test. Accordingly, the synchronization with the execution of the test case on the device under test can be ensured, wherein the communication from the on-chip-system-test controller to the device under test is typically particularly fast in view of the capability of the on-chip-system-test controller to efficiently use a high speed interface.

An embodiment according to the invention creates a device under test. The device under test is configured to provide to an automated test equipment a command (in the form of a message) requesting an update of one or more tester resources (e.g., under the control of a test case which is executed on the device under test). Moreover, the device under test is configured to pause an execution of a test case until an acknowledge signaling (e.g., an acknowledge message), indicating a completion of a tester resource update requested by the device under test, is received by the device under test.

This device under test allows for a particularly efficient execution of a test. The device under test (or a test case which is executed on the device under test) can control the test environment of the device under test (e.g., a setting of one or more supply voltages supplying the device under test, and/or setting of one or more clock frequencies of the device under test, and/or characteristics of input signals provided to the device under test by the automated test equipment). Moreover, by pausing the execution of the test case until an acknowledge signaling indicating a completion of a test resource update requested by the device under test is received by the device under test, a timing synchronization between the test case which is executed on the device under test and the update of the one or more tester resources can be achieved. For example, the device under test can wait with the execution of test program steps that require the update of the one or more tester resources until the acknowledge signaling is received, which helps to ensure that the test case is executed with the proper expected test environment. Also, by using an acknowledge signaling, unnecessary delays “to be on the safe side” can be avoided. Consequently, a test case can be executed fast and with a very high reliability (e.g. by immediately continuing the test case execution when the acknowledge signaling is received, rather than using a precautionary large fixed delay).

Furthermore, the development of such a test case is typically very easy for the verification engineer, since changes of the test environment can be effected by respective commands included in the test case to be executed on the device under test, without making adaptations of the test program which is executed on the automated test equipment. Thus, both development and debugging of the test case to be executed on the DUT is simple and reliable.

In an embodiment, the device under test is a system-on-a-chip. The device under test is configured to execute a test case (e.g., a program performing a test procedure for testing the device under test). Moreover, the device under test is configured to provide the command to the amended test equipment under the control of the test case. Accordingly, a test case has very reliable control over an adjustment of the test environment by having the possibility to request an update (e.g., a parameter change) of one or more tester resources and also by having the possibility to evaluate a signaling indicating a completion of such an update of tester resources.

Accordingly, the test case itself can control the test environment (e.g. supply voltages of the device under test, or physical parameters of one or more signals provided to the device under test by the automated test equipment). This allows to have a very thorough test that is substantially under (superordinate) control of the test case and that can therefore be defined efficiently by the verification engineer designing the test case.

In an embodiment, the device under test is configured to provide the command in the form of a parametrized message, wherein a parameter of the message describes a desired setting of a tester resource (e.g. a desired supply voltage, a desired clock frequency, a desired signal characteristic, or the like). It has been found that the usage of commands in the form of parametrized messaged makes it simple for the verification engineer to communicate the specific requirements for the automated test equipment. Moreover, it has been found that parametrized commands typically provide for a very good readability of the program code underlying the test case. Moreover, reference is also made to the above-discussed advantages provided by the usage of commands in the form of parametrized messages.

In an embodiment, the device under test is configured to receive the acknowledgement signaling in the form of a message. It has been found that devices under test, which comprise one or more high-speed interfaces, are well-suited for reception of messages, since such devices under test typically comprise communication interface drivers which can handle messages (wherein such messages may, for example, comprise a message header, message data, an optional error correction information and an optional message terminator). Moreover, it has been found that a handling of messages is typically possible by the software running on the device under test, for example supported by an operating system running on the device under test, or using a loop waiting for the reception of a message. Also, an evaluation of a message is typically easily possible using a finite state machine, which can be implemented on the DUT with moderate effort.

In an embodiment, the device under test is configured to provide the command to the automated test equipment (e.g. a message to the automated test equipment) via a (protocol-based) high bandwidth interface, for example via a high-speed interface (e.g. via a USB interface, or a PCI interface, or a PCI-express interface, of a PCI-express compliant interface, or a thunderbolt interface, or an Ethernet interface, or an IEEE-1394 interface, or a SATA interface, or an IEEE-1149 interface or an IEEE-1500 interface, or an IEEE-1687 interface). Alternatively or in addition, the device under test is configured to receive the acknowledgement signaling (e.g. the acknowledgement message) (e.g. from the automated test equipment) via a (protocol-based) high bandwidth interface (e.g. via a high-speed interface; e.g. via a USB interface, or a PCI interface, or a PCI-express interface, or a PCI-express compliant interface, or a thunderbolt interface, or an Ethernet interface, or an IEEE-1394 interface, or a SATA interface, or an IEEE-1149 interface or an IEEE-1500 interface, or an IEEE-1687 interface).

It has been found that the usage of such high-speed interfaces (or high bandwidth interfaces) is well-suited for many devices under test, which may comprise one or more of these interfaces on-chip, and which may comprise drivers for one or more of these interfaces. For example, said interfaces may be re-used for multiple purposes during an on-chip-system-test, for example for the upload of the test case from the automated test equipment to the device under test and/or for the download of test results from the device under test to the automated test equipment and/or for a testing of the interfaces themselves. Accordingly, a high-speed interface is easily usable for the transmission of the command to the automated test equipment and also for the reception of the acknowledgement signaling from the automated test equipment, wherein the usage of such a high-speed interface allows for low latencies.

In an embodiment, the device under test is configured to use one or more library routines (e.g. of a software library provided by the automated test equipment) (a usage of which may, for example, be enabled by an application programming interface, which is provided by the automated test equipment), in order to provide the command and/or in order to evaluate the acknowledgement signaling. Usage of library routines by the device under test facilitates the provision of the command and/or the evaluation of the acknowledgement signaling and makes it easy for a verification engineer to develop an appropriate test program. For example, the library routines may be provided by the manufacturer of the automated test equipment, and may therefore be well-adapted to the automated test equipment. For example, the verification engineer designing the test case does not need to have any detailed knowledge about the internals of the automated test equipment and/or about the protocol for the transmission of the messages or for the transmission of the acknowledgement signaling. Rather, a verification engineer who designs the test case to be executed on the device a test may merely need to make use of the application programming interface, which is, for example, provided by the automated test equipment (e.g. as a part of the automated test equipment software). Accordingly, the verification engineer can reliably and comfortably develop the test program.

An embodiment according to the invention creates a test setup. The test setup comprises an automated test equipment as outlined above and a device under test, as outlined above. This test setup is based on the same considerations as the automated test equipment and the device under test discussed above.

Another embodiment according to the invention creates a method for operating an automated test equipment. The method comprises receiving, from a device under test (or equivalently, from a test case) a command (e.g. in the form of a message) requesting an update of one or more test resources. Moreover, the method comprises updating one or more test resources in response to the command provided by the device under test (or equivalently, from a test case). Moreover, the method comprises providing acknowledge signaling (e.g. an acknowledge message) to the device under test, to thereby signal a completion of a test resource update requested by the device under test. This method is based on the same considerations as the above-mentioned automated test equipment. Moreover, the method could optionally be supplemented by any of the features, functionalities and details discussed herein, also with respect to the automated test equipment. The method can optionally be supplemented by such features, functionalities and details both individually and taken in combination.

Another embodiment according to the invention creates a method for testing a device under test. The method comprises providing a command (e.g. in the form of a message) requesting an update of one or more tester resources (e.g. under the control of a test case which is executed on the device under test) from a device under test (or, equivalently, from a test case) to an automated test equipment under the control of a test case running on the device under test. The method comprises pausing (e.g. under the control of the test case) an execution of the test case until an acknowledge signaling (e.g. an acknowledge message), indicating a completion of a tester resource update requested by the device under test, is received by the device under test (and, for example, detected by the test case). Moreover, the method comprises updating one or more test resources in response to the command provided by the device under test (or, equivalently, by the test case). Also, the method comprises providing an acknowledge signaling (e.g. an acknowledge message) to the device under test, to thereby signal a completion of the tester resource update requested by the device under test. Moreover, the method comprises continuing an execution of the test case upon detection of the acknowledged signaling by the device under test.

This method implements an interaction between the automated test equipment discussed above and the device under test discussed above. Accordingly, the method is based on the same considerations and comprises the same advantages as discussed with respect to the automated test equipment and with respect to the device under test. Moreover, the method may optionally be supplemented by any of the features, functionalities and details discussed herein with respect to the automated test equipment and also with respect to the device under test, both individually and taken in combination.

Another embodiment according to the invention creates a computer program for performing the methods discussed here.

Yet another embodiment according to the invention creates an automated test equipment for testing one or more devices on the test. The automated test equipment is configured to receive, from a test case, a command (e.g. in the form of a message) requesting an update of one or more test resources. The automated test equipment is configured to update one or more test resources in response to the command provided by the test case. Moreover, the automated test equipment is configured to provide an acknowledge signaling (e.g. an acknowledge message) to the test case, to thereby signal a completion of a tester resource update requested by the test case. This automated test equipment is based on similar considerations as the automated test equipment discussed earlier. However, it should be noted that the automated test equipment is generally configured to receive the command from the test case, wherein the test case is typically executed on the device under test (but may also be executed in a distributed manner, e.g. distributed between the automated test equipment and the device under test). Moreover, it should be noted that automated test may optionally be supplemented by any of the features, functionalities and details discussed herein, also with respect to the automated test equipment receiving the command from the device under test. For example, the reception of the command from the test case may take the place of the reception of the command from the device under test. The automated test equipment may be supplemented by such features, functionalities and details both individually and taken in combination (wherein the test case may, for example, take the place of the DUT, where appropriate).

Another embodiment according to the invention creates a method for operating an automated test equipment. The method comprises receiving, from a test case, a command (e.g. in the form of a message) requesting an update of one or more test resources. The method comprises updating one or more test resources in response to the command provided by the test case. Moreover, the method comprises providing an acknowledge signaling (e.g. an acknowledge message) to the test case, to thereby signal a completion of a tester resource update requested by the test case. This method is based on the same considerations as the method for operating an automated test equipment described earlier, wherein the command is provided by a test case. The method may optionally be supplemented by any of the features, functionalities and details described herein, also with respect to a corresponding automated test equipment. The method may be supplemented by such features both individual and taken in combination (wherein the test case may, for example, take the place of the DUT, where appropriate).

Moreover, embodiments according to the invention also create a respective computer program.

An embodiment according to the invention creates an automated test equipment for testing a device under test. The automated test equipment comprises a trigger line (e.g. a hardware trigger line, e.g. the GPO-trigger-line) which is controllable by the device under test (or equivalently, by a test case which may, for example, be executed on the device under test). The automated test equipment is configured to update one or more tester resources (also sometimes designated as test resources herein) (e.g. to change one or more supply voltages provided to the device under test by the automated test equipment, or to change one or more signal characteristics of one or more analog or digital signals provided to the device under test by the automated test equipment) in response to an activation of the trigger line by the device under test (or, equivalently, by a test case which may, for example, be executed on the device under test).

This embodiment according to the invention is based on the idea that a test may be executed with high timing accuracy under the control of the device under test (which may, for example, be a system-on-the-chip) by providing, in the automated test equipment, a trigger line that allows the device under test to trigger an update of one or more tester resources. Accordingly, it is possible for the device under test to have an impact on the test environment with little effort but high timing accuracy. For example, by providing a device under test an access to a trigger line, which triggers an update of one or more tester resources, the inventive automated test equipment provides devices under test the possibility to change settings of the automated test equipment (or more precisely, of one of more test resources) without requiring the device to send a command, e.g. using a protocol-based interface. Accordingly, a device under test may effect (or trigger) the update of one or more tester resources by a simple activation (or deactivation) of a single output pin (e.g. a general purpose output pin, or any other output pin) or of a single input/output pin, which is typically possible with very little effort and with very high timing accuracy.

For example, using such a concept, a device under test, which may be a system-on-a-chip, may only require a single machine instruction (or a very small number of machine instructions) to activate or de-activate an output (or, more precisely, a single output pin or a single input/output pin), to thereby trigger an update of one or more test resources (e.g. by an edge on said output pin r input/output pin). The activation (or de-activation) of such an output, which may be coupled with the trigger line, may be possible within a very short time, and may, for example, not raise the need to make use of any complex drivers or communication protocols. Delays or timing non-determinism, which could be caused by drivers that may be needed to operate a protocol based high speed interface, may be avoided (or bypassed) in this manner.

Moreover, additional delays in the automated test equipment may also be avoided by the usage of the above-mentioned trigger line, since the mere activation of a trigger line (e.g. a rising or falling edge on the trigger line) typically does not need a complicated protocol handling or command translation at the side of the automated test equipment, such that both effort and delays can be avoided. Rather, the trigger line, which may be a dedicated trigger line, may directly act on the test resources, thereby minimizing both delay and complexity of the arrangement. Thus, a simple falling or rising edge on said trigger line may cause the tester resource update.

To conclude, providing a device under test with access to the above-described trigger line provides a very good compromise between reaction time, implementation effort and ease-of-use.

In an embodiment, the automated test equipment is configured such that the activation of the trigger line (e.g. a simple edge or transition on the trigger line) directly triggers an update of one or more test resources, bypassing a test program executor executing a test program (e.g., a test program executor of the automated test equipment executing an ATE test program). By bypassing the test program executor, unnecessary delays can be avoided, and tester resources like, for example, an ATE power supply, an analog channel module or a digital channel module, can be directly triggered by the device under test. Moreover, an execution of an ATE test program is also not interrupted by the activation of the trigger line, such that the test program executor may perform its activities (like, for example, an evaluation of result data provided by the device under test) in an uninterrupted manner, which helps to reduce test time. Also, an interruption of the operation of the test program executor, which could result in a loss of data (e.g., when the test program executor is responsible for capturing result data from the device under test) can also be avoided.

In an embodiment, the automated test equipment comprises one or more tester resources (e.g., one or more device power supplies, and/or one or more digital signal modules or signal sources, and/or one or more analog signal modules or signal sources, and/or one or more mixed signal modules). Moreover, the one or more tester resources (also designated as test resources) are coupled to a test program executor via an interface, which allows for a programming of one or more characteristics (e.g., of a supply voltage, e.g., of a digital pattern, e.g., of a digital waveform, etc.) of the one or more test resources under the control of a test program (e.g., under the control of an ATE test program which is executed, for example, by the test program executor of the automated test equipment). Moreover, the one or more tester resources are coupled to the trigger line which is controllable by the device under test (or, equivalently, but a test case which may, for example, be executed on the device under test).

Moreover, the one or more tester resources are configured to update a signal characteristic in a manner (e.g., to a value), which has been pre-programmed under the control of the test program, in response to an activation of the trigger line by the device under test (or, equivalently, by a test case which may, for example, be executed on the device under test).

In this concept, the test program executor maintains control of the actual parameters, to which the one or more tester resources are set. Accordingly, there may be a sharing of responsibilities between the test program executor and the device under test, wherein the test program executor is responsible for programming characteristics of the one or more test resources and also for preprogramming a setting of one or more tester resources, which should be taken over in response to the activation of the trigger signal, while the device under test only needs to activate the trigger signal at an appropriate time (e.g. determined by the test case executed on the DUT). Accordingly, the device under test (which is typically an intelligent device under test, like, for example, a system-on-the-chip) only needs to take over a small part of the functionality (triggering an update of a signal characteristic of one or more tester resources to values preprogrammed by the test program executor), which allows for a very simple communication between the device under test and the automated test equipment (that only requires the activation or de-activation of a single output of the device under test, which provides the trigger signal). On the other hand, the test program executor of the automated test equipment typically comprises knowledge about updates of one or more test resources, which are needed by the device under test, and should also have some timing coordination with the execution of the test case on the device under test. However, such a “coarse” timing synchronization between the test program executor of the automated test equipment and the execution of the test case on the device under test is normally given, since the test program executor typically controls the upload of the test case to the device under test and also communicates with the device under test to receive test result information from the device under test. Accordingly, the test program executor is typically aware of the state of the device under test and therefore also has knowledge which update of one or more test resources will next be required by the device under test, such that the test program executor can easily preprogram the one or more tester resources, which update of one or more parameters of the one or more test resources should be made in response to a subsequent activation of the trigger line by the device under test. Consequently, it is apparent that the concept mentioned here is highly efficient, since the communication between the device under test and the automated test equipment is facilitated while providing a very high timing accuracy.

In an embodiment, the automated test equipment comprises a test program executor configured to pre-program one or more tester resources, in order to pre-define a response (e.g. a change of a signal characteristic to a new parameter value) of the one or more tester resources to a activation of the trigger line by the device under test (or, equivalently, by a test case which may, for example, be executed on the device under test). By predefining a response of one or more tester resources to an activation of the trigger line by the device under test under the control of the ATE test program, the communication between the device under test and the automated test equipment can be kept very simple, such that, as a consequence, a mere activation of the trigger signal by the device under test is sufficient to cause a well-defined response of the one or more tester resources, wherein said response is predefined by the test program executor (e.g., under the control of an ATE test program).

In an embodiment, the automated test equipment (e.g., a test program executor of the automated test equipment) is configured to pre-program one or more tester resources in accordance with one or more instructions (e.g., instructions defining desired parameters for the pre-programming) provided in a test program (e.g., in an ATE test program executed by the test program executor of the ATE), in order to pre-define a response (e.g., a change of a signal characteristics to a new parameter value) of the one or more tester resources to an activation of the trigger line by the device under test (or, equivalently, by a test case which may, for example, be executed on the device under test). By defining the pre-programming of the one or more tester resources using instructions provided in a test program (e.g., an ATE test program), an appropriate update of one or more tester resources can be prepared in a programmable manner by an appropriate development of the ATE-sided test program (which should anyway be at least coarsely time-synchronized with the execution of a test case in the device under test). On the other way, a communication of parameters for the tester resource update from the device under test to the automated test equipment is not necessary (and can be omitted).

In an embodiment, the automated test equipment (e.g., a test program executor of the automated test equipment) is configured to receive, from a device under test (or, equivalently from a test case which may, for example, be executed on the device under test), a command (e.g., in the form of a message) defining one or more parameters for the update of the one or more tester resources (wherein said update is, for example, not triggered by the command defining the parameters but by the (subsequent) activation of the trigger line). Moreover, the automated test equipment (e.g., the test program executor of the automated test equipment) is configured to pre-program one or more tester resources in accordance with the command (e.g., in accordance with the command defining the one or more parameters for the update) received from the device under test (or, equivalently, from a test case which may, for example, be executed on the device under test), in order to pre-define a response (e.g., a change of signal characteristics to a new parameter value) of the one or more tester resources to an activation of the trigger line by the device under test (or, equivalently, by a test case which may, for example, be executed on the device under test).

By using such a concept, the device under test may itself signal to the automated test equipment which update of one or more parameters of one or more tester resources will be required next. However, this signaling from the device under test to the automated test equipment may, for example, be performed under relaxed timing requirements, since the actual time of the update of the one or more tester resources is determined by the activation of the trigger line by the device under test, which can be done in a very time-accurate manner (as discussed above). Using such a concept, it is no longer necessary from the automated test equipment (or for the test program executor of the automated test equipment) to know which parameter update of one or more tester resources will be required next by the device under test. Accordingly, there is no need for synchronism between the test case execution on the device under test and the execution of the ATE test program on the test program executor of the ATE. Moreover, a verification engineer may not only define the time at which an update of one or more tester resources should occur, but also one or more parameters to which the one or more tester resources should be set in the update, within the test case to be executed on the device under test. Thus, there is no need for the verification engineer to modify both the test case to be executed on the device under test and the ATE test program in order to define an appropriate update of the tester resources. Thus, it is significantly easier, and less error-prone, for the verification engineer to develop the test case, since he does no longer need to adapt the ATE test program when forwarding the desired new parameters of the one or more tester resources using the command (e.g., in the form of a message).

Thus, at least with respect to the adaption (update) of the test environment, the development of the test case is substantially independent from an adaption of the ATE test program using such a concept. Moreover, by distinguishing between a command defining one or more parameters for the update for the one or more tester resources and the actual activation of the trigger signal by the device under test, there is a separation between the non-time-critical part “command” (command defining the one or more parameters for the upcoming update of the one or more test resources) and the actual triggering of said update (wherein the latter is the typically a very time critical process). Consequently, the command, which typically comprises a larger amount of data, can, for example, be transmitted using a high speed interface, which may, for example, be protocol based and non-real-time capable (or not ideally real-time capable), while the trigger signal can be generated by a simple activation of a single output of the device under test, which can be done in a very time-accurate manner.

In an embodiment, the one or more tester resources comprise a trigger mechanism configured to update a signal characteristic (e.g., of a signal provided to the device under test by the respective tester resource) (e.g., a signal voltage provided to the device under test, or a frequency of a clock signal provided to the device under test), in response to an activation of the trigger line by the device under test (or, equivalently, by a test case which may, for example, be executed on the device under test). By providing the one or more tester resources with such a trigger mechanism, it is possible to achieve a very fast reaction time, wherein it is possible to pre-program a desired new values (to which the test resource should be switched in response to the activation of the trigger signal) in advance, which makes the pre-programming non-time-critical. In contrast, upon activation of a trigger line (provided by the device under test, or by the test case), the test resource can then rapidly switch to a usage of one or more new signal parameters (which have been pre-programmed), wherein, for the actual execution of the update, the tester resource only needs to receive the trigger signal from the device under test (e.g., via the trigger line). Thus, the non-time-critical preprogramming of the desired new value(s), which should be used in response to the activation of the trigger line, can be separated from the time-critical activation of the trigger line. Accordingly, a very short response time can be achieved, wherein an actual triggering of an update of one or more test resources no longer needs a just-in-time transmission of desired new parameters towards the one or more tester resources.

In an embodiment, the automated test equipment comprises an on-chip-system-test controller and a test program executor and one or more test resources. In this case, the trigger line is a hardware line extending directly from a device under test interface of the automated test equipment to one or more tester resources (e.g., a device power supply, a signal generator module, a channel module, or the like) bypassing the on-chip-system-test controller and the test program executor.

Using such an approach, the update of one or more tester resources can be triggered with minimum latency, wherein the triggering of an update of one or more tester resources also does not impose any additional computational requirements onto the on-chip-system-test controller or the test program executor. Accordingly, an interruption of a functionality of the on-chip-system-test controller or of the test program executor is avoided, while the update of the one or more tester resources can be effected very rapidly.

In an embodiment, the one or more tester resources comprises one or more out of the following: a device power supply; a signal generator module and/or a channel module. It has been found that such types of tester resources are typically well-suited for a rapid update of one or more parameters and significantly determine a test environment of a device under test. Consequently, it has been found that a direct triggering of an update of one or more signal parameters of such tester resources under the direct control of the device under test is very advantageous.

In an embodiment, the one or more tester resources are coupled to a test program executor via an interface. Accordingly, it is possible for the test program executor to initialize said one or more tester resources (e.g., even before a test case is executed on the device under test). Moreover, the provision of an interface coupling the one or more tester resources with the test program executor furthermore allows the test program executor to pre-program desired updates for one or more tester resources (e.g., under the control of an ATE test program). Furthermore, by providing an interface between the tester resources and the test program executor, it may also be possible to fully control the tester resources via this interface. To conclude, it appears to be advantageous to have both an interface between the one or more tester resources and the test program executor and a trigger line extending directly between the one or more tester resources and the device under test interface.

In an embodiment, the one or more tester resources are physically separated (e.g., are different printed circuit boards or are different exchangeable modules) from the test program executor (and y also physically separated from the OCST controller).

Using such a physically separated and modular concept, the automated test equipment can be flexibly adjusted to the specific testing needs. Moreover, by separating the different functionalities into components which are physically separated, distortions of the signal integrity can be kept reasonably small. Moreover, it should be noted that the test program executor is typically adapted to control a plurality of significantly different tester resources (like, for example, one or more device power supplies and one or more analog channel modules and one or more digital channel modules), wherein the number of tester resources typically varies between different applications. Accordingly, it is highly recommendable to have, for example, one test program executor which is coupled to multiple different tester resources (e.g., one or more device power supplies and one or more channel modules, like, for example, analog channel modules and/or digital channel modules). In such a system configuration, the bypassing of the test program executor using one or more trigger lines which extend directly from the device under test interface to the one or more tester resources is particularly efficient, since the test program executor may simultaneously be involved in tasks relating to a plurality of different tester resources and may therefore be subject to significant latency.

An embodiment according to the invention creates a device under test. The device under test is configured to provide to an automated test equipment a trigger signal to thereby trigger an update of one or more test resources, via a dedicated trigger line (wherein, for example, the device under test may be under the control of a test case). By providing the device under test with the ability to directly trigger an update of one or more tester resources using an activation of a trigger line, a latency for effecting a resource update can be minimized and the resource update can be effected with small effort. For example, in such a concept, it is possible to trigger an update of one or more test resources under the control of the device under test and the triggering of the resource update is possible with very small software and hardware effort, since it is only needed for the device under test to change a status of the dedicated trigger line. However, it is not necessary for the device under test to use, for example, a protocol based communication, which may require a complex driver and which may also often be subject to latencies and a lack of real-time capabilities. Thus, a test case which may be executed on the device under test has a very high degree of control over the test environment with minimum latency and without requiring a device driver overhead.

In an embodiment, the device under test is configured to provide the trigger signal under the control of a test case which is executed by the device under test (e.g., using one or more programmable processor devices and/or using one or more microprocessor cores). Using such an approach, an “intelligent” device under test, which is capable to execute a test case, can trigger an update of one or more tester resources under the control of the test case executed by the device under test. However, for triggering the update of one or more tester resources, said test case may only require a very simple command, like a command for changing a state of a single output pin of the device under test which is coupled to the trigger line (an outputs the trigger signal). Thus, the device under test has a very direct low-latency impact onto an update of the test resources.

In an embodiment, the device under test is configured to provide a command defining one or more parameters for the update of the one or more test resources to the automated test equipment (e.g., via a common interface which is different from the dedicated trigger line) (e.g., to initiate a pre-definition of a response of the one or more tester resources to an activation of the trigger line). Moreover, the device under test is configured to provide (e.g., to the automated test equipment; e.g., directly to a tester resource) the trigger signal (e.g., via a dedicated trigger line), to thereby trigger an update of one or more tester resources using the one or more parameters.

By using such a two-step mechanism, the device under test can use an appropriate interface (e.g., a protocol-based high speed interface) for transmitting the typically not particularly time critical command defining the one or more parameters for the update of the one or more test resources to the automated test equipment. For example, the command defining one or more parameters for the update of the one or more tester resources may be sent to the automated test equipment by the device under test well in advance of an actual update of the one or more tester resources. For example, the command defining one or more parameters for the update of one or more tester resources may even be transmitted to the automated test equipment right after triggering of a previous update of the one or more tester resources, such that there is sufficient time both for the transmission of the command to the automated test equipment using a protocol-based interface and for the handling of said command by the automated test equipment (wherein the handling of the command by the automated test equipment may, for example, comprise a parsing of the command by the test program executor and a preprogramming of one or more tester resources of the automated test equipment by the test program executor). Moreover, the actual time-critical triggering of the update of the one or more tester resources may then be effected by the provision (or activation) of the trigger signal (e.g., via the dedicated trigger line), which helps to maintain the latency low and to also avoid a (high-priority) interruption of the test program executor of the automated test equipment. Consequently, the concept to provide the command defining one or more parameters for the (upcoming) update of one or more tester resources to the automated test equipment separate from the actual triggering of the update of the one or more tester resources provides a good compromise between efficiency and latency.

An embodiment according to the invention creates a test setup, wherein the test setup comprises the automated test equipment as described before and the device under test as described before.

An embodiment according to the invention creates a method for operating an automated test equipment, which comprises a trigger line (e.g., a hardware trigger line; e.g., the GPO-trigger-line) that is controllable by the device under test (or, equivalently, by a test case which may, for example, be executed on the device under test). The method comprises updating one or more tester resources (e.g., changing one or more supply voltages provided to the device under test by the automated test equipment, or changing one or more signal characteristics of one or more analog or digital signals provided to the device under test by the automated test equipment) in response to an activation of the trigger line by the device under test (or, equivalently, by the test case which may, for example, be executed on the device under test).

This method for operating an automated test equipment is based on similar considerations as the above described automated test equipment. Moreover, it should be noted that the method for operating an automated test equipment may optionally be supplemented by any of the features, functionalities and details described herein (also with respect to the automated test equipment), both individually and taken in combination.

Another embodiment according to the invention creates a method for testing a device under test. The method comprises pre-programming (e.g., under the control of an automated test equipment) one or more tester resources to one or more respective parameter values, which are to be taken over in response to a trigger signal, using a test program executor. The method comprises providing a trigger signal, which causes the one or more tester resources to take over the pre-programmed one or more respective parameter values, directly from the device under test to one or more tester resources (e.g., bypassing the test program executor).

This method for testing a device under test is also based on similar considerations like the above described automated test equipment and the above described device under test. Accordingly, the method may optionally be supplemented by any of the features, functionalities and details described herein both with respect to an automated test equipment and with respect to a device under test. The method may optionally be supplemented by such features, functionalities and details both individually and taken in combination.

Yet another embodiment according to the invention creates a computer program for performing said methods when the computer program runs on one or more computers and/or on one or more microprocessors and/or on one or more microcontrollers.

Yet another embodiment according to the present invention creates an automated test equipment for testing a device under test. The automated test equipment comprises a trigger line (e.g., a hardware trigger line; e.g., the GPO-trigger-line) which is controllable by a test case (which may, for example, be executed on the device under test, but which may, alternatively, by executed partly on the device under test and partly on the automated test equipment). The automated test equipment is configured to update one or more test resources (e.g., to change one or more supply voltages provided to the device under test by the automated test equipment, or to change one or more signal characteristics of one or more analog or digital signals provided to the device under test by the automated test equipment) in response to an activation of the trigger line by the test case.

This embodiment is based on similar considerations as the above described automated test equipment, wherein it should be noted that, in the present embodiment, the trigger line is controllable by the test case (such that the test case takes the role of the device under test) (e.g. independent from the question how the test case is distributed between the device under test and the automated test equipment).

Moreover, it should be noted that this automated test equipment may optionally be supplemented by any of the features, functionalities and details described herein, also with respect to other automated test equipment. The automated test equipment may be supplemented by such features, functionalities and details both individually and taken in combination.

Yet another embodiment according to the invention is directed to a method for operating an automated test equipment, which comprises a trigger line (e.g., a hardware trigger line; e.g., the GPO-trigger-line) that is controllable by a test case (which may, for example, be executed on the device under test, or which may be distributed between the device under test and the automated test equipment). The method comprises updating one or more test resources (e.g., changing one or more supply voltages provided to the device under test by the automated test equipment, or changing one or more signal characteristics of one or more analog or digital signals provided to the device under test by the automated test equipment) in response to an activation of the trigger line by the test case (which may, for example, be executed on the device under test, or which may be distributed).

This method for operating an automated test equipment is based on similar considerations like the other method for operating an automated test equipment described herein. However, it should be noted that the test case takes over the functionality of the device under test. Moreover, it should be noted that the method for operating an automated test equipment may optionally be supplemented by any of the features, functionalities and details disclosed herein with respect to an automated test equipment and also with respect to a device under test. The method may optionally be supplemented by such features, functionalities and details both individually and taken in combination.

An embodiment according to the invention creates a method for testing a device under test. The method comprises pre-programming (e.g., under the control of an automated test equipment) one or more tester resources to one or more respective parameter values, which are to be taken over in response to a trigger signal, using a test program executor. Moreover, the method comprises providing a trigger signal, which causes the one or more tester resources to take over the pre-programmed one or more respective parameter values, directly from a test case to one or more tester resources (e.g., bypassing the test program executor).

This method for testing a device under test is similar to the above described method for testing a device under test, wherein the test case takes the role of the device under test. Moreover, it should be noted that the method may optionally be supplemented by any of the features, functionalities and details described herein with respect to an automated test equipment and with respect to a device under test. The method may optionally be supplemented by these features both individually and taken in combination.

Another embodiment according to the invention creates a computer program for performing the methods described here when the computer program runs on one or more computers and/or on one or more microprocessors and/or on one or more microcontrollers.

An embodiment according to the invention creates an automated test equipment for testing one or more devices under test. The automated test equipment is configured to receive, from a device under test, a command (e.g., in the form of a message) requesting a measurement of one or more physical quantities (e.g., of a supply voltage provided to the device under test, e.g., of a current supplied to the device under test, e.g., of a signal characteristic of a signal provided by the device under test, e.g., a signal characteristic of a signal provided to the device under test, e.g., of a clock frequency of a clock signal provided to the device under test, e.g., of an environmental parameter like a temperature, a humidity, an air pressure, an electric or magnetic field in an environment of the device under test, or the like). Moreover, the automated test equipment is configured to perform or initiate the measurement of the one or more physical quantities in response to the command provided by the device under test. Moreover, the automated test equipment is configured to provide a measurement result signaling (e.g., an acknowledge message) to the device under test to thereby signal a measurement result requested by the device under test.

Using such a concept, a device under test, or, equivalently, a test case which is executed on the device under test, has control over the execution of one or more measurements and may further process the measurement result, since the measurement result is provided to the device under test (or, equivalently, to the test case) using the measurement result signaling. Consequently, the device under test can control an execution of a test to a large degree, including measurements to be performed for characterizing the functionality or performance of the device under test. Consequently, a verification engineer designing a test may add program instructions to a test case to be executed on a device under test which cause the provision of one or more commands requesting a measurement of one or more physical quantities by the automated test equipment and may also place instructions into a test case to be executed on the device under test for evaluating one or more measurement results (which are provided to the device under test by the automated test equipment using a measurement result signaling). Consequently, most steps of a test can be controlled by the device under test (or by the test case which is executed on the device under test), which means that a verification engineer can focus on the development of the test case to be executed on the device under test and does not need to focus on the development of an ATE test program to be executed on the automated test equipment. For example, using the concept disclosed here, it may not be necessary for a verification engineer to adapt the test program to be executed on the automated test equipment in order to execute a measurement at a certain point of the execution of the test case. Rather, the ATE test program may merely define a standard response (e.g. in a predefined format) to a command provided by the device under test, wherein said standard response may, for example, comprise an appropriate control of the physical tester resources to execute a measurement and the provision of the measurement result signaling. Consequently, the device under test (or, equivalently, the test case which is executed on the device under test) may request a measurement of one or more physical quantities whenever this is appropriate in view of the progress of the execution of the test case on the device under test, and the device under test (or the test case which is executed on the device under test) may protocol and/or evaluate the measurement results. For example, the device under test may even use the measurement results to make decisions about the further execution of the test and may, for example, vary the execution of the test case in dependence on the measurement result.

Moreover, by providing a measurement result signaling to the device under test, to thereby signal a measurement result requested by the device under test, the automated test equipment also allows for a simple time synchronization between the operation of the automated test equipment and the device under test, since the device under test can be sure that a measurement has been completed when it receives the measurement result signaling from the automated test equipment (and the device under test also knows that the measurement will not be executed before the device under test requests the measurement of the one or more physical quantities). Consequently, the mechanism disclosed here can ensure that measurements are made “at the right time”, i.e., at the right point of an execution of a test case by the device under test.

To conclude, the concept described here significantly facilitates the work of a verification engineer since a control over measurements is shifted towards the test case and also provides for a good timing synchronization between the device under test and the execution of the measurements and further gives the device under test (or the test case which is executed on the device under test) the chance to use the measurement results for a control of the test.

In an embodiment, the automated test equipment is configured to receive, from a device under test, a command in the form of a parameterized message, wherein a parameter of the message describes a physical quantity to be measured (e.g., a supply voltage, a clock frequency, a signal characteristic, an environmental characteristic, or the like). However, it has been found that the usage of a parameterized message makes it particularly easy for the verification engineer to develop a test (e.g., to develop a test case to be executed on the device under test). In particular, it has been found that parameterized messages are typically particularly well-readable for a verification engineer, and that the usage of a parameterized message is well-adapted for applications in which different physical quantities can be measured. For example, the parameter of the message may therefore designate which physical quantity is to be measured, and the parameter may also (optionally) provide additional information characterizing the measurement (for example, may define whether a filter or an averaging should be used, or may define a measurement resolution, or may define any other setting of one or more parameters of the measurement resources of the automated test equipment). Consequently, by using such a parameterized message, the device under test can define the measurement requirements in much detail.

Moreover, it should be noted that a message is typically well-suited for a transmission from a device under test to an automated test equipment, since the device under test may, for example, comprise one or more protocol based interfaces that are well-suited for the communication of messages (wherein a message may, for example, comprise a message header, a message payload, and optionally an error detection information or an error correction information and a message terminator). However, it has also been found that a parameterized message may easily be transmitted via such an interface, wherein the message, in a simple case, be encoded using an ASCII string. To conclude, it has been found that the concept, to receive a command in the form of a parameterized message from a device under test, can easily be implemented and allows for a precise definition of a measurement to be made.

In an embodiment, the automated test equipment is configured to provide the measurement result signaling in the form of a message. By providing the measurement result signaling in the form of a message, it is typically easily possible to communicate the measurement result from the automated test equipment to the device under test. For example, the device under test often comprises one or more interfaces (e.g., high speed interfaces) which are capable to receive (and decode) messages. In particular, the result information may typically be extracted in a computationally efficient manner from a message, for example using a parsing functionality. Thus, the provision of the measurement result signaling in the form of a message is well-adapted for an efficient communication of the measurement result to the device under test.

In an embodiment, the automated test equipment is configured to receive the command from the device under test (e.g., a message from the device under test) via a (protocol-based) high bandwidth interface (e.g., via a high speed interface; e.g., via a USB interface or a PCI interface or a PCI-express interface, or a PCI-express compliant interface, or a thunderbolt interface, or an Ethernet interface, or an IEEE-1394 interface, or a SATA interface or an IEEE-interface or an IEEE-1500 interface, or an IEEE-1687 interface). Alternatively or in addition, the automated test equipment is configured to provide the measurement result signaling (e.g., the measurement result message) to the device under test via a (protocol-based) high bandwidth interface (e.g., via a high speed interface; e.g., via a USB interface or a PCI interface or a PCI-express interface, or a PCI-express compliant interface, or a Thunderbolt interface, or an Ethernet interface, or an IEEE-1394 interface, or a SATA interface or an IEEE-1149 interface or an IEEE-1500 interface, or an IEEE-1687 interface).

It has been found that such high bandwidth interfaces are particularly well-suited for the transmission of the command from the device under test to the automated test equipment and for the transmission of the measurement result signaling from the automated test equipment to the device under test, because said high speed interfaces typically comprise a sufficiently small latency and a sufficiently high bandwidth. Moreover, typical devices under test inherently comprise one or more high bandwidth interfaces, wherein at least one of said high bandwidth interfaces is typically used when testing the device under test, e.g., for an upload of the test case to the device under test and/or for a download of test results from the device under test to the automated test equipment. Moreover, in many situations, at least one of the high bandwidth interfaces is also tested by the automated test equipment. Accordingly, it has been found that the functionality to communicate between the automated test equipment and the device under test, which is provided in may test arrangements anyway, can efficiently be reused for sending the command requesting measurement of one or more physical quantities from the device under test to the automated test equipment and/or for sending the measurement result signaling from the automated test equipment to the device under test. In particular, it has been found that typical high bandwidth interfaces have enough data transfer capacity to transport the command requesting the measurement of one or more physical quantities and/or the measurement result signaling in addition to other data supporting the test of the device under test (like, for example, test case data or test result data). Moreover, by using the concept to send a command requesting a measurement of one or more physical quantities from the device under test to the automated test equipment, and to also use a measurement result signaling, signaling a measurement result to the device under test, typically makes a timing of the measurement uncritical, which allows usage of a high bandwidth interface that may be protocol based and/or shared for different purposes and which may therefore bring along some timing non-determinism. To conclude, it has been found that the usage of a high bandwidth interface for requesting a measurement and/or for receiving a measurement result signaling provides a good compromise between implementation effort and timing accuracy.

In an embodiment, the automated test equipment is configured to perform the measurement of the one or more physical quantities during an execution of a test case on the device under test (e.g., a system-on-the-chip) in response to a command provided by the device under test (e.g., under the control of the test case executed by the device under test). By having a concept in which the measurement of a physical quantity is requested by the device under test, it is possible to perform the measurement in good synchronism with the execution of the test case, wherein the execution of the test case on the device under test may, for example, be non-deterministic. In other words, according to an aspect of the present invention, the automated test equipment (or the test program being executed on the automated test equipment) may not have any detailed knowledge when a measurement should be executed until the automated test equipment receives the command requesting the measurement of one or more physical quantities from the device under test. However, according to the present concept, it is not necessary to interrupt the execution of the test case on the device under test for the measurement. Rather, it is even possible to make the measurement under the control of the test case, and therefore at a time when the measurement brings along a desired result in view of the current execution status of the test case. As an example, the test case which is executed on the device under test may issue a command requesting measurement of one or more physical quantities just before it enters a phase of the test case which requires a measurement (or monitoring) of one or more physical quantities, like a current consumption or a die temperature, or the like. To conclude, by allowing the device under test to request a measurement of one or more physical quantities, it is possible to make a measurement in synchronism with an execution of a test case on the device under test without having a need to interrupt the test case, and by providing a measurement result signaling to the device under test, a test case is also well aware about the time when the measurement is completed and when the test case can proceed with another processing step. Thus, the above described concept allows for a particularly fast testing because it is no longer necessary to interrupt the execution of a test case for timing synchronization between the automated test equipment and the test case which is executed on the device under test.

In an embodiment, the automated test equipment is configured to provide an application programming interface (API) for usage by a test case which is executed on the device under test. The application programming interface is configured to provide one or more routines (e.g., methods or functions) and/or routine headers (e.g. method headers or function headers) for a transmission of commands requesting a measurement of one or more physical quantities from the device under test to the automated test equipment. Alternatively or in addition, the application programming interface is configured to provide one or more routines (e.g., methods or functions) or routine headers (e.g. method headers or function headers) for a temporal synchronization between the device under test and the automated test equipment (e.g., one or more routines or routine headers for pausing program execution (e.g., of a test case executed on the device under test) until reception of a signal indicating a measurement result).

By providing an application program interface, the development of the test case by the verification engineer can be facilitated significantly. For example, it may be sufficient that a verification engineer developing a test case merely has knowledge about the syntax of the methods or functions provided by (or represented by) the application programming interface, but the verification engineer may not need any detailed knowledge about the internals of the automated test equipment. Thus, by providing the application programming interface (e.g., in a software repository of the automated test equipment), the manufacturer of the automated test equipment may use his superior knowledge about the details of the automated test equipment to provide the application programming interface, which in turn allows the verification engineer designing the test case to access the measurement functionalities provided by the automated test equipment using simple (and possibly parametrized) function calls or method calls. Further, the application programming interface may also allow the verification engineer designing the test case to use one or more methods or functions that support the temporal synchronization between the device under test and the automated test equipment, like a function or method that waits for the measurement result signaling. Such a function may also make the measurement result available to the test case as a return value, and may therefore also support a synchronization between the measurement and the execution of the test case. Furthermore, such a function facilitates a usage of the measurement result in the further execution of the test case.

The method or functions of the application programming interface may, in this case, handle the provision of the command requesting the measurement of one or more physical quantities, and may also handle an evaluation (e.g., a parsing and/or a translation) of the measurement result signaling, to thereby provide the measurement result in a form (e.g., in a number representation) which is easy to handle by the test case.

In an embodiment, the automated test equipment comprises an on-chip-system-test (OSCT) controller and a test program executor executing a test program and one or more tester resources (e.g., one or more device power supplies, and/or one or more analog or digital signal generators, and/or one or more measurement resources). The on-chip-system-test controller is configured to receive the command (e.g., in the form of a message) requesting a measurement of one or more physical quantities from the device under test (e.g., via a high-bandwidth interface) and to forward the command (e.g., the message) to the test program executor executing a test program. Moreover, the test program comprises a message handler configured to effect (e.g., execute) a measurement of one or more physical quantities in response to the (forwarded) command (e.g., in the form of a forwarded message), for example after decoding and/or interpreting the forwarded message (and, for example, in dependence on one or more parameters included in the forwarded message).

Using such a concept, the OCST controller may, for example, handle the communication between the device under test and the automated test equipment, wherein the on-chip-system-test controller may, for example, have dedicated processing means (e.g., dedicated hardware) which is specifically adapted for a high speed communication with the device under test. Moreover, the on-chip-system-test controller may also comprise additional functionalities which support the testing of a system-on-chip like, for example, the functionality to upload a test program (or a test case) to the device under test and to download test results from the device under test. Moreover, the on-chip-system-test controller may also comprise additional functionalities that allow for an evaluation of test results provided by the device under test. The on-chip-system-test controller may be configured to efficiently handle a real-time (but typically non-deterministic or protocol-based) communication with the device under test, and may therefore be well-suited for exchanging data with the on-chip system. On the other hand, the test program executor may be configured to execute an ATE test program and may, for example, be closely linked (or be in direct communication) with the tester resources, like one or more device power supplies, and/or one or more digital channel modules, and/or one or more analog channel modules and/or one or more measurement instruments (wherein it is not necessary to have all of these components, and wherein the measurement instruments may, for example, be part of the analog channel modules or of the digital channel modules or of the device power supplies).

For example, the test program executor may comprise a test program which can interpret the command requesting a measurement of one or more physical quantities and which can cause a proper measurement resource or measurement instrument to make the requested measurement. For example, a portion of the ATE test program (which is executed on the test program executor) that is responsible for the interpretation and execution of the commands, may be independent from the program code of the test case, and may therefore remain equal for different test cases. Accordingly, using such a concept, there may be an efficient sharing of functionalities between the on-chip system test controller and the test program executor. The on-chip-system-test controller may, for example, be used for (possibly) non-deterministic tasks which should be executed in a real time or with very high speed, while the test program executor may take over closer control over the other tester resources (like device power supplies, analog channel modules, digital channel modules and measurement resources) and may execute a typically freely configurable ATE test program that may, for example, define the test environment for the device under test (like, for example, one or more supply voltages, one or more clock signals, one or more predefined input signals, and the like). Accordingly, the test can be executed in an efficient manner, wherein the on-chip system test controller can act as an intermediator between the device under test and the test program executor.

In an embodiment, the message handler (which may be part of the test program) is configured to translate a command (e.g., a message) comprising a symbolic reference (e.g., “VCC2”) of a test resource (e.g., of a supply voltage or of a signal) into a tester-hardware-related measurement instruction (e.g., into an instruction effecting a measurement of a voltage or of a temperature or a signal characteristic).

By using such a command translation that makes use of a symbolic reference, an engineer can use an easy-to-understand symbolic reference in his test program, while the message handler translates this command to a tester-hardware-rated measurement instruction. Accordingly, the verification engineer programming the test case does not need to have any knowledge of internals of the automated test equipment, and can use the symbolic reference in an efficient manner, wherein it should be noted that usage of a symbolic reference is typically much less error-prone than a specification of a specific hardware resource of the automated test equipment. In contrast, the message handler can be adapted (e.g., by an engineer who is well aware of the internal physical details of the automated test equipment) to make an allocation between a symbolic reference and the physical tester hardware associated with said symbolic reference in a current tester configuration (e.g., taking into consideration both the physical resources of the automated test equipment and a connection of the ATE's physical resources with specific pins (or pads) of a device under test.

Using such a concept, a test case may be usable on different tester hardware since it uses commands comprising a symbolic reference, while only the message handler should be adapted to the specific hardware (e.g., to the available tester resources and to the connection between the ATE hardware and the device under test pins). Consequently, high efficiency of the test case development can be reached.

In an embodiment, the message handler is configured to generate the measurement result message and to provide the generated measurement result message to the on-chip-system-test controller (e.g., after an execution of the measurement). Moreover, the on-chip-system-test controller is configured to forward the measurement result message provided by the message handler to the device under test, or to provide a measurement result message to the device under test in response to the measurement result message provided by the message handler. Using such a concept, the ability of the on-chip system test controller to efficiently communicate with the device under test (e.g., using a protocol-based high speed interface) can be exploited, while the measurement result message is generated (or effected) by the message handler that typically comprises a more direct access to the tester resources (e.g., to a measurement resource). Thus, the measurement result can be communicated to the device under test (or to the test case which is executed on the device under test) in a very efficient manner, wherein the on-chip-system-test controller may either forward the measurement result in an unchanged manner or may apply some message translation to adapt the measurement result message (e.g., to the requirements of the specific high speed interface being used). Thus, a very resource efficient concept can be achieved.

In an embodiment, the automated test equipment (e.g., a test program executor of the automated test equipment) is configured to execute a test program. The test program is configured to initialize tester resources of the automated test equipment, to allow for a start of a program execution on the device under test. Moreover, the test program is configured to effect further updates of the test resources under the control of the device under test (e.g., under the control of one or more test cases executed on the device under test). Alternatively, the test program is configured to effect one or more measurements under the control of the device under test (e.g., under the control of one or more OCST test cases executed on the device under test).

Using such a concept, the test program (i.e., the ATE test program which may, for example, be executed on the test program executor of the automated test equipment) can take over multiple functionalities. The test program can pre-configure the tester resources of the automated test equipment to allow for a reliable startup of the device under test, for example by setting the power supplies to provide a supply voltage that allows for a very reliable operation of the device under test. Accordingly, the test program that is executed on the test program executor of the automated test equipment can support a safe upload of a test case to the device under test by providing reliable conditions.

Moreover, the test program may, for example, control (or at least support) an initialization of the device under test and optionally also an upload of an initial program code which may, for example, allow for an establishment of a communication between the device under test and the on-chip system test controller using a high speed interface. By effecting further updates of the test resources under the control of the device under test, the test environment of the device under test may, for example, be changed to be more “challenging” than the initial test environment, to thereby execute a test case under “stress” conditions. By allowing the further updates of the test resources under the control of the device under test, the tests can be defined predominantly by the test case which is executed on the device under test, which brings along significant advantages in the test development. Moreover, the update of the test resources (and consequently the update of the test environment) under the control of the device under test allows for a good coordination between the execution of the test case on the device under test and the variation of the test environment without requiring a modification of the ATE test program by the verification engineer defining the test. Moreover, by optionally providing the device under test (or the test case) with control both over updates of the test environment and over measurements to be performed by resources of the automated test equipment, the test case to be executed by the device under test can control a very large portion of all functionalities required for a thorough test of a device under test. Thus, a design of a test becomes particularly easy. Moreover, there is an efficient sharing of the functionalities between the ATE-sided test program and the test case to be executed on the device under test.

In an embodiment, the automated test equipment comprises an on-chip system test controller. The automated test equipment comprises one or more tester resources, e.g., one or more device power supplies, and/or one or more analog or digital signal generators and/or one or more measurement resources. The on-chip system test controller is coupled (e.g., directly coupled; e.g., coupled in a manner bypassing the test program executor) to one or more tester resources. Moreover, the on-chip system test controller is configured to provide control signals (e.g., via data bus and/or via one or more synchronization lines and/or via a synchronization bus) to one or more tester resources, in order to effect a measurement of one or more physical quantities in response to a command from the device under test.

Using such a configuration, in which the on-chip system controller has direct access (bypassing the test program executor) to the tester resources, a measurement can be effected particularly fast and without disturbing an execution of an ATE test program that is executed by the test program executor. Using such a concept, the functionality of the on-chip system test controller to perform a protocol-based high speed communication with the device under test in an efficient manner (e.g., using dedicated hardware) can be exploited. By providing the on-chip system test controller with the ability to directly control one or more tester resources, e.g., one or more measurement resources, a delay that would be caused by the test program executor can be avoided. Moreover, it can also be avoided to disturb the operation of the test program executor by the command requesting a measurement of one or more physical quantities, such that the test program executor can more efficiently handle its task to evaluate test results. Consequently, a faster and more resource efficient execution of a test can be achieved.

In an embodiment, the on-chip system test controller is configured to translate a command (e.g., a message) comprising a symbolic reference (e.g., “VCC2”) of (or to) a tester resource (e.g., of a supply voltage or of a signal) into a tester-hardware related measurement instruction (e.g., into an instruction effecting a measurement of one or more physical quantities by a measurement resource of the automated test equipment).

Providing the on-chip system test controller with the functionality to translate a command comprising a symbolic reference into a tester-hardware-related measurement instruction allows for a tester-hardware-agnostic development of a test case to be executed on the device under test. By using symbolic references in the commands transmitted from the device under test to the automated test equipment, the test case can be used on different hardware configurations of an automated test equipment, wherein the mapping from a symbolic reference to an actual physical resource of the tester (ATE) may be defined once for a current tester configuration, and may be provided to the on-chip system test controller as a configuration information. Consequently, the usage of automated test equipment having different hardware configurations is easily possible without adapting the test case.

In an embodiment, the on-chip-system-test controller is coupled with one or more tester resources via a data bus and a synchronization line or a synchronization bus. Moreover, the on-chip-system-test controller is configured to prepare (e.g., initialize) a measurement (e.g., a voltage measurement or a current measurement or a temperature measurement) of a selected physical quantity (e.g., a supply voltage or a supply current or an environment temperature) via the data bus in dependence on a message parameter (e.g., a message parameter defining the physical quantity to be measured) of the command received from the device under test (e.g., in order to define an upcoming characteristic of the selected tester resources or of an upcoming measurement). Moreover, the on-chip system test controller is configured to trigger a measurement of the physical quantity to be measured by a synchronization bus or by a synchronization line (e.g., using a synchronization bus event or a synchronization bus message).

Using such a concept, the on-chip-system-test controller can perform a measurement with high timing accuracy. By preconfiguring the measurement of a selected physical quantity, the settings of a measurement resource can be prepared such that the measurement resource can react very quickly to a triggering of the measurement. Accordingly, the on-chip system test controller may first initialize a measurement resource in accordance with the message parameter (wherein the message parameter may, for example, determine which voltage should be measured and/or which filtering or averaging should be used in such a measurement), and the actual measurement may then be triggered by the on-chip-system-test controller with high timing accuracy. Accordingly, the device under test may even be able to request a certain measurement timing, wherein the on-chip-system-test controller may first preconfigure the measurement (for example, by setting the respective measurement resource to a proper state or configuration) and may then trigger the measurement resource with the desired timing. Accordingly, a very accurate measurement, which fits the requirements defined in the test case, can be made.

In an embodiment, the on-chip-system-test controller is configured to provide the measurement result signaling (e.g., in the form of a measurement result message) to the device under test. By having the functionality to provide the measurement result signaling to the device under test implemented within the on-chip-system-test controller, high efficiency and a short latency can be reached.

An embodiment according to the invention creates a device under test. The device under test is configured to provide an automated test equipment with a command (e.g., in the form of a message) requesting measurement of one or more physical quantities (e.g., under the control of a test case which is executed on the device under test). Moreover, the device under test is configured to wait for a reception of a measurement result signaling (e.g., a measurement result message), indicating a measurement result requested by the device under test (e.g., by pausing an execution of a test case until the measurement result requested by the device under test is received by the device under test). Such a device under test can efficiently control measurements of one or more physical quantities and in addition time synchronize the execution of a test case with such a measurement. By waiting for the measurement result signaling, indicating a measurement result requested by the device under test, the device under test can avoid to proceed with a test execution (which could, for example, falsify a test result) before the measurement result is actually obtained. Thus, such a procedure allows to obtain reliable measurement results under the control of the device under test, even though there may be no perfect timing synchronization between the execution of a test case on the device under test and the automated test equipment. For example, the device under test may maintain a condition, under which the measurement is to be made, until the device under test receives the measurement result signaling, and can consequently be assured that the measurement result is valid.

Thus, reliable measurements can be made even though there is no perfect timing synchronization mechanism between the device under test and the automated test equipment (which may be true for many systems-on-the-chip which do not comprise a strict timing determinism).

In an embodiment, the device under test is a system-on-the-chip. The device under test is configured to execute a test case (e.g., performing a test for testing the device under test). Moreover, the device under test is configured to provide the command to the automated test equipment under the control of the test case. It has been found that the concept disclosed here is particularly well-suited for a testing of a system-on-the-chip, which is capable to execute a test case, e.g., using one or more internal processors or processor cores. In particular, it has been found that a test case is well-suited for providing the command to the automated test equipment, since the test case typically has access to one or more high speed interfaces, e.g., using an underlying interface driver.

In an embodiment, the device under test is configured to provide the command in the form of a parameterized message, wherein a parameter of the message describes one or more physical quantities to be measured, e.g., a supply voltage, a supply current, a clock frequency, a signal characteristic, an environmental parameter, or the like.

By using a parameterized message, the advantages mentioned above can be achieved. In particular, the usage of a parameterized message makes it easy for the verification engineer to write a test program, since the verification engineer can use one or more parameters to describe which physical quantity is to be measured, and optionally also to describe with measurement setting (e.g., measurement range, averaging operation, filtering operation, and so on) is to be applied when performing the measuring. Moreover, by using a parameter which may, for example, define the quantity to be measured (e.g., a certain voltage at a certain pin of the device under test, or a certain current flowing into a certain pin of the device under test, or the like), the command set can be kept small and the actually measured quantity can rather be described by a parameter. This allows for a very “readable” code, and this allows for an efficient communication between the device under test and the automated test equipment (wherein, for example, an on-chip-system-test controller or a test program executor may evaluate the command and the parameter described therein). Moreover, it should be noted that the usage of a message is particularly well-suited for a transmission via a (e.g., protocol-based) high speed interface, since many high speed interfaces are typically well-suited for the transmission of messages (wherein a message may, for example, comprise a message header, a message data payload, which may comprise a message identifier and the parameters, and optionally an error detection information or an error correction information and optionally a message terminator). Such well-defined messages can typically be easily transmitted via a high speed interface, wherein a respective interface driver, that may be present on the device under test, can support the message transmission. Thus, a very efficient concept is provided.

In an embodiment, the device under test is configured to receive the measurement result signal in the form of a message. As mentioned before, messages are well-suited for communication over (e.g., protocol-based) high speed interfaces, such that a fast communication is possible over an interface that may also be shared for other functionalities (e.g., for an upload of a test case to the device under test and/or for a download of test results from the device under test to the automatic test equipment).

By evaluating a measurement result signal in the form of a message, the message can be detected, for example, by a parsing of the information incoming towards the device under test. Since a message is used, which is typically characterized by a message header, the message signaling the measurement result may, for example, be easily distinguished from other incoming information. Thus, reception of a measurement result signaling in the form of a message has been found to be very advantageous, since a message parsing can be achieved with a moderate effort.

In an embodiment, the device under test is configured to provide the command to the automated test equipment (e.g., a message to the automated test equipment) via a (protocol-based) high bandwidth interface (e.g., via a high speed interface; e.g., via a USB interface, or a PCI interface, or a PCI-express interface or a PCI-express compliant interface, or a Thunderbolt interface, or an Ethernet interface, or an IEEE-1394 interface, or a SATA interface, or an IEEE-1149 interface, or an IEEE-1500 interface, or an IEEE-1687 interface, or the like). Alternatively or in addition, the device under test is configured to receive the measurement result signaling (e.g., the measurement result message) (e.g., from the automated test equipment) via a (protocol-based) high bandwidth interface (e.g., via a high speed interface; e.g., via a USB interface, or a PCI interface, or a PCI-express interface, or a PCI-express compliant interface, or a Thunderbolt interface, or an Ethernet interface, or an IEEE-1394 interface, or a SATA interface, or an IEEE-1149 interface, or an IEEE-1500 interface, or an IEEE-1687 interface).

Usage of such interfaces brings along the above-discussed advantages. In particular, provision of the command to the automated test equipment via such a high bandwidth interface and/or reception of the measurement result signaling via such a high bandwidth interface allows for a very fast communication and, in addition, allows for a reuse of said high bandwidth interface, which is typically also used for other purposes, like for an update of a test case to the device under test or for a provision of the test result data to the automated test equipment. Moreover, the high bandwidth interface typically has sufficient bandwidth to transmit the measurement-related information (e.g., the command requesting a measurement and the measurement result signaling) in addition to other payload. Moreover, high bandwidth interfaces are often capable to mix different types of payload (e.g., to interpose a short message into other data communication processes). Consequently, an efficient usage of the available resources of the device under test is possible. Moreover, the high bandwidth character of the interface typically also results in comparatively low latencies, which is advantageous for the triggering of a measurement and helps to shorten test time.

In an embodiment, the device under test is configured to use one or more library routines (e.g., of a software library provided by the automated test equipment) (usage of which may, for example, be enabled by an application programming interface, which is provided by the automated test equipment), in order to provide the command and/or in order to evaluate the measurement result signaling.

Usage of one or more library routines in order to provide the command and/or in order to evaluate the measurement result signaling brings along the above discussed advantages and significantly facilitates the development of a test case to be executed on the device under test. Also, error risks are reduced.

In an embodiment, the device under test is configured to continue a test case execution in dependence on the measurement result indicated by the measurement result signaling (e.g., by selectively branching in dependence on the measurement result).

Accordingly, execution of the test case can be made dependent on the actual measurement result, which may, for example, help to identify a maximum rating of a device under test. For example, if a certain test case results in an excessive current consumption or in an excessive heating of the device under test, the subsequent test may be executed with a reduced processing load in order to avoid an over-stressing of the device under test. Thus, the device under test or, equivalently, the test case being executed on the device under test can efficiently consider the measured results and adapt its test case execution accordingly.

An embodiment according to the invention creates a test set up. The test set up comprises an automated test equipment as discussed before and the device under test discussed before. The test set up is based on the same considerations as the above-discussed automated test equipment and the above-discussed device under test. The test set up may optionally be supplemented by any of the features, functionalities and details disclosed herein both with respect to the automated test equipment and with respect to the device under test. The test set up may optionally be supplemented by these features or functionalities or details both individually and taken in combination.

An embodiment according to the invention creates a method for operating an automated test equipment. The method comprises receiving, from a device under test, a command (e.g., in the form of a message) requesting a measurement of one or more physical quantities. The method further comprises performing or initiating the measurement of the one or more physical quantities in response to the command provided by the device under test. Moreover, the method comprises providing a measurement result signaling (e.g., a measurement result message) to the device under test, to thereby signal a measurement result requested by the device under test. This method is based on the same considerations like the above-described automated test equipment. Moreover, the method may optionally be supplemented by any of the features, functionalities and details disclosed herein, also with respect to the automated test equipment. The method may be supplemented by such features, functionalities and details both individually and taken in combination.

An embodiment according to the invention creates a method for testing a device under test. The method comprises providing a command (e.g., in the form of a message) requesting a measurement of one or more physical quantities (e.g., under the control of a test case which is executed on the device under test) from a device under test to an automated test equipment under the control of a test case running on the device under test. Moreover, the method comprises pausing (e.g., under the control of the test case) an execution of the test case until a measurement result signaling (e.g., a measurement result signal or a measurement result message), indicating a measurement result requested by the device under test, is received by the device under test (and, for example, detected by the test case). Moreover, the method comprises performing a measurement of the one or more physical quantities in response to the command provided by the device under test. Furthermore, the method comprises providing a measurement result signaling (e.g., a measurement result message) to the device under test, to thereby signal a measurement result requested by the device under test. Furthermore, the method comprises continuing an execution of the test case in response to a reception of the measurement result signaling by the device under test.

This method is based on the same considerations as the above-described automated test equipment and the above-described device under test. The method may optionally be supplemented by any of the features, functionalities and the details disclosed herein with respect to the automated test equipment and also with respect to the device under test. The method may optionally be supplemented by such features, functionalities and details both individually and taken in combination.

Another embodiment according to the invention creates a computer program for performing such a method.

Yet another embodiment according to the invention creates an automated test equipment for testing one or more devices under test. The automated test equipment is configured to receive, from a test case, a command, (e.g., in the form of a message) requesting a measurement of one or more of the physical quantities (e.g., of a supply voltage provided to the device under test, e.g., of a current supplied to the device under test, e.g., of a signal characteristic of a signal provided by the device under test, e.g., of a signal characteristic of a signal provided to the device under test, e.g., of a clock frequency of a clock signal provided to the device under test, e.g., of an environmental parameter, like a temperature, a humidity, an air pressure, an electric or magnetic field, in an environment of the device under test, or the like). Moreover, the automated test equipment is configured to perform or initiate a measurement of the one or more physical quantities in response to the command provided by the test case. Furthermore, the automated test equipment is configured to provide a measurement result signaling (e.g., an acknowledgement message) to the test case, to thereby signal a measurement result to the test case.

This automated test equipment is based on the same considerations like the above-described automated test equipment, wherein the test case takes over the role of the automated test equipment. However, it should be noted that the test case may be executed on the device under test, but may also be distributed between the device under test and the automated test equipment. Moreover, this automated test equipment may optionally be supplemented by any of the features, functionalities and details disclosed herein with respect to other automated test equipment. The automated test equipment may be supplemented by such features, functionalities and details both individually and taken in combination.

Another embodiment according to the invention creates a method for operating an automated test equipment. The method comprises receiving, from a test case (which may, for example, be executed on a device under test, but which may also be distributed between the device under test and the automated test equipment), a command (e.g., in the form of a message) requesting a measurement of one or more physical quantities. The method further comprises performing or initiating the measurement of the one or more physical quantities in response to the command provided by the test case. Moreover, the method comprises providing a measurement result signaling (e.g., a measurement result message) to the test case, to thereby signal a measurement result requested by the test case.

This method is based on the same considerations like the above-described method, wherein the test case takes the place of the device under test. The method may optionally be supplemented by any of the features, functionalities, and details both individually and taken in combination.

Yet another embodiment according to the invention creates a respective computer program.

### BRIEF DESCRIPTION OF THE DRAWINGS

Embodiments of the present invention will be detailed subsequently referring to the appended drawings, in which:

FIG. 1a shows a schematic representation of an automated test equipment, according to an embodiment of the present invention;

FIG. 1b shows a schematic representation of a device under test, according to an embodiment of the present invention;

FIG. 2a shows a schematic representation of an automated test equipment, according to an embodiment of the present invention;

FIG. 2b shows a schematic representation of a device under test, according to an embodiment of the present invention;

FIG. 2c shows a schematic representation of an automated test equipment, according to an embodiment of the present invention;

FIG. 3a shows a schematic representation of an automated test equipment, according to an embodiment of the present invention;

FIG. 3b shows a schematic representation of a device under test, according to an embodiment of the present invention;

FIG. 4 shows a schematic representation of an on-chip-system-test (OCST)/functional test upload and control by test pattern;

FIG. 5 shows a schematic representation of an on-chip-system-test (OCST)/functional test upload and control by high speed input/output (IO);

FIG. 6 shows a schematic representation of a variant by using a separate controller for OCST/functional test;

FIG. 7 shows a schematic representation of an on-chip-system-test (OCST) extended by a tester resource control path, according to an embodiment of the present invention;

FIG. 8 shows a schematic representation of a variant including an OCST-controller to include a tester resource control path, according to an embodiment of the present invention;

FIG. 9 shows a graphical representation of a message flow for tester resource control, according to an embodiment of the present invention;

FIG. 10 a schematic representation of OCST extended by a tester resource measurement path, according to an embodiment of the present invention;

FIG. 11 shows a schematic representation of a variant including OCST-controller to include a tester resource control path, according to an embodiment of the present invention;

FIG. 12 shows a graphical representation of a message flow for tester resource measurement, according to an embodiment of the present invention;

FIG. 13 shows a schematic representation of production tester controlled by an on-chip-system-test, according to an embodiment of the present invention;

FIG. 14 shows a schematic representation of production tester controlled by an on-chip-system-test, according to an embodiment of the present invention;

FIG. 15 shows a schematic representation of a scenario in which the functional test case is fully located on the DUT, according to an embodiment of the present invention;

FIG. 16 shows a schematic representation of a scenario in which the functional test is logically split into a DUT- and work station-part according to an embodiment of the present invention;

FIG. 17 shows a schematic representation of a concept comprising library support ATE-environment control, according to an embodiment of the present invention;

FIG. 18 shows a schematic representation of a resource controlled by a data- and synchronization-bus, according to an embodiment of the present invention; and

FIG. 19 shows a schematic representation of a tester resource controlled by GPO-trigger, according to an embodiment of the present invention.

### DETAILED DESCRIPTION OF THE INVENTION

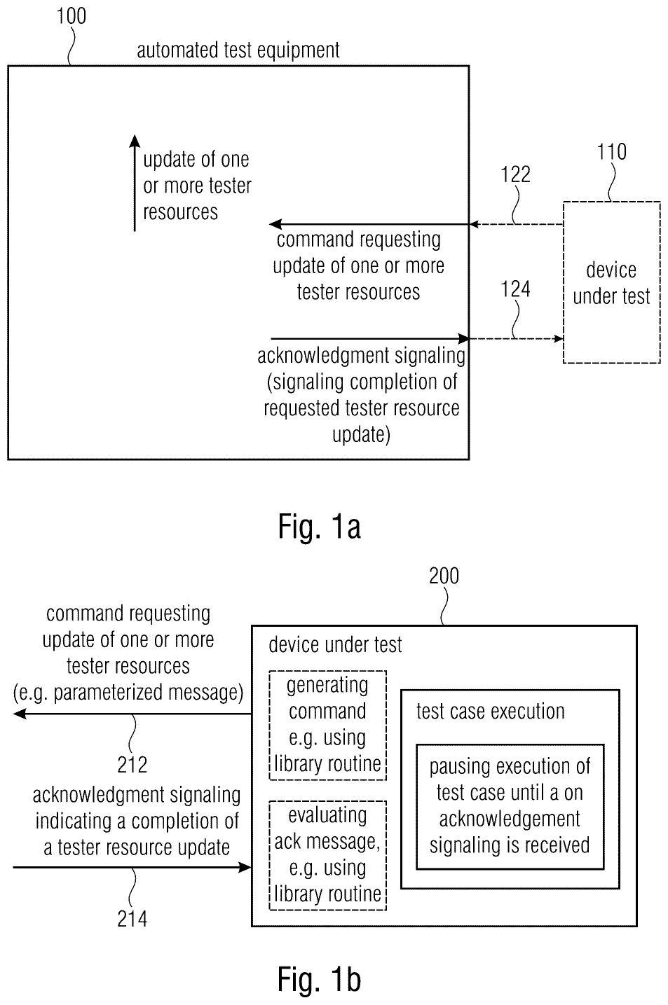

### 1. Automated Test Equipment According to FIG. 1a

FIG. 1a shows a schematic representation of an automated test equipment, according to an embodiment of the present invention.

The automated test equipment shown in FIG. 1a is designated with 100. The automated test equipment is typically intended to be coupled with a device under test 110. The automated test equipment 100 is configured to receive, from the device under test 110 (or, equivalently, from a test case) a command 122 requesting an update of one or more tester resources. Moreover, the automated test equipment is configured to update one or more tester resources in response to the command 122 provided by the device under test 110. Moreover, the automated test equipment is configured to provide an acknowledge signaling 124, to thereby signal a completion of a test resource update requested by the device under test 110.

The automated test equipment 100 therefore allows the device under test 110 to exercise control over one or more tester resources by providing a command 122 requesting an update of one or more tester resources. Thus, the device under test 110 can issue a command that causes the automated test equipment to change a parameter of a tester resource, e.g., to change a supply voltage of the device under test 110 or to change a characteristic of another signal provided to the device under test 110 at the request of the device under test. Moreover, the automated test equipment 100 also provides an acknowledgment signaling 124 to the device under test, such that the device under test 110 is well-informed about the execution of the update of the one or more test resources. Thus, the device under test 110 can use the acknowledgement signaling 124 to decide when to continue a test execution which may require the requested update of the one or more tester resources for a proper execution. Accordingly, a reliable testing can be performed under the control of the device under test.

Moreover, it should be noted that the automated test equipment 100 may optionally be supplemented by any of the features, functionalities and details disclosed herein, both individually and taken in combination.

### 2. Device Under Test According to FIG. 1b

FIG. 1b shows a schematic representation of a device under test 200, according to an embodiment of the present invention. The device under test 200 may, for example, be configured to execute a test case. Accordingly, the device under test 200 may be configured to provide (e.g., to an automated test equipment) a command 212 (e.g., in the form of a message) requesting an update of one or more tester resources. The provision of said command 212 may, for example, be under the control of a test case which is executed on the device under test. The generation of this command 212 may be performed in the device under test 200, e.g., using a library routine which may define the functionality to generate the command and allow for the generation of the command in a user-friendly manner.

Moreover, the device under test is configured to receive an acknowledgement signal 214 indicating a completion of a tester resource update. Moreover, the device under test is configured to pause an execution of a test case until the acknowledge signaling 214 (e.g., an acknowledgement message), indicating a completion of a tester resource update requested by the device under test, is received by the device under test. For this purpose, the device under test 200 may, for example, be configured to evaluate the acknowledgement message, for example using a library routine. For example, the library routine may define a function to detect or to evaluate the acknowledgement signaling 214, and may also, for example, provide the functionality to pause the execution of the test case until the acknowledgement signaling is received (or detected) in a user friendly manner.

Accordingly, the device under test can instruct the automated test equipment (e.g., the automated test equipment 100) to update one or more tester resources, and the device under test 200 may also synchronize an execution of the test case with a completion of the update of the one or more tester resources, for example by pausing the execution of the test case until the acknowledgment signaling 214 is received. Consequently, the device under test 200 (or, equivalently, the test case executed on the device under test) can request the update of the test environment in which the device under test 200 is operated, and can also be sure to continue an execution of the test case only when the one or more test resources have been updated by pausing the execution of the test case until the acknowledgement signaling is received. Consequently, a test can be performed largely under the control of the device under test, wherein a higher reliability of the test can be achieved by the evaluation of the acknowledgement signaling indicating the completion of the tester resource update.

Moreover, it should be noted that the device under test 200 may optionally be supplemented by any of the features, functionalities and details described here, both individually and taken in combination.

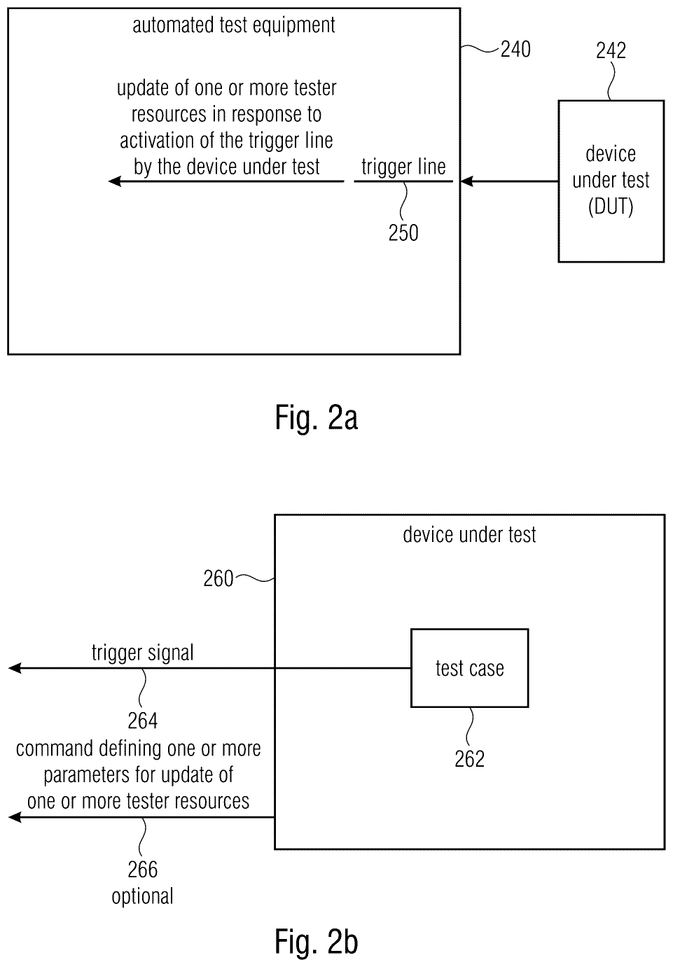

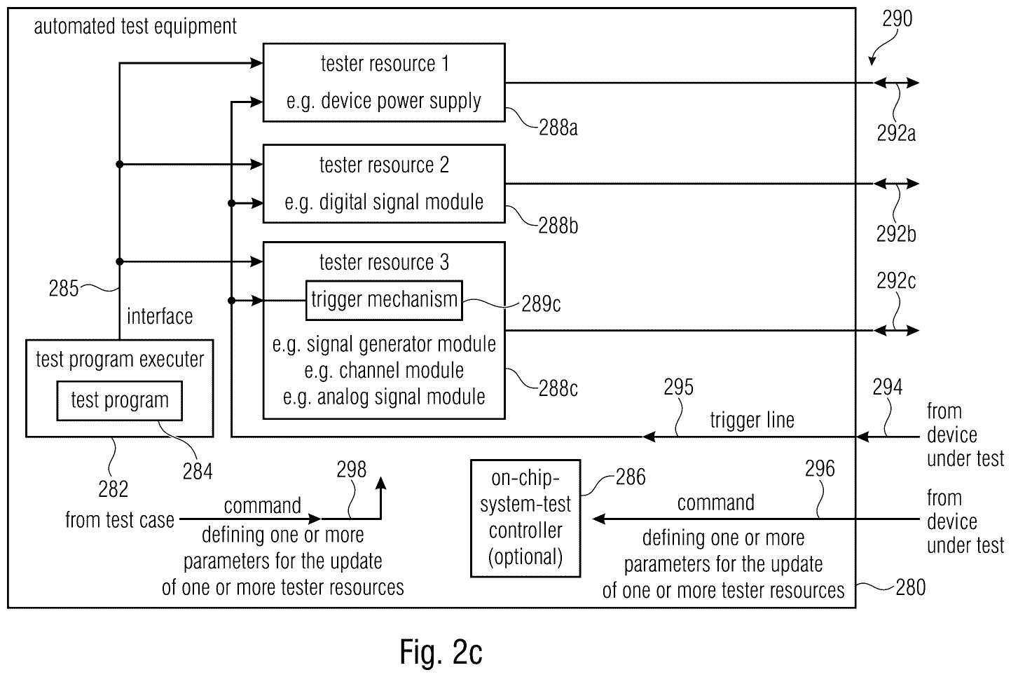

### 3. Automated Test Equipment According to FIG. 2

FIG. 2 shows a schematic representation of an automated test equipment 240, according to an embodiment of the invention. The automated test equipment 240 comprises a trigger line 250 (e.g., a hardware trigger line; e.g., a GPO trigger line) which is controllable by a device under test 242 (or, equivalently, by a test case which may, for example, be executed on the device under test 242). For example, the trigger line may be controllable by a general purpose output of the device under test, and may, for example, react to a single edge. Moreover, the automated test equipment is configured to update one or more tester resources (e.g., to change one or more supply voltages provided to the device under test 242 by the automated test equipment, or to change one or more signal characteristics of one or more analog or digital signals provided to the device under test 242 by the automated test equipment) in response to an activation (e.g. in the sense of a single/simple toggling of the state) of the trigger line 250 by the device under test 242 (or, equivalently, by a test case which may, for example, be executed on the device under test).

Accordingly, the automated test equipment 240 may allow the device under test 242 to trigger an update of one or more tester resources by the (simple) activation of the trigger line 250 (e.g. in the sense of a generation of a single edge or pulse on the trigger line). Accordingly, the automated test equipment 240 gives the device under test 242 a very accurate time control over the update of the one or more test resources, since the triggering of the update of one or more tester resources can be directly affected by the device under test 242, and is therefore not affected by latencies which may exist in a test program executor of the automated test equipment and/or in an on-chip-system-test controller of the automated test equipment 240. Thus, the automated test equipment 240 allows for a very high timing accuracy which can be directly controlled by the device under test 242. Accordingly, the device under test 242 can trigger the update of one or more tester resources at a time which is very well controllable by the device under test. Consequently, the device under test can quickly continue an execution of a test (e.g., an execution of a test case) after the activation of the trigger line, since the device under test only needs to consider a typically low latency of the actual tester resource, but does not need to consider a (typically non-deterministic) latency of a test program executor of the automated test equipment and/or a latency of an on-chip-test controller of the automated test equipment and/or a latency of a protocol-based communication.

Consequently, a particularly fast test can be achieved, which is well controllable by the device under test (and consequently by the test case which is typically executed on the device under test). Also, by providing a trigger line (at the side of the ATE), the device under test may only need to activate (or toggle) a single pin that is coupled to the trigger line, which is typically possible with very low software effort and only requires the usage of a single pin of the device under test. Consequently, the automated test equipment 240 provides a very good support for a testing of a device under test that is capable of controlling its own test environment by causing the automated equipment to update one or more tester resources.

Moreover, it should be noted that the automated test equipment 240 may optionally be supplemented by any of the features, functionalities and details described herein, both individually and taken in combination.

### 4. Device Under Test According to FIG. 2b

FIG. 2b shows a schematic representation of a device under test 260, according to an embodiment of the invention. The device under test 260 may, for example, be configured to execute a test case 262. Moreover, the device under test 260 is configured to provide (e.g., to an automated test equipment) a trigger signal 264, to thereby trigger an update of one or more tester resources via a dedicated trigger line. In this respect, it should be noted that the device under test 260 may, for example, correspond to the device under test 242 and that the trigger signal 264 may, for example, be provided to the trigger line 250.

Moreover, it should be noted that, for example, the device under test may be under the control of a test case 262 which is executed by the device under test. Moreover, it should be noted that, optionally, the device under test 260 may also be configured to provide a command 266 defining one or more parameters for an update of one or more tester resources. Accordingly, the device under test 260 may prepare the automated test equipment (or a tester resource of the automated equipment) for an update of the one or more test resources by defining, prior to an activation of the trigger signal 264, to which new parameters the respective one or more tester resources should be set in response to the activation of the trigger signal. Accordingly, the device under test has a very high control over its test environment. By optionally providing a command 266 defining one or more parameters for the update of the one or more tester resources, the device under test can determine details regarding the update of the one or more tester resources. Moreover, by the activation of the trigger signal 266, the device under test can determine, with a very high timing accuracy, when an update of one or more tester resources should be executed. Consequently, the device under test 260 may, for example, control a large part of a test with high timing accuracy and may therefore quickly execute a test, wherein a synchronization overhead for synchronizing with the automated test equipment is comparatively small.

Moreover, it should be noted that the device under test 260 may optionally be supplemented by any of the features, functionalities and details disclosed herein, both individually and taken in combination.

### 5. Automated Test Equipment According to FIG. 2c

FIG. 2c shows a schematic representation of an automated test equipment 280 according to an embodiment of the present invention. The automated test equipment 280 comprises a test program executor 282, which is configured to execute a test program 284. Moreover, the automated test equipment 280 also comprises an on-chip-system-test controller 286 which may be configured to support a test of a system-on-the-chip. Moreover, the automated test equipment 280 comprises a plurality of tester resources 288a, 288b, 228c. For example, the tester resources 288a to 288c may comprise a device power supply and/or a digital channel module (or digital signal module) and/or an analog channel module (or analog signal module) and/or a signal generator module. For example, one or more of the tester resources 288a, 288b, 288c may comprise a trigger mechanism 289c, which may, for example, effect a change of a setting of the respective tester resource, which is also designated as an update of the respective tester resource. For example, the test program executor 282 may be coupled to the tester resources 288a, 288b, 288c via an interface and may, for example, program the one or more tester resources. For example, the test program executor may be able to set one or more parameters of the tester resources 288a, 288b, 288c and may, for example, also be configured to pre-program a behavior of the one or more tester resources which the one or more tester resource exhibit in response to an activation of the trigger line, which may be coupled with the trigger mechanism (e.g. with the trigger mechanism 289c). Moreover, the automated test equipment may comprise a device-under-test interface 290, wherein signals 292a, 292b, 292c of one or more tester resources may be provided to a device under test via the device-under-test interface 290. Moreover, the device-under-test interface may also have (e.g. as a part of the device-under-test interface 290) a trigger input 294, which may be configured to receive a trigger signal from a device under test and which may be coupled to a trigger line 295 that may, for example, be directly coupled with the trigger mechanisms of one or more tester resources 288a to 288c. For example, FIG. 2c shows that the trigger line 295 is coupled to the trigger mechanism 289c of the tester resource 288c, but the other tester resources 288a, 288b may also comprise respective trigger mechanisms.

Moreover, the automated test equipment 280 may be configured to receive, via the device-under-test interface 290, a command 296 defining one or more parameters for the update of the one or more tester resources. This command 296 may be received from the device under test, but, generally speaking, this command could also be received from a test case (which may be executed on the device under test, and which may also be executed partially on the device under test and partially on the automated test equipment). The command 296 may, for example, be received by the on-chip-system-test controller 286, or may be received by the test program executor 282. In some configurations, said command 296 may also be first received by the on-chip-system-test controller 286 and may then be forwarded (in its original form or in a modified form) from the on-chip-system-test controller 286 to the test program executor 282. The test program executor 282 may, for example, preconfigure one or more of the tester resources 288a, 288b, 288c in response to the command.

Thus, the one or more test resources, which are pre-configured in response to the command 296 defining one or more parameters for the update of the one or more test resources may then react to an activation of the trigger line 295 by the device under test with a change of one or more parameters, wherein said change (e.g. the one or more new parameters to be used after the change) is, for example, defined by the pre-configuration. Consequently, the one or more tester resources may react very fast to the activation of the trigger line, and it may not be necessary to provide the one or more test resources 288a to 288c with any additional information at the time when the actual update of the one or more tester resources is desired. Consequently, the device under test can exercise a very fast control over the configuration of the one or more tester resources.

Moreover, it should be noted that a command defining one or more parameters for the update of one or more test resources may be alternatively received from a test case. Such a command is designated with 298. The command from the test case may be directed to the on chip system test controller 286 or to the test program executor 282. Regarding this issue, it should be noted that the test case may, for example, be executed solely on the device under test, and that the test case may alternatively be executed partially on the device under test and partially on the automated test equipment. However, while the command 298 may affect the pre-configuration of one or more tester resources, to thereby define a reaction of the one or more tester resources to the activation of the trigger line, the trigger signal may still be received from the device under test, for example, via the input 294.

To conclude, the automated test equipment 280 provides the device under test with the possibility to effect (or trigger) a change of a signal characteristic of one or more signals provided to the device under test in a very simple manner, simply by the activation of a trigger line, and with typically very small latency.

Moreover, it should be noted that the automated test equipment 280 may optionally be supplemented by any of the features, functionalities, and details disclosed herein, both individually and taken in combination.

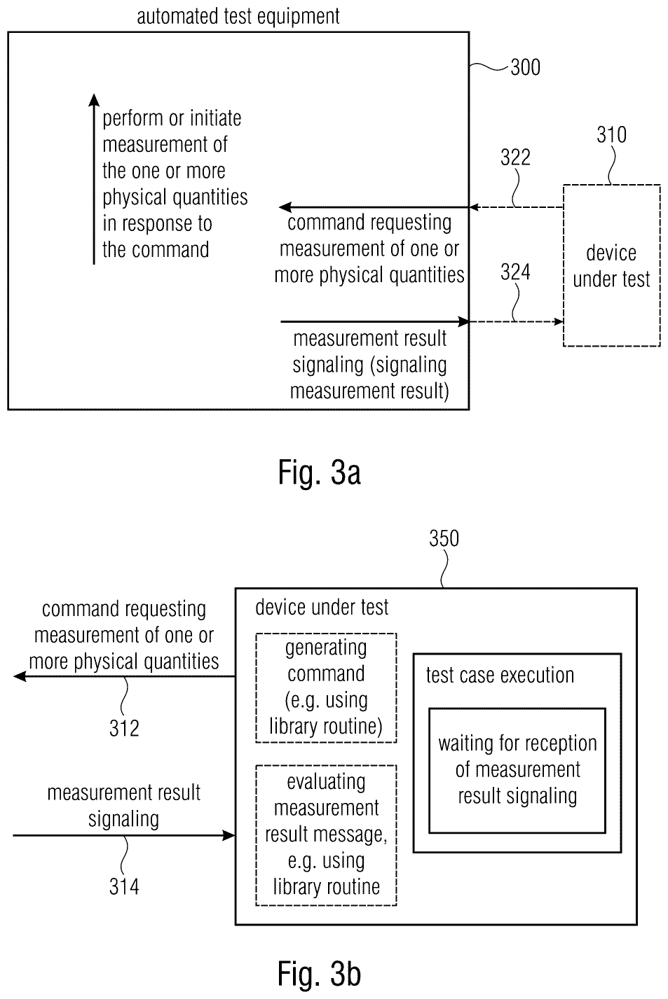

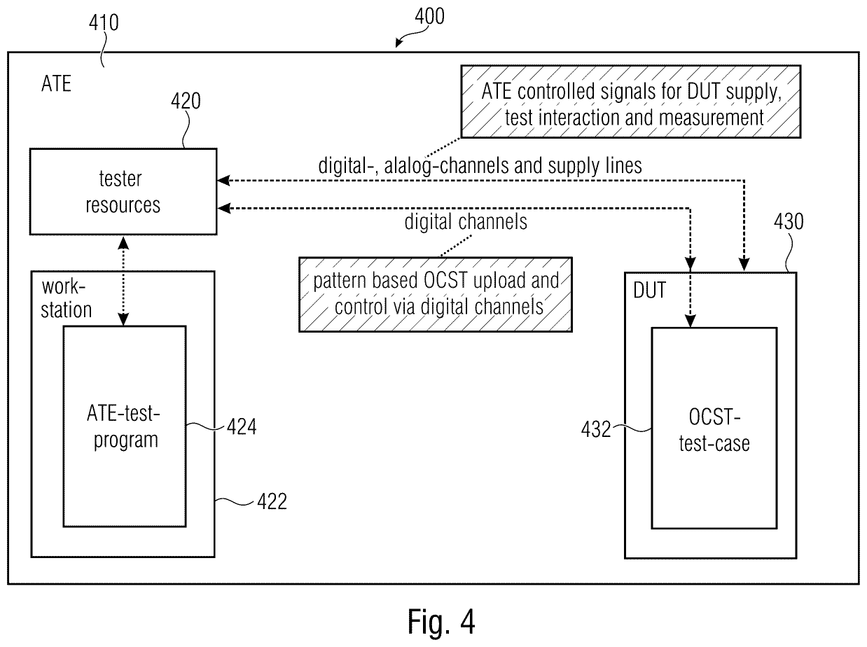

### 6. Automated Test Equipment According to FIG. 3a

FIG. 3a shows a schematic representation of an automated test equipment 300, according to an embodiment of the present invention. The automated test equipment 300 is configured to test the device under test 310, which may be coupled to the automated test equipment. For example, the automated test equipment is configured to receive, from the device under test 310, a command 322 (e.g., in the form of a message) requesting a measurement of one or more physical quantities (e.g., of a supply voltage provided to the device under test, e.g., of a current supplied to the device under test, e.g., of a signal characteristic of a signal provided by the device under test, e.g., of a signal characteristic of a signal provided to the device under test, e.g., of a clock frequency of a clock signal provided to the device under test, e.g., of an environmental parameter like a temperature, a humidity, an air pressure, an electric of magnetic field, in an environment of the device under test, or the like). Moreover, the automated test equipment is configured to perform or initiate the measurement of the one or more physical quantities in response to the command provided to the device under test.

For example, the automated test equipment may cause (or trigger) one or more internal measurement resources of the automated test equipment to make a measurement of the one or more physical quantities designated in the command. For example, measurement functionalities of one or more channel modules of the automated test equipment may be used to make a measurement. Alternatively, however, the automated test equipment may control one or more external measurement resources (like, for example, an external precision measurement equipment or external high frequency measurement equipment, or an external optical measurement equipment) to make the requested measurement. Moreover, the automated test equipment is configured to provide a measurement result signaling 324 (e.g., an acknowledgement message or a message comprising a measurement result) to the device under test 310, to thereby signal a measurement result requested by the device under test.

Accordingly, the automated test equipment 300 allows the device under test 310 to trigger a measurement, which is to be performed (or initiated) by the automated test equipment, such that, for example, a test case which is executed on the device under test may define which measurements are made at which point of the execution of the test case. Consequently, measurements can be made under the control of the device under test, which significantly facilitates a test development, since a large portion of the activities to be performed by the automated test equipment during the execution of a test case can be defined in the test case itself.

Moreover, by providing a measurement result signaling, which may signal the measurement result to the device under test, and which may also indicate to the device under test that a measurement has been completed, the device under test is enabled to make use of the measurement results. For example, the device under test may use the measurement result to decide about the further execution of a test case in dependence on the measurement result. As another example, the device under test 310 may generate a test result information making use of the measurement result. To conclude, the automated test equipment 300 allows the device under test to request measurements and also forwards measurement results to the device under test. Accordingly, a test or a test case can be executed largely under the control of the device under test, which significantly facilitates test case generation and allows to define very powerful and efficient test cases that may even exploit measurement results for a control of the test case execution.

Moreover, it should be noted that the automated test equipment 300 may optionally be supplemented by any of the features, functionalities and details disclosed herein, both individually and taken in combination.

### 7. Device Under Test According to FIG. 3b

FIG. 3b shows a schematic representation of a device under test 350, according to an embodiment of the invention. The device under test 350 is configured to provide to an automated test equipment a command 312 (e.g., in the form of a message) requesting a measurement of one or more physical quantities (e.g., under the control of a test case, which is executed on the device under test). Moreover, the device under test 350 is configured to wait for a reception of a measurement result signaling 314 (e.g., a measurement result message), indicating a measurement result requested by the device under test (e.g., by pausing an execution of a test case until the measurement result requested by the device under test is received by the device under test).

Accordingly, the device under test 350 can both initiate the execution of a measurement by the automated test equipment (or by an external measurement device coupled to the automated test equipment), and the device under test can also receive the measurement result and synchronize the execution of the test case on the device under test with the measurement. For example, the measurement result signaling 314 may indicate that the measurement is completed, such that the device under test 350 can continue the execution of the test case when the measurement result signaling 314 has been received by the device under test. As a consequence, the device under test 350 can be sure that the execution of the test case (for example, with a new test step) is not continued before the completion of the measurement, which helps to avoid a falsification of the measurement result. Moreover, the device under test (or the test case, which is executed on the device under test) can consider a measurement result, for example, for a decision for how to further execute the test case. Accordingly, the device under test 350 has a large degree of control over the testing, since the test case that is executed on the device under test may determine the processing operations that are performed on the device under test and may also determine measurements to be made by the automated test equipment, wherein the described mechanism to provide a command requesting a measurement of one or more physical quantities and to wait for a reception of a measurement result signaling from the automated test equipment allows for a good temporal synchronization between the test case executed on the device under test and the measurements to be made by the automated test equipment.

Moreover, it should be noted that the device under test 350 may optionally be supplemented by any of the features, functionalities and details disclosed herein, both individually and taken in combination.

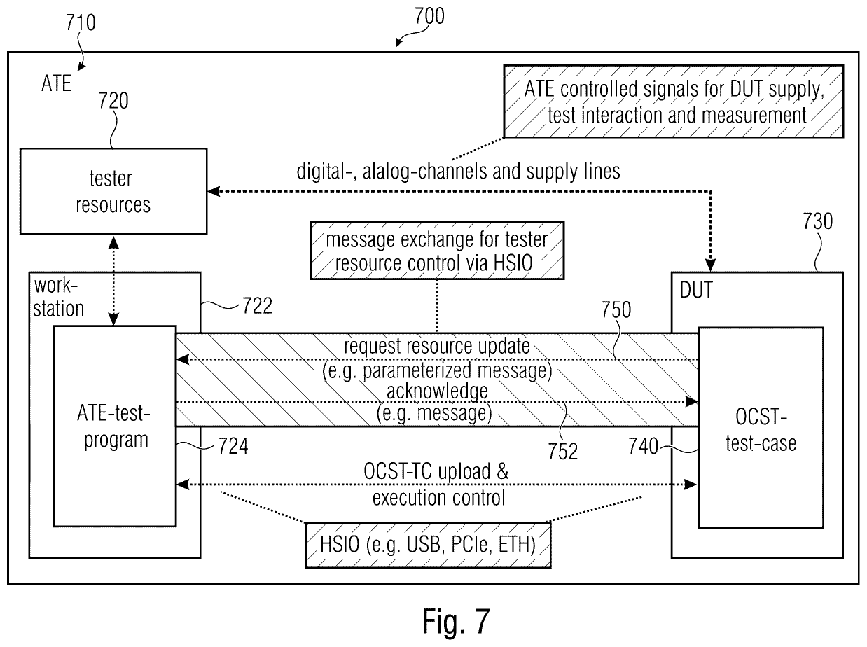

### 8. Measurement Arrangement According to FIG. 7

FIG. 7 shows a schematic representation of a measurement arrangement 700, according to an embodiment of the present invention. The measurement arrangement 700 comprises an automated test equipment 710 and a device under test 730. The automated test equipment 710 comprises tester resources 720 and a work station 722, which may be adapted to execute an ATE test program 724. The device under test 730 may be configured to execute an OCST test case 740.

The tester resources 720 of the automated test equipment 710 may, for example, comprise one or more digital channels (or digital channel modules), and/or one or more analog channels (or channel modules) and/or one or more power supplies (e.g., device power supplies). Accordingly, the tester resources 720 may be coupled with the device under test 730. For example, one or more digital channels of the tester resources 720 may be coupled with digital pins (e.g., digital inputs or digital outputs or digital input/outputs) of the device under test 730. Alternatively, or in addition, one or more analog channels of the tester resources 720 may be coupled with one or more analog pins (e.g., analog inputs or analog outputs or analog inputs/outputs) of the device under test 730. Alternatively, or in addition, one or more supply lines, which may be coupled with one or more power supplies or device power supplies out of the tester resources 720, may be coupled with the device under test 730 (e.g., with supply pins or supply pads of the device under test 730). Accordingly, analog and/or digital signals may be provided to the device under test 730 by respective tester resources. Moreover, one or more supply voltages and/or supply currents may be provided to the device under test 730 by respective tester resources. Generally speaking, the coupling between the tester resources 720 and the device under test 730 may be used for ATE control signals for DUT supply, test interaction and measurement. In particular, it should be noted that the coupling between the tester resources 720 and the device under test 730 may, for example, be bidirectional. For example, one or more digital signals and/or one or more analog signals may be provided to the device under test 730 using respective tester resources. Alternatively, or in addition, one or more digital signals and/or one or more analog signals may be provided by the device under test 730 and may be received (and typically evaluated) by respective tester resources 720. For example, the tester resources 720 may provide one or more digital and/or analog stimulus signals for the device under test 730 and may optionally also evaluate one or more digital and/or analog response signals of the device under test. In the case that the device under test 730 comprises a system-on-the-chip, the tester resources 720 may, for example, be used to initialize this system-on-the-chip or may, for example, by applying appropriate signals to allow for a safe startup of the device under test 730. Moreover, the test resources 720 may, for example, be used in an upload of a test program, and/or of a fundamental operating system, to the device under test (e.g. using a JTAG port of the device under test, or the like), in order to prepare an execution of a test case 740 on the device under test 730.

Moreover, the device under test 730 may, for example, be coupled with the automated test equipment in order to allow for an on-chip-system-test-test case upload (OCST-TC upload) and for an execution control. For example, the automated test equipment 700 may be adapted to allow for a communication between the ATE-test program 724 and the OCST test case 740 (or, more generally, between the work station 722 and the device under test 730). For example, a high speed input/output (HSIO) (e.g. a high speed interface) may be used for the communication between the automated test equipment and the device under test (for example, for the communication between the ATE-test program and the OCST test case, or for the communication between the ATE-test program and a control software running on the device under test 730, wherein said control software may, for example, have the functionality to allow for an upload of one or more test cases and to allow for a control of an execution of the one or more test cases). For example, the HSIO may comprise a USB interface and/or a PCle interface, or an Ethernet interface (ETH), or any other type of high speed interface. To conclude, generally speaking, an OCST-TC upload and an execution control may be performed using a high speed interface (or a high bandwidth interface, or a high data rate interface) between the automated test equipment and the device under test.

Moreover, the ATE and the device under test may be configured to allow the OCST-test case 740 to request a resource update. For example, the OCST-test case 740 may request the resource update from the ATE test program 724, e.g., using a parameterized message. Moreover, the ATE-test program 724 may provide an acknowledgement to the OCST test case 740 (e.g., in the form of an acknowledgement message or in the form of an acknowledgement signaling). Thus, there may be message exchange between the OCST test case 740 and the ATE test program 724, e.g., using a request resource update message 750 (also designated as resource update request message) and an acknowledge message 752 (also designated as acknowledgement message). For example, the message exchange, which includes the request resource update message 750 and the acknowledge message 752, may be used for tester resource control via HSIO. Worded differently, the request resource update message 750 and the acknowledge message 752 may, for example, be exchanged between the OCST test case 740 and the ATE test program 724 using a HSIO. For example, the message exchange comprising the request resource update message 750 and the acknowledge message 752 may use the same HSIO, which is also used for the OCST-test case upload and the execution control.

Accordingly, the OCST test case 740 has the functionality to perform test routines on the device under test, and also has the functionality to request changes of the test environment of the DUT, by requesting a resource update using the request resource update message 750. Moreover, the OCST test case 740 also receives the acknowledge message 752, and can use this acknowledge message for a timing synchronization.

For example, the request resource update message 750 may request that a parameter of one of the test resources 720 is changed (or updated). Just as an example, the OCST test case 740 may request that a supply voltage that is provided to the device under test 730 is changed by changing a setting of a device power supply, which is part of the tester resources 720. Moreover, the ATE test program provides an acknowledge message 752 to the OCST test case 740 (or, generally speaking, to the device under test 730) to signal that the resource update is completed, wherein the OCST test case 740 may continue with the execution of a new test step after receiving the acknowledge message 752. Accordingly, the OCST test case can be sure that proper test conditions, as requested, are present for a test (or for the new test step).

To conclude, the test arrangement 700 according to FIG. 7 allows for highly efficient testing, wherein the control of the test execution can be executed by the OCST test case to a large degree.

Moreover, it should be noted that the ATE itself, as described here, should be considered as an embodiment of the invention. Moreover, it should be noted that the device under test as described here should also be considered as an embodiment of the invention. Furthermore, it should be noted that the test arrangement, the automated test equipment and the device under test can optionally all be supplemented by any of the features, functionalities and details disclosed herein, both individually and taken in combination.

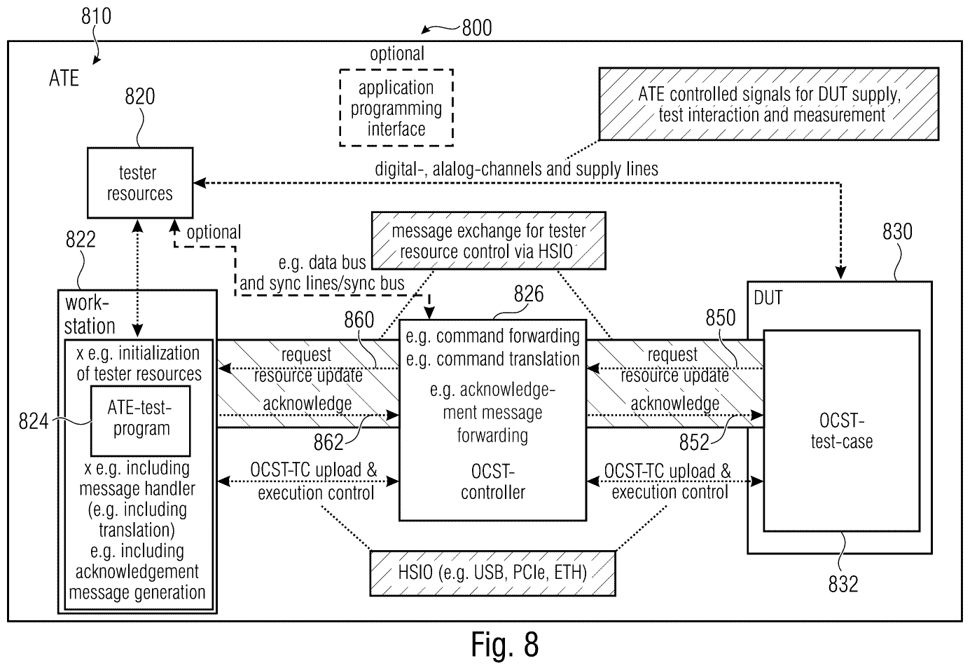

### 9. Test Arrangement According to FIG. 8

FIG. 8 shows a schematic representation of a test arrangement 800, according to an embodiment of the present invention.

The test arrangement 800 is similar to the test arrangement 700. Accordingly, reference is made to the above description with respect to the test arrangement 700.

The test arrangement 800 comprises an automated test equipment 810 and a device under test 830. The automated test equipment 810 comprises tester resources 820, which are, for example, very similar to the tester resources 720, such that the above explanations also apply. The automated test equipment 810 also comprises a work station 822, which may be similar to the work station 722. The work station 822 is adapted to execute an ATE test program, which may take over a variety of functionalities. For example, the ATE test program 824 may be configured to perform an initialization of tester resources (e.g., of the tester resources 820). For example, the ATE test program 824 may be configured to initialize the tester resources 820 to allow for a start of a program execution on the device under test 830. Moreover, the ATE test program 824 may, for example, include a message handler. The message handler may, for example, perform a translation of messages and may, for example, include an acknowledgement message generation. Moreover, the ATE test program may be configured to effect further updates of one or more of the tester resources 820 under the control of the device under test, e.g., in response to a message evaluated by the message handler.

However, in addition to the tester resources 820 and the work station 822, the test equipment 810 comprises an on-chip-system-test controller 826, which may, for example, be coupled between the device under test 830 and the work station 822. For example, on on-chip-system-test controller may be configured to receive a request for a resource update from the device under test 830, or from a OCST test case 832 that is executed on the device under test 830. Moreover, the on-chip-system-test controller 826 may be configured to forward this request or command. Alternatively or in addition, the OSCT controller 826 may be configured to perform a command translation, for example, by translating the request 850 for a resource update from a first command format into a second command format. For example, the on-chip-system-test controller 826 may be configured to provide a request 860 for a resource update to the work station 822 or to the ATE test program 824. For example, the OCST controller 826 may forward the request (or request message) 850 without an amendment, such that the request (or request message) 860 may be identical to the request (or request message) 850. However, the OCST controller 826 may also perform a translation, and thereby translate the request (or request message) 850 for a resource update, which is provided by the OCST test case 832, into a different format, such that the format of the request (or request message) 860 for a resource update is different from the format of the request (or request message) 850 for a resource update. However, it should be noted that the OCST controller 826 may, for example, handle a high speed interface protocol and may, for example, unwrap the request (or request message) 850 from a communication protocol, to thereby forward to the ATE test program 824 an unwrapped request (or request message). In other words, the OCST controller may, for example, extract a representation of the request (or request message) from a communication protocol, and provide a “plain” form of the request to the ATE test program 824.

Moreover, the OCST controller 826 may receive an acknowledge information (or acknowledge signaling, or acknowledge message) from the ATE test program 824, and may forward this acknowledge information to the OCST test case 832. However, the OCST controller 826 may, for example, receive an acknowledgement information from the ATE test program 824 (for example, an acknowledge information acknowledging an update of one or more tester resources in response to a request issued by the OCST test case) and generate an acknowledge signaling or an acknowledge message to be forwarded to the OCST test case 832. For example, the acknowledge information provided to the OCST controller 826 by the ATE test program is designated with 862, and the acknowledge signaling or acknowledge message or acknowledge information provided by the OCST controller 826 to the OCST test case 832 is designated with 852. For example, the message exchange for the tester resource control may be performed using a HSIO (e.g., using a high speed interface or a high bandwidth interface). For example, a high speed interface or high bandwidth interface may be used for the communication between the OCST controller 826 and the OCST test case 832, wherein the OCST controller 826 may, for example, provide hardware support for the usage of such a high speed interface (wherein the high speed interface is typically protocol-based, and wherein the OCST controller 826 may comprise support for a handling of the protocol of the high speed interface). Moreover, the device under test 830 may typically also comprise support for the high speed interface, like, for example, dedicated hardware and an appropriate high speed interface driver that gives the OCST test case 832 access to the high speed interface. Optionally, a high speed interface may also be used for the communication between the OCST controller 826 and the work station 822 or the ATE test program 824. For example, a HSIO may be used for the transmission of the request resource update message 860 from the OCST controller 826 to the ATE test program 824 and also for the provision of the acknowledge information 862 from the ATE test program 824 to the OCST controller 826. However, different types of interfaces may be used for the communication between the ATE test program and the OCST controller and for the communication between the OCST controller and the OCST test case.

In addition, the ATE test program 824 may be in communication with the OCST controller 826, for example, for OCST-test case upload and/or execution control. Moreover, there may also be a communication between the OCST controller 826 and the OCST test case 832 for OCST test case upload and/or execution control. For example, the ATE test program 824 may provide an OCST test case to be uploaded to the device under test to the OCST controller 826 using an appropriate interface between the ATE test program 824 and the OCST controller 826. Moreover, the OCST controller 826 may upload this OCST test case to the device under test using an appropriate interface between the OCST controller 826 and the device under test 830 (or the test case 832). Similarly, there may be a communication between the ATE test program 824 and the OCST controller 826 in order to control an execution of the test on the device under test. This communication may, for example, be bidirectional. In addition, there may also be a communication between the OCST controller 826 and the OCST test case 832, in order to control an execution of the test case. This communication may also be bidirectional.

For example, the communication between the ATE test program 824 and OCST controller, for the OCST test case upload an execution control may be performed using a high-speed interface (HSIO), like, for example, a USB interface, or a PCle interface, or an Ethernet interface ETH. Moreover, the communication between the OCST controller 826 and the OCST test case 832, for the OCST test case upload an execution control, may also be performed using a high-speed interface (HSIO), like a USB interface, a PCle interface or an Ethernet interface (ETH).

However, it should be noted that, for example, the request 850 for a resource update and that the acknowledgement 852 may be communicated using the same high-speed interface like the OCST test case upload and/or execution control. Similarly, the request resource update message (or signaling, or command) 860 and the acknowledgement 862 may be communicated using the same high-speed interface like the OCST test case upload and/or execution control. In other words, the high-speed interface between the OCST controller and the OCST test case may, for example, be shared for the OCST test case upload and execution control and also for the messages 850, 852. Similarly, a high-speed interface between the ATE test program 824 and the OCST controller 826 may be shared for the messages 860, 862 and for the OCST test case upload and/or execution control.

To conclude, in the test arrangement 800 according to FIG. 8, the OSCT controller 826 may, for example, be used as an intermediator between the ATE test program 824 and the device under test 830 (or OCST test case 832). For example, the OCST controller may take over a time-critical (and possibly non-time-deterministic) communication with the device under test 830 or with the OCST test case 832, for example under the superior control of the ATE test program 824. Thus, the OCST controller 826 may, for example, take over the task to upload one or more test cases to the device under test 830 and to issue commands controlling the execution of the one or more test cases (e.g. to a test case executor software running on the device under test 830). Moreover, the OCST controller may, for example, also handle the download of test results from the DUT and, optionally, perform a preprocessing of these test results before reporting the test results, or a preprocessed version thereof, to the ATE test program 824.

Moreover, the OCST controller 826 may, for example, take the role of an intermediator when the OCST test case requests a resource update. The OCST controller 826 may forward such a request for a resource update to the ATE test program 824, wherein the ATE test program 824 may be responsible for the direct communication with the tester resources 820.

However, alternatively, the OCST controller 826 may also be coupled to the test resources 820, e.g. using a data bus and/or a synchronization bus and/or one or more synchronization lines. Thus, the OCST controller 826 may optionally directly access the test resources 820 (e.g. bypassing the work station 822 and the ATE test program 824) and effect an update of the one or more tester resources, as requested by the OCST test case 832, using the direct connection (e.g. a data bus and/or a synchronization bus and/or one or more synchronization lines) between the OCST controller 826 and the tester resources 820. In this case, it is also not necessary that the OCST controller forwards the request resource update message 860 to the ATE test program 824 or receives the acknowledgement 862 from the ATE test program 824.

To conclude, the general concept to handle a request resource update message 850 from the OCST test case 832 in an automated test equipment may be supported by the OCST controller 826, wherein the OCST controller may act as an intermediator between the OCST test case 832 and the ATE test program 824, or wherein the OCST controller 826 may directly handle the requested resource update (e.g. using a direct connection with the tester resources 820). Moreover, the OCST controller may also support the forwarding of the acknowledgement 852 to the OCST test case, e.g. as an intermediator between the ATE test program 824 and the OCST test case, or provide the acknowledgement message 852 under its own control. Consequently, a high degree of control over an ATE test process is provided to the OCST test case 832.

It should be noted that an embodiment of the invention can be seen in the automated test equipment 810 comprising the OCST controller 826. Moreover, another embodiment according to the invention can be seen in the device under test 830.

Moreover, it should be noted that the test arrangement 800, or the automated test equipment 810, or the device under test 830, may optionally be supplemented by any of the features, functionalities and details disclosed herein, both when taken individually and in combination.

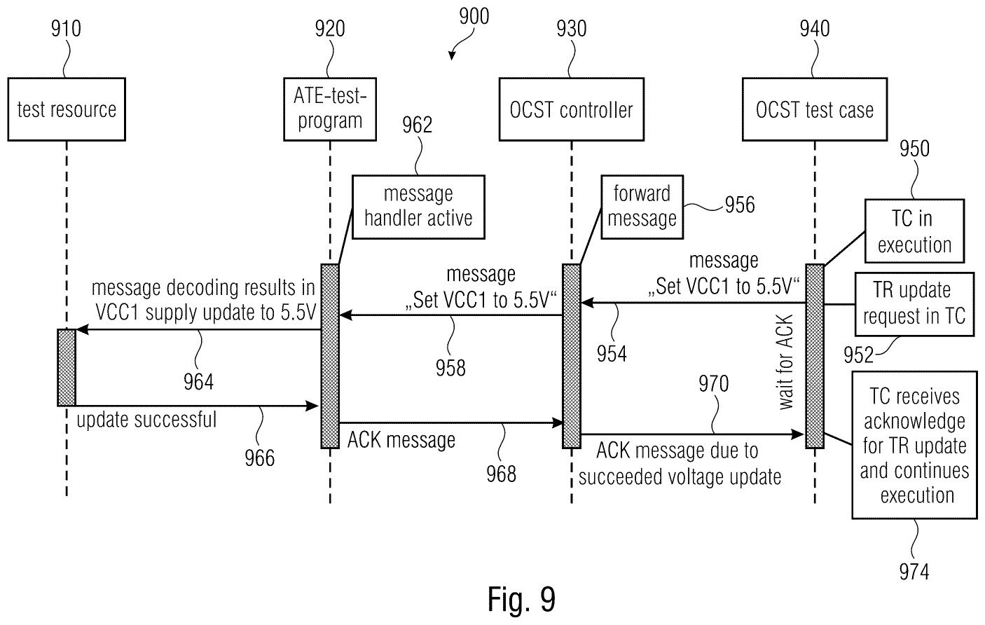

### 10. Message Flow According to FIG. 9

FIG. 9 shows a schematic representation of a message flow for tester resource control, which can be used in embodiments according to the invention. For example, the message flow can be used in any of the automated test equipment disclosed herein. As an example, the message flow of FIG. 9 may be used in the test arrangement 800 according to FIG. 8.

Regarding the message flow, it should be noted that there are four entities involved in the message flow: A tester resource 910, which may, for example, correspond to the tester resource 820, an ATE test program 920 which may, for example, correspond to the ATE test program 824, an OCST controller 930 which may, for example, correspond to the OCST controller 826 and an OCST test case 940 which may, for example, correspond to the OCST test case 832.

The message flow may, for example start with the fact that an OCST test case is in execution, which is shown as the reference numeral 950. A tester resource update request may be present within the test case (e.g. in the form of a program instruction), which is shown at reference numeral 952. In response to the test resource update request in the test case, a message 954 may be effected, which may, for example, be transmitted from the test case (or from the device under test) to the OCST controller 930. The message may, for example, comprise (for example, in an encoded form) the command “Set VCC1 to 5.5 volt”. This message may, for example, be encoded using a predefined syntax and may, for example, be represented by an appropriate ASCII string. The message 954 may be received by the OSCT controller 930, which may forward the message to the ATE test program. The forwarding of the message is shown as reference numeral 956, and the forwarded version of the message is shown as reference numeral 958. The forwarded message 958 may, for example, comprise the same format as the message 954 and may, for example, represent the command “Set VCC1 to 5.5 volt”. However, when forwarding the message 954, the OCST controller 930 may, for example, unwrap the message 954 from a protocol-based high-speed communication, such that the message 958 can be handled more easily by the ATE test program. Optionally, the OCST controller may also perform a message translation when providing the message on the basis of the message 954, for example in the form of a syntax translation. However, 958 the OCST controller 930 can also forward the message 954 in an unchanged manner, such that the message 958 is identical to the message 954.

In the ATE test program 920, a message handler may be active, which is shown at the reference numeral 962. The message handler may recognize the reception of the message 958 and may, for example, parse the message 958 and/or interpret the message 958. For example, the message handler within the ATE program may “decode” the message 958 and translate the message 958 in a physical command 964, which results in the requested update of the tester resource and which is forwarded to the tester resource 910. For example, the message handler 962 may receive and evaluate the message 958 and translate the message into a bus access command representing the requested update of the tester resource. For example, the message handler may replace a symbolic reference (e.g. “VCC1”) by a low level (e.g. bus access) command instructing an appropriate tester resource (e.g. a device power supply which provides the supply voltage referenced to as “VCC1”) to take a desired value. For this purpose, the message handler may also translate a number representation within the message 958 into a number representation which is adapted to the specific tester resource. Thus, the ATE test program 920 provides a message 964 which results in the desired update of the test resource. In the present case, the message decoding results in a VCC1 supply update, for example to 5.5 volt. Moreover, the test resource 910 may provide an “update successful” message 966 (which may, for example, be considered as optional) to the ATE test program 920. Accordingly, the ATE test program 920 may be aware that the resource update is completed. However, the ATE test program may also conclude that the update is successfully completed from an assessment of a timing. For example, the ATE test program 920 may, for example, assume that a test resource update is successfully completed when a certain amount of time has elapsed since the provision of an update command to the tester resource 910.

However, when the ATE test program has confirmed that the tester resource update is successful (e.g. on the basis of the update successful message 966, or on the basis of a time evaluation), the ATE test program provides an acknowledgement message 968 to the OCST controller. Furthermore, in response to a reception of the acknowledgement message 968, the OCST controller 930 provides an acknowledgement message (e.g. an acknowledgement message due to succeeded voltage update) to the OCST test case 940. An acknowledgment message provided from the OCST controller to the OCST test case may be designated to with 970. For example, the OCST controller 930 may simply forward the acknowledgement message 968 to the OCST test case, or the OCST controller 930 may generate the acknowledgement message 970 in response to the reception of the acknowledgement message 968 from the ATE test program. Subsequently, the OCST test case receives the acknowledgement for the tester resource update and continues the execution, which is shown at the reference numeral 974.

However, according to an aspect, the OCST test case 940 may be in a “wait for acknowledgement” state between the transmission of the message 944 and the reception of the acknowledgement message 970. During this wait condition, the OCST test case may, for example, pause the test case execution, or the OCST test case may perform one or more tests that do not need the update of the test resources and that may be insensitive to an update of the tester resource. However, the OCST test case may delay the execution of any tests that require the update of the test resource until the acknowledgment message 970 has been received. Using such a message flow, a reliable execution of a test case which a requires an update of a tester resource can be performed largely under the control of the test case.

It should be noted that the message flow as described here may optionally be used in any of the embodiments according to the invention, wherein message 954 may, be provided by the OSCT test case and message 970 may be evaluated by the OCST test case, and wherein message 954 may be received by the automated test equipment and wherein the 970 may be provided by the automated test equipment. Messages 958, 964, 966 and 968 may be ATE internal messages.

Moreover, it should be noted that the message flow according to FIG. 9 may optionally be supplemented by any of the features, functionalities and details disclosed herein, both individually and taken in combination.

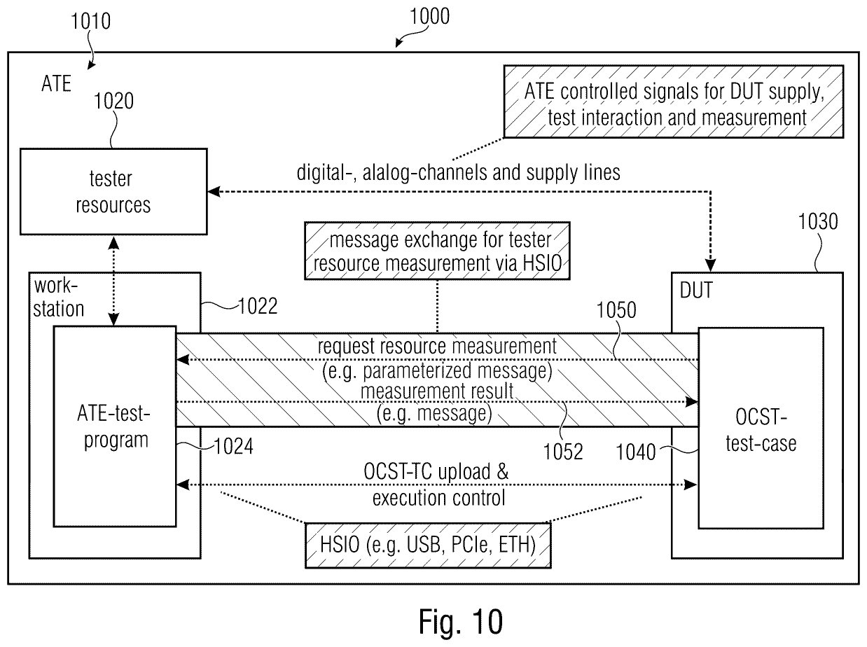

### 11. Test Arrangement According to FIG. 10

FIG. 10 shows a schematic representation of a test arrangement, according to an embodiment of the present invention. It should be noted that the test arrangement 1000 according to FIG. 10 is similar to the tester arrangement 700 according to FIG. 7, such that equal components will not be described again here. Rather, reference is made to the above explanations.

The test arrangement 1000 comprises an automated test equipment 1010, which may be similar to the automated test equipment 710. The automated test equipment 1010 may comprise one or more tester resources 1020, which may be similar to the tester resources 720. However, it should be noted that the one or more tester resources 1020 may comprise at least one measurement resource which is configured to measure a physical quantity like, for example, a physical characteristic of an analog or digital signal provided to the device under test or a physical characteristic of an analog or digital signal received from the device under test. However, the tester resources 1020 may also comprise a measurement resource which is configured to measure an environment parameter, like a temperature, a pressure, a humidity, or the like (e.g. in an environment of the device under test). The automated test equipment 1010 also comprises a workstation 1022, which may be similar to the workstation 722. The workstation 1022 may be configured to execute an ATE test program 1024.

Moreover, there is a device under test 1030, which may be coupled with the one or more tester resources 1020, e.g. in the manner as described with reference to FIG. 7. Thus, there may be one or more connections between the one or more tester resources 1022 and the device under test 1030, which, for example, provide ATE control signals for DUT supply, test interaction and measurement.

However, the test arrangement 700 is distinguished from the test arrangement 1000 in that a different type of communication between the OCST test case 1040 and the ATE test program 1024 is performed. In the test arrangement 1000, the OCST test case 1040 is configured to request a resource measurement from the ATE test program 1024. For this purpose, the OCST test case 1040 sends a request resource measurement message 1050 (also designated as resource measurement request message) to the ATE test program 1024, wherein this message may, for example, be a parametrized message. In response to this message 1050, the ATE test program 1024 may instruct one of the tester resources, e.g. a measurement resource, to perform a requested measurement and to provide a measurement result. For example, the ATE test program 1024 may instruct a device power supply to perform a current measurement. Alternatively, the ATE test 1024 may instruct a digital channel module to perform a measurement on a digital signal provided by the device under test, or the ATE test program 1024 may instruct the analog channel module to perform a measurement on an analog signal provided by the device under test. However, the ATE test program 1024 may alternatively instruct a measurement resource (which may be part of the tester resources 1020) to perform any other measurement of a physical quantity.

When the measurement is completed, the ATE test program 1024 may provide a measurement result message to the OCST test case 1040. The measurement result message is designated with 1052.

Accordingly, the OCST test case 1040 can request a measurement to be performed by one of the test resources, and the ATE program 1024 responds to this request by instructing an appropriate measurement resource to make such a measurement. Subsequently, the ATE test program 1024 reports the measurement result to the OCST test case using the measurement result message 1052. The OCST test case may, for example, wait for the measurement result message 1052, in order to ensure that the measurement result is not falsified by an execution of an inappropriate test case step. Thus, it is possible, that the OCST test case exercises a high degree of control and can be time-synchronized with the measurement. Moreover, the measurement result can be considered in the further execution of the OCST test case.

Moreover, it should be noted that the test arrangement 1100 may also be supplemented by any of the features, functionalities and details described herein, both individually and taken in combination. Moreover, it should be noted that the automated test equipment 1010 may be considered as an embodiment of the invention. Similarly, the device under test 1030 may also be considered as an embodiment of the invention.

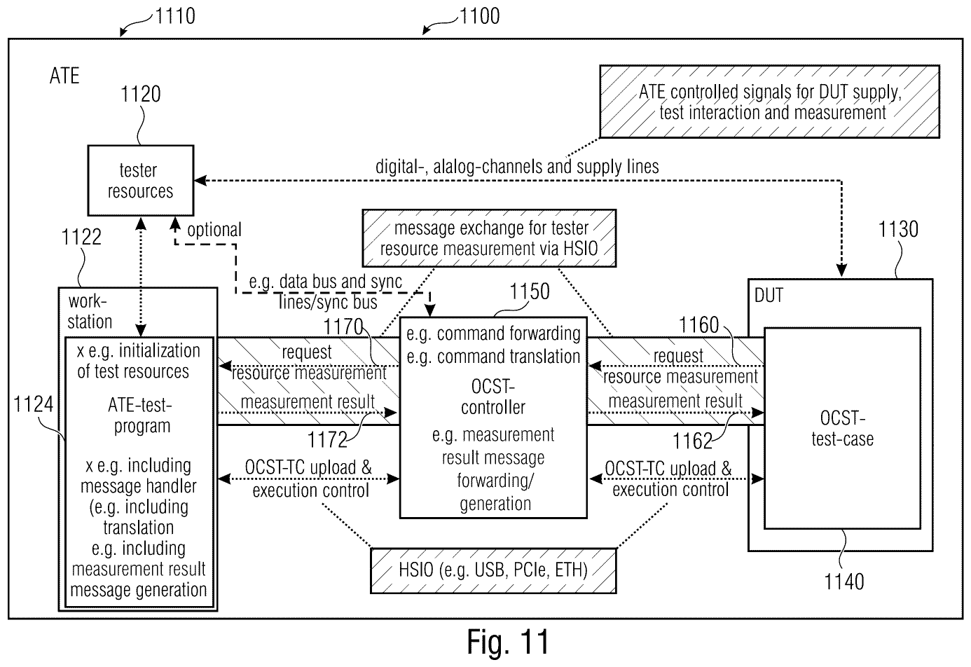

### 12.Test Arrangement According to FIG. 11

FIG. 11 shows a schematic representation of a test arrangement 1100, according to an embodiment of the invention. The test arrangement 1100 comprises an automated test equipment 1110 and a device under test 1130.

The automated test equipment 1110 may comprise test resources 1120 which may, for example, correspond to the test resources 1120. Moreover, the automated test equipment 1110 comprises a work station 1122 which may, for example, correspond to the work station 1020 described above. The work station 1122 is configured to execute an ATE test program 1124 which may, for example, correspond to the ATE test program 1024. However, in addition to the automated test equipment 1010, the automated test equipment 1110 also comprises an on-chip-system-test controller 1150, which may, for example, be coupled with the workstation 1122 and optionally also with the tester resource 1120. Furthermore, the on-chip-system-test controller 1140 is typically configured to receive from the device under test 1130, or from a test case 1140 which is executed on the device under test 1130, a resource measurement request 1160 and to provide to the device under test 1130, or to the OCST test case 1140 executed on the device under test 1130, a measurement result 1162.

For example, the OCST controller 1150 may be coupled with the device under test 1130 for a message exchange for tester resource measurement via a high speed interface (HSIO). Moreover, the OCST controller 1150 may also be coupled with the work station 1122 to provide a resource measurement request (or resource measurement request message) 1170 to the work station 1122 or to the ATE test program 1124 executed on the work station 1122. Moreover, the OCST controller may also be configured to receive a measurement result (or measurement result message) 1172 from the workstation 1122 or from the ATE test program 1124. In other words, the OCST controller 1150 may be configured to perform a message exchange for tester resource measurement via a high speed interface (HSIO) also with the work station 1122 or with the ATE test program 1124. However, it should be noted that the high speed interface between the OCST controller 1150 and the work station 1122 may naturally be different from the high speed interface between the device under test 1130 and the OCST controller 1150. In addition, the OCST controller may also be configured to communicate (e.g., bidirectionally) with the device under test 1130 (or with the OCST test case 1140) to perform an OCST-test case upload and/or execution control. Moreover, the OCST controller 1150 may also be configured to communicate (e.g. bidirectionally) with the work station 1122, or with the ATE test program 1124 executed on the work station 1122, to perform an OCST-TC upload and/or execution control. The communication between the OCST controller 1150 and the DUT 1130, in order to perform OCST-TC upload and/or execution control, may, for example, use a high speed interface (e.g., USB, PCle, ETH, or any other appropriate high speed interface).

Similarly, the communication between the OCST controller 1150 and the work station 1122 or the ATE test program 1124, to perform or support or control OCST-TC upload and/or execution control may, for example, be performed using a high speed interface (e.g., USB, PCle, ETH, or any other appropriate interface). Accordingly, the OCST controller may support the on chip-system test. For example, by having a particularly good capability to perform high speed communication with the device under test, or with the OCST test case 1140, the OCST controller 1150 may perform the upload of an on-chip system test-test case to the device under test 1130 in a particularly fast manner, which helps to speed up the test. Moreover, the on-chip system test controller 1150 may also, for example, provide execution control information and/or execution control commands to the device under test 1130 or to the OCST test case 1140 via a high speed interface. Thus, the OCST controller can help to perform the OCST test in a fast and time-saving manner. However, the OCST controller 1140 may, for example, receive the OCST test case from the ATE test program which may, for example, control an overall test flow. Moreover, the ATE test program may also provide information about a desired overall test flow to the OCST controller 1150, such that the OCST controller 1150 may provide execution control information and/or execution control commands to the device under test 1130 or to the OCST test case 1140 on the basis thereof. Thus, the OCST test controller 1150 may act as an intermediator between the work station 1120 or the ATE test program 1124 on the one side and the DUT 1130 or the OCST test case 1140 on the other side.

Moreover, the OCST test controller 1150 may also act as an intermediator in the resource measurement procedure described herein. For example, the OCST controller may be configured to receive the resource measurement request 1160 from the OCST test case 1140 and forward this resource measurement request (which can also be considered as a resource measurement command or a resource measurement request message) to the work station 1120 or to the ATE test program 1124 (e.g. in the form of the resource measurement request 1170). The OCST controller may forward the resource measurement request in its original form and may, for example, only handle the communication protocol of the high speed interface between the OCST controller 1150 and the DUT 1130. However, the OCST controller 1150 may alternately also perform a translation of the resource measurement request, which can be considered as a “command translation”. Thus, the OCST controller 1150 may provide the resource measurement request 1170 such that the resource measurement request 1170 is a translated version of the resource measurement request 1160. For example, the OCST controller 1150 may perform such a command translation if this is appropriate in view of the specific interface or communication format between the OCST controller 1150 and the work station 1122.

Moreover, the OCST controller 1150 may forward the measurement result information 1172 provided by the work station 1122 or provided by the ATE test program 1124 to the DUT 1130 or to the OCST test case 1140 in an unchanged manner, wherein the OCST controller 1150 may, for example, take over the protocol handling for the high speed interface between the OCST controller 1150 and the device under test 1130. However, the OCST controller 1150 may also generate the measurement result 1162 on the basis of measurement result information 1172 received from the work station 1122 or from the ATE test program 1124.

To conclude, the OCST controller may act as a “simple intermediator” that merely forwards the resource measurement request 1160 from the OCST test case 1140 to the ATE test program 1124 without amendments and which forwards the measurement result 1172 from the ATE test program 1124 to the OCST test case 1140 without amendments and only handles the high speed communication protocol. Alternatively, however, the OCST controller may also comprise an extended functionality, which may comprise, for example, a command translation and/or a measurement result message translation or a measurement result message generation (in addition to the protocol handling).

Accordingly, the OCST test case 1140 which is executed on the device under test 1130 can provide a command requesting a measurement of one or more physical quantities (e.g. the resource measurement request 1160) and can receive a measurement result signaling 1162. The OCST controller 1152 acts as an intermediator and takes over a protocol handling for a high-speed communication between the automated testing equipment 1110 and the device under test 1130. The OCST controller 1150 is also in communication with the ATE test program 1124 and forwards the resource measurement request 1060 to the ATE test program 1124 in an original form or in a translated form. Moreover, the OCST controller 1150 also acts as an intermediator for the measurement result signaling from the ATE test program 1124 to the OCST test case 1140. In addition, the OCST controller optionally also takes over functionalities in the OCST test case upload and/or execution control, wherein, for example, the same physical interface between the OCST controller 1150 and the device under test 1130 may be used for the OCST test case upload and/or execution control on the one hand and for the transmission of the resource measurement request 1160 and of the measurement result signaling 1162 on the other hand. Accordingly, the high-speed interface between the OCST controller 1150 and the device under test 1130 can be used in a particularly advantageous manner for multiple purposes.

Moreover, it should be noted that, regarding the fundamental functionality of the concept, reference is also made to the description of FIG. 10.

In addition, it should be noted that the test arrange 1100 may optionally be supplemented by any of the features, functionalities and details described herein, both individually and taken in combination. Moreover, it should be noted that both the automated test equipment 1110 and the device under test 1130 described herein should be considered as embodiments of the present invention.

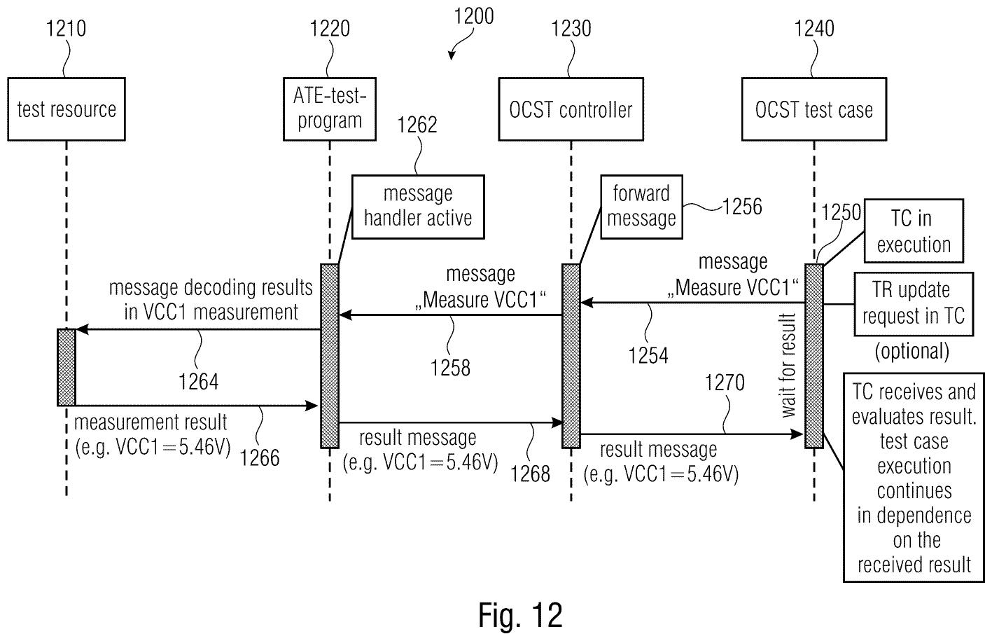

### 13. Test Flow According to FIG. 12

FIG. 12 shows a schematic representation of a test flow 1200, according to an embodiment of the present invention. The test flow may, for example, be executed in the test arrangement 1100.

FIG. 12 shows a communication or message flow that involves a tester resource 1210 (which may, for example, correspond to the tester resource 1120), an ATE test program 1220 (which may, for example, correspond to the ATE test program 1124), an OCST controller 1230 (which may, for example, correspond to the OCST controller 1150) and an OCST test case 1240 (which may, for example, correspond to the OCST test case 1140). As can be seen, the OCST test case is in execution, as shown at the reference numeral 1250. The OCST test case sends a message 1254 requesting a measurement of a physical quantity, for example a message “Measure VCC1” to the OCST controller 1230. The OCST controller 1230 comprise a message forwarding functionality 1256. In the example, the OCST controller 1230 forwards this message, for example in the form or a message 1258, to the ATE test program 1220. For example, the message 1258 still comprises the command “Measure VCC1”. The ATE test program 1202 comprises a message handler 1262 which is active and which evaluates the message 1258 received from the OCST controller.

The message handler 1262 may, for example, perform a message decoding of the message 1258 and may consequently provide a message (or command) 1264 to the test resource 1210, wherein said command 1264 effects the requested measurement of a physical quantity. For example, the message or command 1264 may be in the form of a (physical) hardware command causing the test resources 1210 to make the desired measurement. Accordingly, the ATE test program 1220 receives a measurement result information 1266 (for example, a measurement result message) from the test resource 1210. The measurement results information 1266 may, for example, indicate a certain value of the physical quantity (e.g. VCC1 to be measured). However, it should be noted that the ATE test program 1220 may, for example, actively read the measurement result information 1266 from the tester resource 1210. Alternatively, the measurement resource 1210 may also provide the measurement result information 1266 to the ATE test program 1220 in the form of a measurement result message. The ATE test program 1220 may consequently generate a result message 1268, which indicates the value of the physical quantity to be measured, and provide this measurement result message to OCST controller 1230. The OCST controller 1230 may, for example, forward the measurement result message 1268 to the OCST test case in the form of a measurement result message 1270. However, it should be noted that the OCST controller 1230 may optionally comprise a functionality to translate the message 1268 into the message 1270, e.g. by modifying a syntax. Subsequently, the OCST test case 1240 may receive and evaluate the measurement result message 1270. For example, the OCST test case 1240 may parse the result message 1270 and extract the measurement result information from the measurement result message 1270. Furthermore, optionally, test case execution may continue in dependence on the received result (e.g. in dependence on the measurement result). However, alternatively, the OCST test case 1240 may simply store the measurement result and report it back to the automated test equipment later on (or used it for a test-case-sided determination of a test result).

To conclude, using the message flow of FIG. 12, the OCST test case can request the measurement of a physical quantity and the automated test equipment can exploit the protocol handling capabilities of the OCST controller 1230 to deal with this request. Thus, the measurement result can be signaled to the OCST test case 1240 in an efficient manner, and the OCST test case 1240 can make use of the test results.

Moreover, it should be noted that the message flow 1200 according to FIG. 12 may be used in any of the embodiments according to the invention, and that the message flow 1200 of FIG. 12 may optionally be supplemented by any of the features, functionalities and details described herein, both individually and when taken in combination.

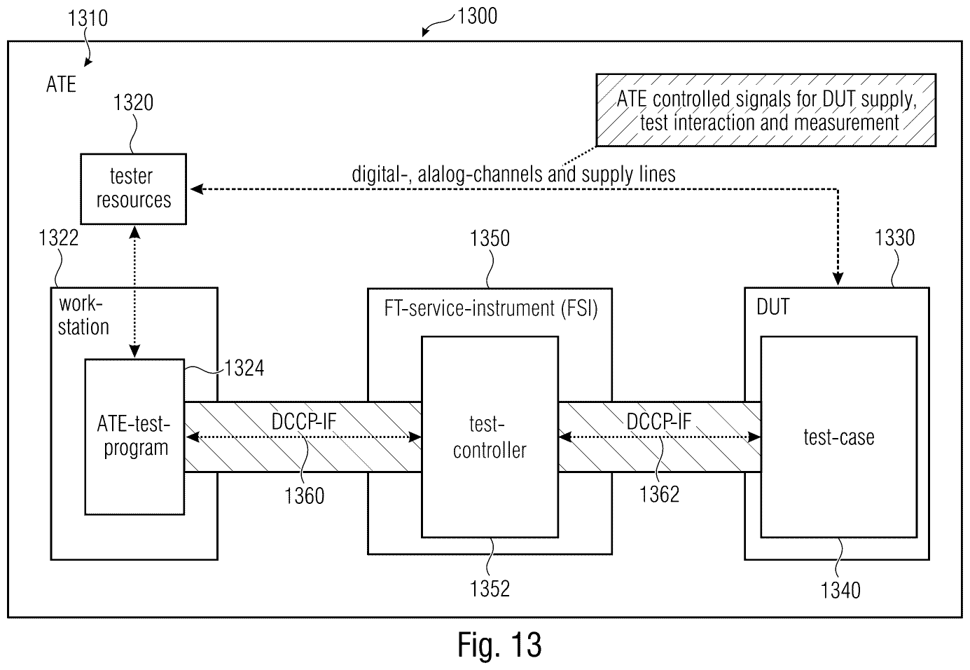

### 14. Test Arrangement According to FIG. 13

FIG. 13 shows a schematic representation of a test arrangement 1300, according to an embodiment of the invention. The test arrangement 1300 comprises an automated test equipment 1310, which may correspond to the other automated test equipment described herein. For example, the automated test equipment 1310 may comprise tester resources 1320 and the work station 1322 which may be configured to execute an ATE test program 1324. The automated test equipment 1310 may also comprise a so called “FT-service instrument 1350”, which may be a functional-test-case-service-instrument which may be a CPU supported hardware instance containing a DUT test controller. The test controller of the FT-service instrument 1350 is designated with 1352. For example, the test controller 1352 may be configured to communicate with the ATE test program 1324 using a so called “DCCP-IF”, which may be a data, control-, communication path interface. Furthermore, the test controller 1352 may also be configured to communicate with a test case 1340, which is executed on a device under test 1330, via a DCCP-interface, which is a data, control-, communication path interface.

Regarding the functionality of the test arrangement 1300, reference is made, for example, to the above discussion, wherein it should be noted that the automated test equipment 1310 may, for example correspond to the automated test equipment 810 or to the automated test equipment 1110. Moreover, it should be noted, that the FT-service instrument 1352 may, for example, correspond to the OCST controller 826 or to the OCST controller 1150. The DCCP-interface 1360 may, for example, take the functionality of the interfaces between the OCST controller 826 and the ATE program 824, and the DCCP-interface 1362 may, for example, take the role of the interfaces between the OCST controller 826 and the OCST test case 832.

As can be seen from FIG. 13, it may, for example, be sufficient to have a single DCCP-interface 1362 between the test controller 1352 and the test case 1340, wherein said single DCCP-interface 1362 may, for example, be used for the OCST-test case upload and/or execution control and also for the transmission of a resource update request (e.g., 850) and of an acknowledge signaling (e.g., 852). Similarly, a single DCCP-interface 1360 may be sufficient between the test controller 1352 and the ATE test program 1324. For example, this single DCCP-interface 1360 may be used for the OCST-test case upload and/or execution control and may also be used for the transmission of a resource update request (e.g., 860) from the test controller 1352 to the ATE test program 1324 and for the transmission of an acknowledge signaling (e.g., 862) from the ATE test program 1324 to the test controller 1352.

To conclude, FIG. 13 shows a test arrangement 1300, where the functional test case 1340 is fully located on the device under test 1330. The DCCP-interface to the test controller 1352 is realized, for example, by a physical interface like HSIO PCle or USB.

However, it should be noted that the test arrangement 1300 may optionally be supplemented by any of the features, functionalities and details disclosed herein, both individually and taken in combination. Moreover, it should be noted that both the automated test equipment 1310 and the device under test 1330 may be considered as embodiments according to the invention.

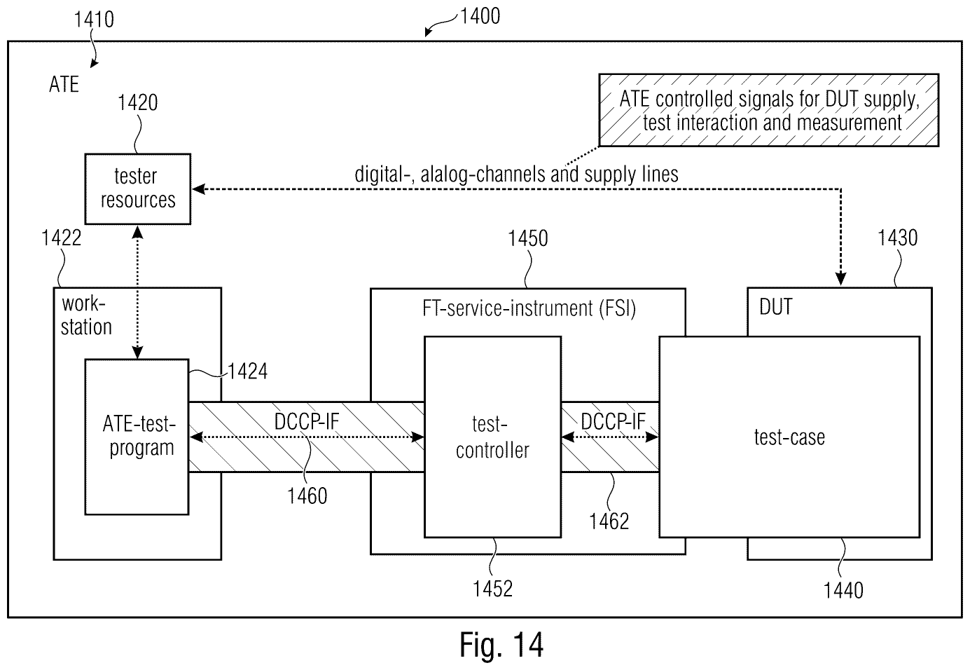

### 15. Test Arrangement According to FIG. 14

FIG. 14 shows a schematic representation of a test arrangement 1400, according to an embodiment of the present invention. The test arrangement 1400 comprises an automated test equipment 1410, which may be similar to the test arrangement 1300, such that reference is made to the above discussion. The test arrangement 1400 also comprises a device under test 1430, which is similar to the device under test 1330 such that reference is made to the above explanations.

The automated test equipment 1410 comprises test resources 1420, which are similar to the test resources 1320, and the automated test equipment 1410 also comprises a work station 1422, which is similar to the work station 1322. Accordingly, reference is made to the above description. For example, an ATE test program 1424 is executed on the work station 1422, wherein the test program 1424 may be similar or identical to the test program 1324 that is executed on the work station 1322. Moreover, the automated test equipment 1410 comprises a functional-test-case-service instrument 1450 which is also designated as FT-service-instrument (FSI). The functional-test-case-service-instrument 1450 may, for example, correspond to the functional-test-case-service-instrument 1350 and may, for example, take over the functionality of an on-chip-system-test controller (e.g., of the on-chip-system-test controller 826).

However, in the test arrangement 1400 according to FIG. 14, the test case 1440 is distributed between the device under test 1430 and the functional-test-case-service-instrument 1450. For example, a part of the test case may be executed on the functional-test-case-service-instrument 1450, and another part of the test case may be executed on the device under test 1430. Just as an example, the functional-test-case-service-instrument 1450 may comprise a hardware component which is in close communication with the device under test 1430 and which may, for example, take the place of a hardware that should be coupled to the device under test 1430 in a real-world environment.

According to an aspect, there may be a DCCP-interface 1462 between the test case 1440 and the test controller 1452 of the functional-test-case-service-instrument 1450. Accordingly, the DCCP-interface 1462 may, for example, allow for the OCST-test case upload and/or execution control and may also handle the transmission of a resource update request (e.g., 850) and the transmission of an acknowledgment signaling (e.g., 852). Moreover, there is also a DCCP-interface 1460 between the test controller 1452 and the ATE test program 1424.

To conclude, in the test arrangement 1400 according to FIG. 14, the functional test case is logically split into a DUT- and FSI-part. The DCCP-interface between test controller and test case is, for example, realized by software executed on the FSI. The software to handle the physical connection of the FSI and the DUT is, for example, located inside the test case.

Moreover, it should be noted that the test arrangement 1400 according to FIG. 14 may optionally be supplemented by any of the features, functionalities and details described herein, both individually and taken in combination.

Moreover, it should be noted that the ATE 1410 and the device under test 1430 may both be considered as embodiments according to the invention.

To conclude, FIG. 14 shows an extension that handles a further interface topology for the communication with the test case. According to an aspect, there may be an integration of the DUT interface control inside the test case. However, an integration of the DUT interface control inside the test case also lies within the scope of the invention.

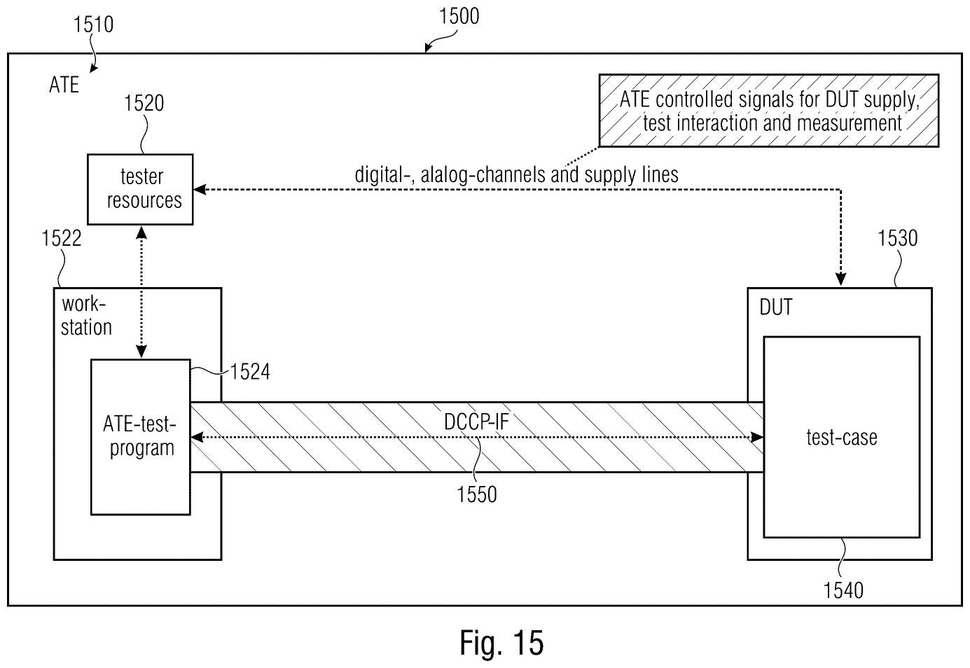

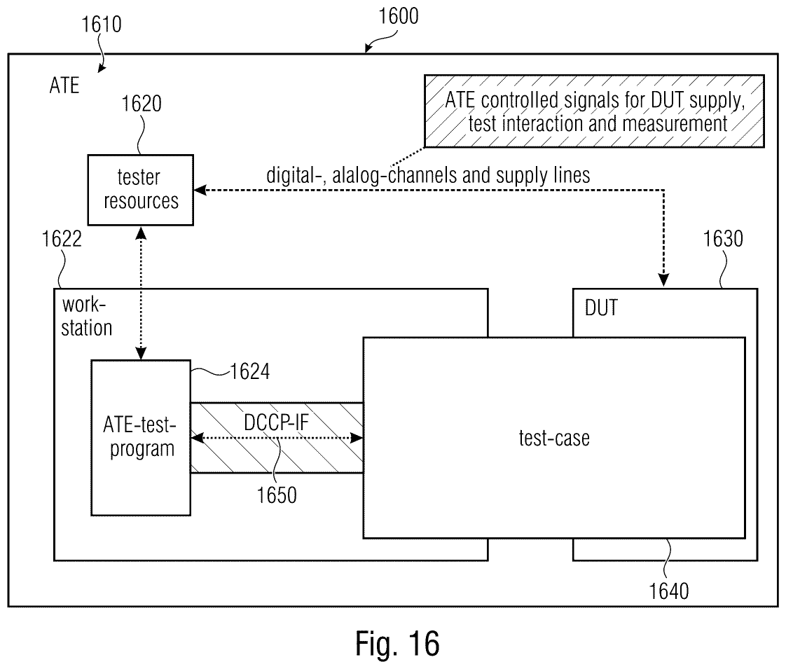

### 16. Test Arrangement According to FIG. 15

FIG. 15 shows a schematic representation of a test arrangement 1500, according to an embodiment of the present invention. The test arrangement 1500 comprises an automated test equipment 1510 and a device under test 1530. The automated test equipment 1510 comprises test resources 1520 and a work station 1522, wherein an ATE test program 1524 is executed on the work station 1522. Moreover, a test case 1540 is executed on the device under test.

Regarding the automated test equipment, reference is made, for example, to the test arrangement 700 according to FIG. 7, which comprises a similar functionality. For example, the automated test equipment 1510 may correspond to the automated test equipment 710, and the device under test 1530 may correspond to the device under test 730. As can be seen in FIG. 15, there is a DCCP-interface 1550 between the ATE test program 1524 and the test case 1540. For example, the DCCP-interface 1550 may be used for the OCST-test case upload and/or execution control, which has been explained with reference to FIG. 7, and the DCCP-interface 1550 may also be used for a resource update request (e.g., 750) and for an acknowledge signaling (e.g., 752). Thus, for example, the single DCCP-interface 1550 may be used for multiple purposes.

Moreover, it should be noted that the functionality of the test arrangement 1500 may be similar to the functionality of the test arrangement 700, such that reference is also made to the above explanations.

To conclude, in the test arrangement 1500 according to FIG. 15, the functional test case is fully located on the device under test. The DCCP-interface to the ATE test program is realized, for example, by a physical interface like HSIO PCle or USB.

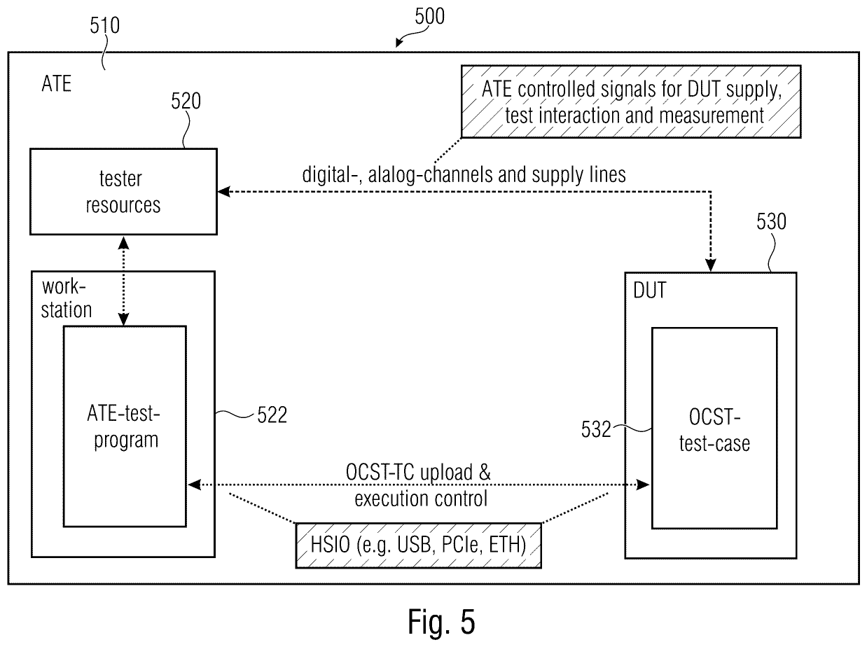

Moreover, it should be noted that the test arrangement 1500 according to FIG. 5 may optionally be supplemented by any of the features, functionalities and details disclosed herein, both individually and taken in combination. Moreover, it should be noted that the ATE 1510 and the DUT 1530 may both be considered as embodiments according to the present invention.

### 17. Test Arrangement According to FIG. 16

FIG. 16 shows a schematic representation of a test arrangement, according to an embodiment of the present invention. The test arrangement 1600 according to FIG. 16 comprises an automated test equipment 1610 and a device under test 1630. The automated test equipment 1610 may, for example, correspond to the automated test equipment 1510 according to FIG. 15. The automated test equipment 1610 comprises test resources 1620 which may, for example, correspond to the test resources 1520, and the automated test equipment 1610 also comprises a work station 1622, which may, for example, correspond to the work station 1522. An automated test equipment test program 1624 is executed on the work station 1622.

However, a test case 1640 is distributed between the work station 1622 and the device under test 1630. Thus, the functional test may, for example, be logically split into a DUT- and a work station part (e.g., into a DUT part which is executed on the device under test 1630 and a work station part which is executed on the work station 1622). The DCCP-interface between the two parts is, for example, realized by software executed on the work station 1622. The software to handle the physical connection of the work station and the DUT is, for example, located inside the test case 1640.

Moreover, it should be noted that the DCCP-interface 1650 between the ATE test program 1624 and the test case 1640 may, for example, comprise a functionality which is comparable to the functionality of the DCCP-interface 1550. For example, the DCCP interface 1650 may be used for the OCST test case upload and/or execution control (e.g., as described with respect to FIG. 5), and the DCCP-interface 1650 may also be used for a transmission of a resource update request (e.g., 750) and an acknowledge signaling (e.g., 752).

Moreover, it should be noted that the test arrangement 600 may optionally be supplemented by any of the features, functionalities and details described herein, both individually and taken in combination.

Moreover, it should be noted that the automated test equipment 1610 and the device under test 1630 may be considered as embodiments according to the invention.

To conclude, FIG. 16 shows an extension that handles a further interface topology for the communication with the test case. According to an aspect, there may be an integration of the DUT interface control inside the test case. However, an integration of the DUT interface control inside the test case also lies within the scope of the invention.

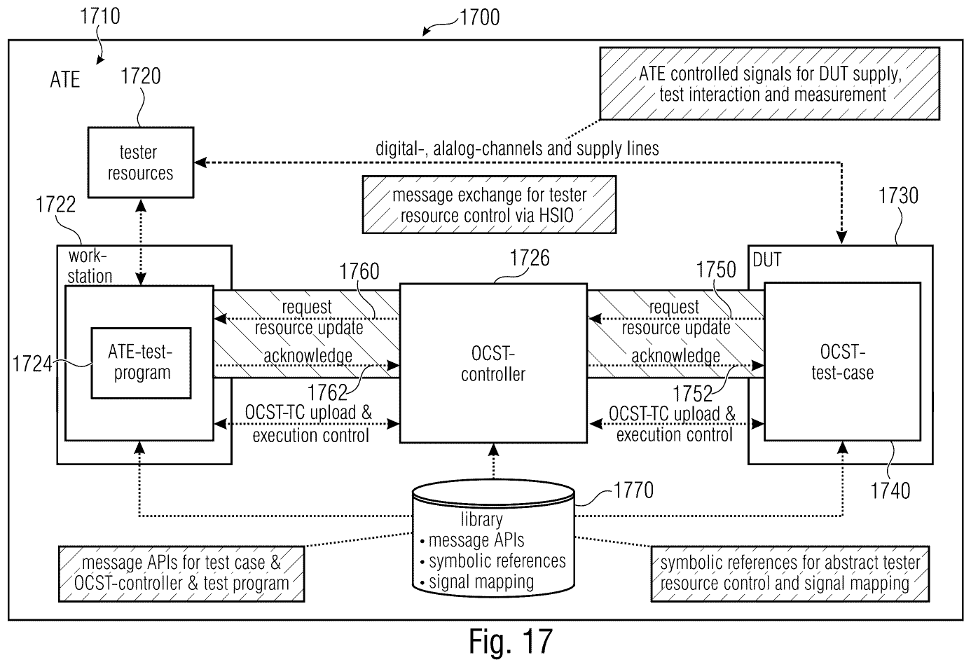

### 18. Test Arrangement According to the FIG. 17

FIG. 17 shows a schematic representation of a test arrangement 1700, according to an embodiment of the present invention.

The test arrangement 1700 comprises an automated test equipment 1710, which may, for example, correspond to the automated test equipment 810. For example, the automated test equipment 1710 may comprise tester resources 1720 which may, for example, correspond to the tester resources 820. Moreover, the test arrangement 1710 may comprise a work station 1722, which may correspond to the work station 822. Furthermore, the test arrangement 1710 may comprise an OCST controller 1726 which may, for example, correspond to the OCST controller 826. Moreover, the test arrangement 1700 comprises a device under test 1730 which may, for example, correspond to the device under test 830.

However, the test arrangement 1700 also comprises a library 1770 which may, for example, be part of the automated test equipment 1710. The library may, for example, comprise one or more message application-programming-interfaces (APIs). Moreover, the library 1770 may, for example, comprise one or more symbolic references. In addition, the library 1770 may optionally comprise a signal mapping.

For example, the message APIs may define calls to library procedures or library functions. For example, the message APIs may define a syntax for the call of a procedure or function for usage in the development of an OCST test case (e.g. in the form of function headers or method headers or function interfaces or method interfaces). Moreover, the library may optionally also include an implementation (e.g., in a pre-compiled form, or in the form of a source code) of said functions or methods. For example, the functions or methods defined by the APIs of the library 1770 may define the generation (and transmission) of a resource update request message. Just as an example, a message API may define a function or method, a call of which results in the generation of a message that serves to request a resource update of a tester resource. Such a function or method may, for example, define to generate a message in an appropriate syntax and to transmit such a message via a high speed interface to the OCST controller 1726, or to the ATE test program 1724. Accordingly, a developer of an OCST test case only needs to include a function call or method call as defined in the library 1770 into the source code of the OCST test case and can then generate the executable code of the OCST test case (e.g., using an appropriate representation of an implementation of said procedures or functions defined in the message APIs).

To conclude, one of the functions or methods defined in the library 1770 may define a generation (and also a transmission) of a resource update request message, and another method or function defined in the library may define a detection whether the acknowledge signaling has arrived at the device under test or may define a waiting for the reception of the acknowledge signaling at the device under test.

Alternatively or in addition, one of the functions or methods defined in the library may define a generation (and also a transmission) of a resource measurement request message, and another function or method defined in the library may define an evaluation of a measurement result signaling.

The library 1770 may, optionally, also comprise a representation of symbolic references, wherein said symbolic references may be symbolic references for abstract test resource control and signal mapping. For example, the library 1770 may comprise symbolic references for typically used signal names, like, for example, VCC1, VCC2, VCC3, fCLK1, fCLK2, etc. Thus, the symbolic references in the library may be user friendly names of signals, or signal characteristics, that can easily be understood by a verification engineer who designs a test for a certain device under test.

Moreover, the library 1770 may optionally comprise a signal mapping which may, for example, define a mapping of symbolic references onto actual physical signals provided by the automated test equipment 1710.

Moreover, it should be noted that the library 1770 may not only comprise message APIs for a test case but may comprise message APIs for test case and/or OCST-controller and/or test program. For example, the library 1770 may comprise message APIs which can be used in the design of a program to be executed on the OCST controller 1726, and which may, for example, define functions or methods for an evaluation of resource update request messages and/or for the generation of an acknowledge message. Moreover, the message APIs included in the library 1770 may also define function or methods which can be included into the ATE test program 1724 and which may, for example, evaluate resource update request messages or generate acknowledge messages. Thus, the message APIs included in the library 1770 may support a development of an OCST-test case and may also support a development of an ATE test program. Furthermore, the message APIs included in the library 1770 may also support the development of a software to be executed on the OCST controller 1726.

Moreover, the symbolic references may, for example, help the developer of an OCST test case, since the symbolic references may, for example, define signals and/or quantities in a device-related manner (e.g., closely related to the naming of respective signals in a device specification or in a device data sheet).

Moreover, the signal mapping may, for example, be used in the generation of a program to be executed on the OCST controller 1726 or in the development of the ATE test program 1724, and may also be used in the OCST controller 1726 or in the ATE test program 1724 at run time. For example, a signal mapping defined in the library 1726 may be used by the OCST controller 1726 or by the ATE test program 1724 to translate the symbolic references and may be used, for example, for translating messages from the OCST test case (that may, for example, include symbolic references included into resource update request messages) into commands referring to specific physical tester resources.

Just as an example, the ATE test program 1725 may translate the symbolic reference “VCC1”, that may be included in a resource update request message, into a physical identifier (e.g., a bus address) of a certain device power supply (e.g., device power supply 1). It should be noted that the symbolic references may, for example, be independent from the actual physical configuration of the automated test equipment and may rather be related to the naming conventions of the device under test. Thus, the signal mapping may, for example, define the “translation rule” from DUT-related symbolic references to actual physical tester resources.

To conclude, the library 1770 significantly facilitates the development of OCST test cases and also of ATE test programs. Moreover, the usage of symbolic references and of a signal mapping reduces the error risk for the developer of the OCST test case and furthermore allows for porting of a test to ATEs of different hardware configurations with small effort.

Moreover, it should be noted that the library 1770 described here may optionally be introduced into any of the other test arrangements and automated test equipment disclosed herein. Moreover, it should be noted that the test arrangement 1700 may optionally be supplemented by any of the features, functionalities and details disclosed herein, both individually and taken in combination.

Moreover, it should be noted that both the ATE 1710 and the device under test 1730 may be considered as embodiments according to the invention.

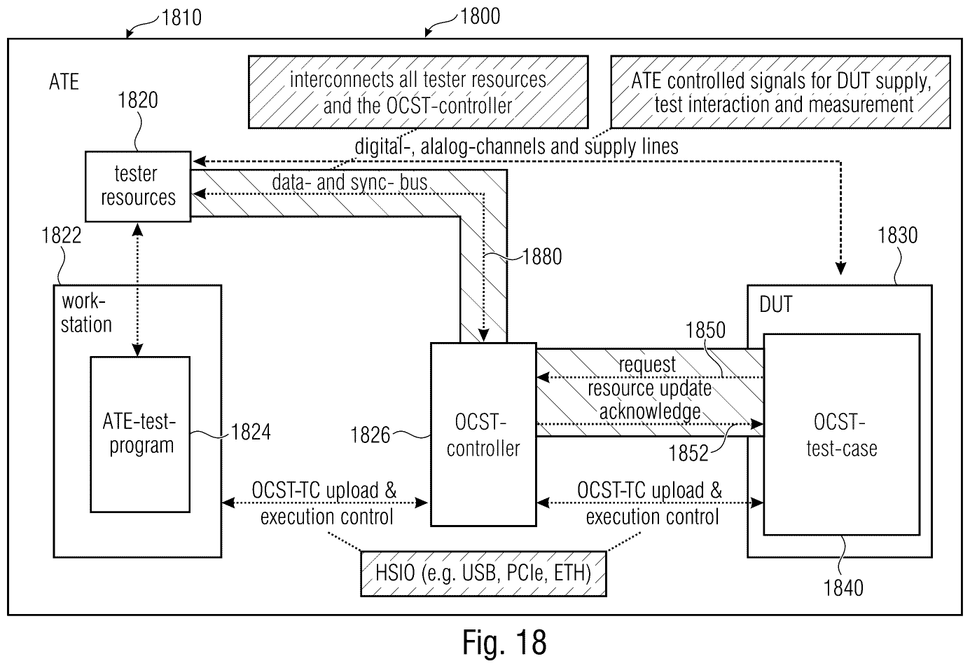

### 19. Test Arrangement 1800 According to FIG. 18

FIG. 18 shows a schematic representation of a test arrangement 1800 according to an embodiment of the present invention. The test arrangement 1800 comprises an automated test equipment 1810 and a device under test 1830. The automated test equipment comprises test resources 1820 and a work station 1822 on which a test program 1824 is executed. Moreover, the automated test equipment 1810 also comprises an OCST controller 1826. The device under test 1830 is typically configured to execute an OCST test case 1840.

Regarding the automated test equipment 1810 it should be noted that the test resources 1820 may be similar, for example, to the test resources 820 described above. However, it should be noted that the tester resources 1820 are also (directed) coupled to the OCST controller which may, for example, be similar to the OCST controller 826.

However, it should be noted that the OCST controller 1826 is configured to receive a resource update request (for example, in the form of a message) 1850 from the OCST test case 1840 and to provide an acknowledge signaling (for example, in the form of a message) 1852 to the OCST test case. However, the OCST controller 1826 is directly coupled to the one or more tester resources 1820, for example via a data- and synchronization-bus 1880. Accordingly, the OCST controller 1826 may directly (e.g., in a manner bypassing the workstation 1822) cause a response to the resource update request 1850. For example, the OCST controller 1826 may, in response to a resource update request (or resource update request message) 1850 access one or more test resources 1820 via the data- and synchronization-bus 1880 (which typically, but not necessarily, interconnects all tester resources 1820 and the OCST controller 1826). Accordingly, in response to the resource update request 1850, the OCST controller 1826 may directly (e.g., in a manner bypassing the work station 1822) instruct a certain tester resource indicated in the resource update request massage 1850 to update its characteristic.

For example, the OCST controller 1826 may transmit an instruction or command causing a certain tester resource 1820 (for example, a device power supply or a clock signal generator or the like) to change its parameter to a new parameter specified by the OCST controller 1826 in accordance with the resource update request 1850. For example, the OCST controller 1826 may write one or more data words onto a data bus which directly connects the OCST controller 1826 with one or more test resources 1820, and the OCST controller 1826 may, for example, address a desired tester resource 1820 in such a data bus access. For example, the transmission of one or more appropriate data words via the data bus 1880 may directly cause the specified (or addressed) tester resource to update its characteristics (e.g., a voltage provided by the device power supply, or a clock frequency of a clock signal provided by a clock signal generator). However, in some implementations, the one or more data words communicated from the OCST controller 1826 to the specified tester resource via the data bus 1880 may merely define a new parameter for the specified tester resource, which only becomes active in response to a synchronization event. For example, the OCST controller may consequently trigger the actual update of the characteristic of the tester resource by communicating a synchronization event to the specified tester resource 1820 (or to all tester resources 1820) via the synchronization bus. However, as another alternative, the OCST controller may communicate such a synchronization to the specified tester resource via a dedicated trigger line. For example, the activation of a synchronization line (not shown in FIG. 18) may cause a specified tester resource coupled to this synchronization line to take over a new setting (which could be considered as an update of the tester resource).

To conclude, by having a direct coupling between the OCST controller 1826 and the tester resources 1820 (e.g. via the data-and-sync-bus 1880, or using a data connection and (optionally) a synchronization mechanism, like one or more dedicated synchronization lines or trigger lines), the OCST controller 1826 can effect an update of one or more tester resources with very low latency. For example, the OCST controller 1826, which is typically configured to establish a high speed communication with the OCST test case 1840 using a high speed interface, can react very fast to a resource update request message from the OCST test case, and can directly instruct one or more test resources to perform the requested resource update. Accordingly, it is no longer necessary to rely on the handling of the resource update request by the work station 1822 or by the ATE test program 1824, such that latencies can be avoided. Moreover, an interruption of the ATE test program 1824 can also be avoided using the concept to give the OCST controller direct access to the one or more tester resources. Accordingly, a fast and efficient testing of the device under test can be achieved.

Moreover, it should be noted that the test arrangement 1800 may optionally be supplemented by any of the features, functionalities and details disclosed herein, both individually and taken in combination.

Moreover, it should be noted that both the automated test equipment 1810 and the device under test 1830 may be considered as embodiments according to the invention.

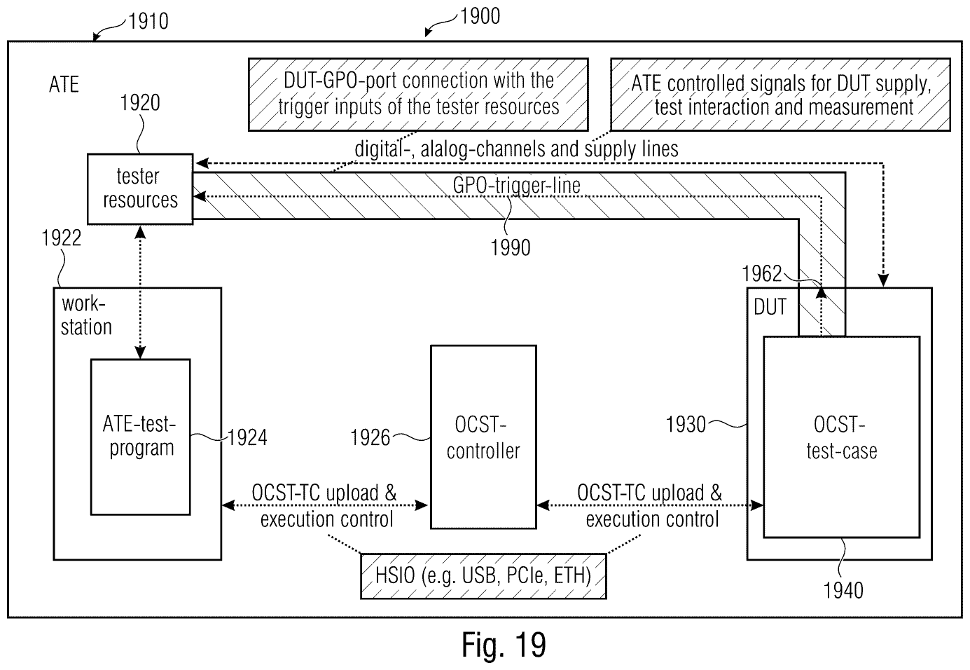

### 20. Test Arrangement According to FIG. 19

FIG. 19 shows a schematic representation of a test arrangement 1900, according to an embodiment of the present invention. The test arrangement 1900 comprises an automated test equipment 1910 and a device under test 1930. The automated test equipment comprises tester resources 1920, which may, for example, be similar to the tester resources 820, 1820. Moreover, the automated test equipment 1910 also comprises a work station 1922, wherein an ATE test program 1924 may be executed on the work station 1922. The work station 1922 may, for example, be similar to the work station 822 or to the work station 1822, such that the above explanations also apply. Moreover, the automated test equipment 1910 comprises an OCST controller 1926, which may, for example, be similar to the OCST controller 826 or to the OCST controller 1826.

However, one or more of the tester resources may be configured to receive a trigger signaling from a GPO trigger line 1990. For example, the automated test equipment 1910 may be configured to make the GPO trigger line accessible at a DUT interface. For example, the GPO trigger line may be coupled to a general purpose output 1942 of the device under test 1930 (e.g. via a load board which is in between the DUT interface of the automated test equipment and the device under test 1930). For example, the general purpose output pin 1942 of the device under test 1930 may be controlled by the test case 1940 which is executed on the device under test. Accordingly, the OCST test case 1940 can trigger an update of the test resources, for example by an activation of the GPO-trigger line 1990. Consequently, it is possible for the OCST test case 1940 to effect an update of one or more tester resources 1920 in a manner which requires a minimum hardware and software effort. In principle, a single pin of the device under test 1930 (e.g. a general purpose output pin, or any other output pin, or input/output pin) which is otherwise unused in the test arrangement and which can be programed with reasonable effort by the OCST test case 1940, can be used to trigger the tester resource update.

Moreover, it should be noted that the one or more tester resources, which will be updated in response to the activation of the GPO trigger line 1990, may, for example, be pre-programmed by the ATE test program 1924. For example, the ATE test program 1924 may provide a specific tester resource 1920 with an instruction which indicates a new state to be taken in response to an activation of a GPO-trigger-line (e.g. in response to an activation of an associated GPO-trigger-line). In other words, the ATE test program may, for example, be in a coarse temporal synchronism with the execution of the OCST test case 1940 on the device under test 1930 and may therefore be capable to anticipate which resource update will be requested by the OCST test case 1940 with the next activation of the GPO trigger line 1990. Accordingly, the ATE test program may preconfigure the specific tester resource, characteristics of which are to be updated next, by providing the specific tester resource with information regarding the upcoming desired characteristics. Subsequently, the specific tester resource 1920 may perform an update, in order to use the preconfigured characteristics, in response to the activation of the GPO-trigger-line 1990 by the OCST test case. Accordingly, the ATE test program 1920 may, for example, define the new value to which the specific tester resource 1920 will updated, and the OCST test case 1940 decides, by an activation of the GPO-trigger-line 1990, a precise timing at which the update of the tester resource to the new characteristic (or new value) should be made. In such a scenario, the time at which the pre-configuration takes place is relatively uncritical, while the reaction to the activation to the GPO trigger line typically occurs within a well-defined period of time (e.g. with a very high timing accuracy). Thus, the OCST test 1940 has a very high control over the timing of the tester resource update, while a very simple communication mechanism, namely a single GPO-trigger-line, may be sufficient to actually effect the update of the tester resource.

However, in some embodiments, the OCST test case 1940 may also be able to communicate the desired new characteristics (or the desired new setting) of the one or more tester resources to be updated. For example, the OCST test case 1940 may use a protocol-based high speed interface for this purpose, wherein the communication may, for example extend from the OCST test case 1920 towards the OCST controller and from the OCST controller to the ATE test program, and from the ATE test program to the tester resources. Alternatively, however, such a communication may also extend from the OCST test case 1940 to the OCST controller 1926, and from the OCST controller 1926 directly to the tester resources 1920, such that the OCST controller may directly pre-program the tester resources 1920 for the desired update of their characteristics, bypassing the ATE test program 1924.

To conclude, by providing the automated test equipment with the functionality to receive a trigger signaling, which triggers an update of one or more tester resources, from a device under test, it can be achieved that the device under test, which may be a system-on-the-chip, has a very precise timing control over an update of tester resources. This helps to allow for a very fast execution of an OCST test case which is executed on the device under test, since the latency is very low. Also, complex variations of the test environment can be defined in such a manner, like, for example, a temporary drop of a supply voltage or a spike on a supply voltage, under control of the OCST test case and in very precise timing relationship to the OCST test case.

However, it should be noted that the test arrangement 1900 may optionally be supplemented by any of the features, functionalities and details described herein. Moreover, it should be noted that both the automated test equipment 1910 and the device under test 1930 may be considered as embodiments according to the invention.

### 20. Further Embodiments and Aspects

Generally speaking, embodiments according to the here described innovation explain an ATE integrated solution to extend the on-chip-system-test capabilities via a path to control the ATE tester resources (TRs).

### 20.1. Tester Resources

Tester resources are, for example, hardware (HW) modules installed in the automated test equipment (ATE) used to provide the electrical environment, stimulus generation and signal evaluation of the DUT (device-under-test) during test execution. Typical test modules cover, for example, the areas power supply, digital-, mixed signal- and RF-IO with features to apply and measure test specific patterns and test signals.

### 20.2. Comparison Between Legacy and New TR Control Path

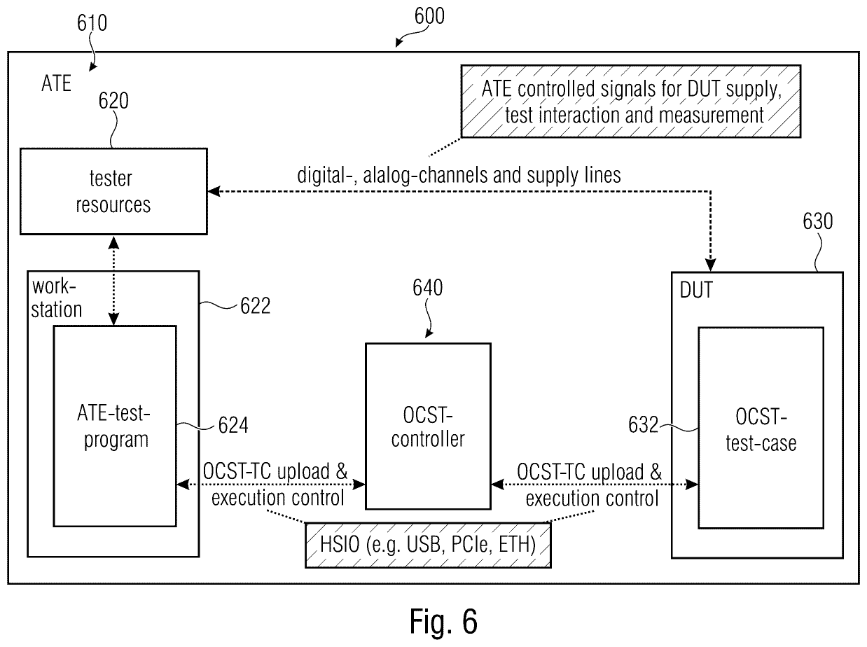

Tester resources are traditionally controlled by the ATE test program which is, for example, executed on the ATE work station (see, for example, FIG. 5 and FIG. 6). Any ATE environmental update is (e.g. conventionally) initiated by the test program, environmental updates by the OCST-test-case are not foreseen.

In this respect, a test case may, for example, be defined in a manner that a test case is a functional OCST-test-case to be executed as imbedded software (SW) on a device under test (DUT). Moreover, a test program is, for example, defined in that a test program is a ATE specific program executed on a work station to control the test.

However, it has been found that the missing interconnection of the OCST-test-case to control the ATE environment limits the usability of the OCST development a lot.

According to an aspect of the invention, the here proposed solution compensates this drawback by a new control path from the OCST-test-case to the ATE-test-program based on communication channels (see, for example, FIGS. 7 and 8). A new control path is realized, for example, by a software approach and uses messages which can be exchanged between a test-case and the test-program. The related message calls are, for example provided by an API and can, for example, be placed at any code line inside the test case.

As mentioned above, FIG. 7 shows a schematic representation of an OCST extended by a tester resource control path (wherein the tester resource control path may, for example, allow the transmission of the resource update request message 750 and of the acknowledgement message 752).

Moreover, FIG. 8 shows a schematic representation of a variant including a OCST controller to include a tester resource control path. For example, the tester resource control path may allow for the transmission of the resource update request message 850, 860 and for the transmission of the acknowledge message 862, 852.

These functionalities may optionally be included into any of the embodiments disclosed herein, both individually and taken in combination.

### 20.3. Message Based Tester Resource Control Flow

According to an aspect of the invention, ATE environment configurations can now additionally be controlled by the OCST-test-case, for example by sending a specific parametrized message to the ATE-test-program. For example, a message handler inside the test program interprets the message and executes tester resource updates in dependence on the message parameter. After completion of the resource update, an acknowledge message is sent to the waiting DUT, which continues the test case execution then.

FIG. 9 shows a schematic representation of message flow for tester resource control. In the following, the tester resource update flow will be briefly outlined.

### Tester Resource Update Flow

1. The OCST-test-case uses an API message call during execution to request a resource update and enters a wait loop until reception of a resource update acknowledge message.

2. The message is propagated via the OCST-controller to the ATE-test-program and interpreted by the message handler.

3. The tester resources are updated in dependence on the decoded message parameter.

4. An acknowledge message is propagated via the OCST-controller to the OCST-test-case on successful tester resource update for synchronization purpose.

5. The OCST-test-case continues execution after reception of the acknowledge message.

These functionalities may optionally be included into any of the embodiments disclosed herein, both individually and taken in combination.

### 20.4. Message Based Tester Resource Measurement Flow

According to an aspect of the invention, besides control of the tester resources the message interface can also (alternatively or in addition) be used to trigger resource measurements by the OCST-test-case. This is, for example, useful to execute the OCST-test-case in dependence on ATE specific environment conditions, like level of supply voltage or environment temperature.

For example, FIG. 10 shows a schematic representation of a OCST extended by a tester resource measurement path. For example, the tester resource measurement path may allow for a transmission of the resource measurement request message 1050 and of the measurement result message 1052.

Moreover, FIG. 11 shows a schematic representation of a variant including OCST-controller to include a tester resource control path. In this case, the tester resource control path may, for example, allow for the forwarding of the resource measurement request message 1160, 1170 and for the transmission of the measurement result message 1172, 1162.

For example, the OCST-test-case can trigger the ATE resource specific measurements by sending parametrized measurement messages (e.g. messages 1160) to the ATE-test-program (e.g. to the ATE-test-program 1124). A message handler inside the test program (e.g. within the ATE-test-program 1124) may, for example interpret the measurement message parameter (e.g. a parameter indicating that a voltage VCC1 should be measured) and it triggers the identified tester resource (e.g. a tester resource which is capable to measure the physical voltage designated by the symbolic reference VCC1) to execute a measurement. The result of the resource measurement is then, for example, sent back to the waiting DUT 1130, which, for example, continues the test case in dependence on the received result value (e.g. a result value indicating that VCC1 takes a certain value like, for example, 5.46 V).

FIG. 12 shows a schematic representation of a message flow for a tester resource measurement.

In the following, an example of the tester resource measurement flow will be described.

### Tester Resource Measurement Flow

1. The OCST-test-case uses, for example, an API message call during execution to request a resource measurement (e.g. message 1254) and, for example, enters a wait loop until reception of the measurement result message (e.g. message 1270).

2. The message (e.g. message 1254) is propagated, for example via the OCST controller, to the ATE-test-program (e.g. ATE-test-program 1220) and interpreted by the message handler (e.g. by a message handler which is part of the ATE-test-program).

3. The tester resource (e.g. tester resource 1210) executes a measurement in dependence on the decoded message parameter (e.g. in dependence on the parameter VCC1 which indicates that a certain voltage should be measured).

4. The measurement value is propagated via the OCST controller to the OCST test case (e.g. using messages 1260, 1270).

5. The OCST-test-case (e.g. OCST-test-case 1240) continues the execution, for example, in dependence on the received result (e.g. in dependence on the result described by the result message 1270).

These functionalities may optionally be included into any of the embodiments disclosed herein, both individually and taken in combination.

### 20.5. Logical Deployment of the Test-Case and the Required Control and Communication Interfaces for Different Test Typologies

In the following, the logical deployment of the test case and the required control and communication interfaces will be described for different tester typologies.

In the following, some definitions will be provided. For example, tester resources are hardware (HW) modules installed in the ATE used to provide, for example, the electrical environment, and/or stimulus generation and/or signal evaluation of the DUT during test execution. Typically tester modules cover for example, the areas power supply, digital-, mixed signal- and/or RF-IO, for example with features to apply and measure test specific patterns and test signals.

The work station typically executes the ATE-test-program and controls the tester resources. The test-program is, for example, controlling in dependence on the test-typology either the test-controller or directly the test-case via the DCCP-interface. It is, for example, additionally listening to the incoming communication messages from the test controller or test-case via the DCCP-IF. For example, the work station may be directly coupled to the device under test, or the OCST controller may act as an intermediator between the work station and the device under test.

The FT-service instrument (or functional test-case-service-instrument) is, for example, a CPU supported hardware (HW) instance containing the DUT test controller (e.g. the OCST controller).

The test controller (or OCST controller) handles, for example, the upload process of the DUT test case, controls the test case execution and collects execution result information.

The test case is, for example, the functional test code executed on the processor system of the DUT. It can, for example, contain software (SW) parts to handle the physical interface part to the FT-service-instrument or work station. For example, the test case may comprise a driver software to allow the test case to communicate with the work station or with the OCST controller via a high-speed interface (e.g. as described above). However, the driver software does not necessarily need to be part of the test case, but could, for example, also be part of an operating system which is running on the device under test.

The DCCP-interface (DCCP-IF) is, for example, a data, control-, communication path interface (DCCP-IF) used for
Test case upload and/or control, and/or
communication path between test-program and test case for e.g. tester resource updates and/or measurements.

The DCCP-interface may, for example, be one of the above-mentioned high-speed interfaces.

The DUT is, for example, a device under test containing a processor system for the execution of functional tests.

The DUT is, for example, a device under test containing a processor system for the execution of functional tests.

FIGS. 13-16 show different test arrangements.

FIG. 13 shows a test arrangement in which the functional test case 1340 is fully located on the device under test 1330. The DCCP-IF 1362 to the test controller is, for example, realized by a physical interface like HSIO PCle or USB.

FIG. 14 shows a test arrangement in which the functional test case 1440 is logically split into a DUT and FSI part. The DCCP-interface 1462 between the test controller 1452 and the test case 1440 is, for example, realized by software (SW) executed on the FSI. The software to handle the physical connection of the FSI and the DUT is, for example, located inside the test case.

FIG. 15 shows a test arrangement in which the test case 1540 is fully located on the device under test 1530. The DCCP-IF 1550 to the ATE-test-program 1524 is realized, for example, by a physical interface like HSIO PCle or USB.

FIG. 16 shows a test arrangement in which the functional test 1640 is logically split into DUT- and a work station-part. The DCCP-interface between the two parts is, for example, realized by software executed on the work station. The software to handle the physical connection of the work station 1622 and the DUT 1630 is, for example, located inside the test case 1640.

These functionalities may optionally be included into any of the embodiments disclosed herein, both individually and taken in combination.

### 20.6. Advantages in Enabling the ATE Environment Control by an OCST Test Case

### 20.6.1 Resource Control can be Synchronized to the Execution of the Test Case.

According to an aspect of the invention, tester resource updates during the test case execution is now possible. The updates can, for example, happen at any code line of the test case program and not only before the execution of the test case. In contrast, a legacy approach did not allow to vary test resources during test case execution.

### 20.6.2 Tester Resources are Configurable by Test Case Parameter

According to an aspect of the invention, the parameters of a test case call can be used to initiate tester resource updates. This extends the variation and flexibility of a test case.

20.6.3 OCST Test-Case Development without ATE Expert Support

Use case specific test cases are developed in general by a verification engineer because he knows the internals of the DUT. But, conventionally, for the execution of the OCST-test-cases in a specific ATE-environment, further ATE test program adaptations by a test engineer are needed.

A single OCST requires up to now (e.g. conventionally):
Development efforts to align test-program and test case.
A verification-engineer and a test-engineer to generate the OCST-test-case and ATE-test-program.

It has been found that the efforts to develop an OCST can be reduced significantly by the here described solution to move the ATE environment control from the test program into the OCST test case. For example, a unique test-program is used by all OCST-test-cases and may be required to setup an ATE-environment for guaranteed safe DUT startup. Further test-case specific ATE-environment updates are controlled now (e.g. according to an aspect of the invention) by the OCST test case itself. Accordingly, the verification engineer becomes independent from the test engineer because he can now control the ATE environment and execute the test cases on his own. The development of an on-chip-system-test is now, for example, limited to OCST test case.

### 20.6.4 ATE Environment Control and OCST Test Case Sequence is in One Source

According to an aspect of the invention, there are no dependencies between the ATE test program and the OCST test case anymore. In some embodiments according to the invention, tester resource control and test case development is now located in one test case source file.

However, it should be noted that, for example, an initialization of tester resources may still be provided in the ATE test program. Also, there may, in some case, be at least coarse temporal synchronization between the ATE test program and the test case.

### 20.6.5 ATE Independent OCST Test Case Development Possible

According to an aspect of the invention, no knowledge of the ATE environment for the test case development is needed. The tester resources are, for example, accessed by the verification engineer by (or using) abstract symbolic signal references, target values and/or mode settings in the form of one or more message parameters. The parameter interpretation and resulting test specific programming sequence of the tester resources is, for example, executed by the message handler in the ATE test program.

### 20.6.6 No Hardware (HW) Adaptation Needed

According to an aspect of the invention, the tester resource update concept is based on a pure software approach. In some cases, no hardware adaptations on the ATE are needed in order to implement concepts according to the present invention.

However, it should be noted that one or more of the above mentioned advantages may, for example, be present in embodiments according to the invention.

### 21. Libraries to Support ATE Environment Control

In the following, a usage of libraries to support ATE environment control will be described, according to an (optional) aspect of the invention. T

These functionalities may optionally be included into any of the embodiments disclosed herein, both individually and taken in combination.

For example, FIG. 17 shows a schematic representation of libraries to support ATE environmental control (e.g. in the context of a test arrangement).

### 21.1. Message APIs to Support Different DUTs

The API for ATE environment control uses, for example, predefine methods for message exchange with ATE test program. To cover the DUT-specific interfaces (e.g. USB and/or PCle) and to adapt to the different DUT processor core types (e.g. ARM, Atmel, Microchip . . . ) a library with different versions of the message API may, for example be prepared.

For example, the library may comprise application programing interfaces for a transmission of one or more types of messages (for example, resource update request messages or resource measurement request messages) via different types of interfaces (e.g. via different types of high speed interfaces). Moreover, the library may comprise implementations for said functions or method predefined in the message APIs, which are adapted for a usage with different types of DUT processor cores.

Accordingly, a verification engineer may, for example, generate a test case making use of one or more appropriate message APIs and making use of predefined implementations (e.g. in the form of pre-complied code that can be included into the test case using a linker) which are provided in the library for different types of DUT process cores and for different types of (high-speed) interfaces to be used. Accordingly, a development of an OCST test case is very simple for the verification engineer since he does not need to care about the specific implementation of a function or method for requesting a resource update or for requesting a resource measurement, but merely needs to make use of a predefined message API that is provided in the library 1770.

### 21.2 Symbolic References to Identify Resource and Channel

According to an aspect of the invention, properties, modes and signals of the tester resource are selected by the parameters of the messages and represented as symbolic references. For example, the test case developer can use those references to control, for example, all kinds of signals applied to the DUT, e.g. to control the DUT supply environment. For example, a message handler in the ATE test program uses the symbolic references to identify the tester resources and/or tester channels and/or operating modes to execute the requested action by predefined resource specific sequences.

In the following, a simple example will be provided.

In this example, the supply voltage VCC2 should be set to 5V.

An exemplary API-call may take the following form: Message (“VCC2”, 5V)

The message handler identifies the parameter “VCC2” as a supply module specific test resource, e.g. by searching the symbolic reference “VCC2” in the mapping table. The voltage setting of “VCC2” is executed by a predefined supply module programming sequence including the parameters target voltage “5V” and resource channel “10103”.

### Exemplary Mapping Table

| Symbolic Reference | Tester Resource | Resource Channel |
|---|---|---|
| VCC1 | Supply Module | 10102 |
| VCC2 | Supply Module | 10103 |
| GPO1 | Digital Channel | 20101 |
| . . . | . . . | . . . |

To conclude, the mapping table may, for example, define the “signal mapping” and may, for example, be included in the library. For example, the mapping table may map a symbolic reference of a signal or quantity to physical resource identifiers identifying a specific tester resource. Accordingly, the mapping table may vary if the hardware configuration of the automated test equipment is changed (e.g., by removing tester resource modules or by adding tester resource modules). Thus, the OCST test case can use the symbolic references, and the symbolic references are then translated into references to physical tester resources, for example using the mapping table, for example, by the ATE-test-program (or, alternatively, by the OCST controller).

### 22. Further Variations of the ATE-Environment Controlled by an OCST

In the following, further optional variations of an ATE-environment controlled by an OCST will be described, according to embodiments according to the invention.

### 22.1. Tester Resource Control by Synchronization Bus Events

According to an aspect of the invention, all test resources (or at least some of the test resources) and the OCST controller are interconnected by a data-and-synchronization-bus. The bus-system is used to exchange data and to send synchronization events between the bus members. For example, a tester resource update is initiated by a message sent from the OCST-test-case to the OCST-controller. The OCST-controller initializes the selected tester resource in dependence of the message parameter by a data bus configuration sequence and activates the new settings, for example, by a dedicated synchronization bus event.

FIG. 18 shows a schematic representation of a tester resource controller by a data-and-synchronization bus.

In the following, an example of a test resource update flow will be described.

1: The OCST test case (e.g., OCST case 1840) requests to update a tester resource by a message (e.g., a message 1850) sent to the OCST controller (e.g., OCST controller 1826) and, for example, enters a loop to wait on the message (e.g., message 1852) to acknowledge the update.

2: The OCST controller (e.g., OCST controller 1826) configures the selected tester resource (e.g., out of test resources 1820) in dependence of the message parameter (e.g., included in the resource update request message 1850) and activates the new setting, for example, via a dedicated trigger signal on the synchronization bus (e.g., on the data-and-synchronization bus 1880).

3: An acknowledge message (e.g., acknowledge message 1852) is sent back to the OCST test case to flag (or signal) the succeeded update. For example, the test case leaves the acknowledge-wait-loop (ACK-wait-loop) and continues processing.

It should be noted that this embodiment according to the invention may optionally be supplemented by any of the features, functionalities and details disclose herein, both individually and taken in combination.

Also, any of these functionalities may optionally be included into any of the embodiments disclosed herein, both individually and taken in combination.

### 22.2. Tester Resource Control by GPO Trigger

According to an aspect of the invention, the GPO-ports (e.g., general purpose output ports) of the DUT are interconnected with the tester resources and used as trigger lines to activate preconfigured resource configurations. Just as an example, it may be sufficient that a single general purpose output port (or general purpose output pin) of the DUT is interconnected with a tester resource and used as a trigger line. However, it is also possible that a plurality of general purpose output ports or general purpose output pins of the DUT are interconnected with test resources and used as trigger lines.

This allows the OCST test case to update the test resources by setting the relevant GPO line (or, equivalently, by setting a general purpose output port or general purpose output pin of the device under test to a predetermined state, e.g., an active state).

A minor drawback is that the test program and the test case are not independent in some cases, because the intended configuration may need to be prepared by the ATE test program before execution of the OCST-test-case. The approach is therefore, in some cases, inflexible with respect to dynamic resource updates. Also, in some cases, only one configuration per GPO line can be supported and hardware modifications to route the GPO-lines to the tester resources are required.

However, it should be noted that these minor drawbacks may optionally be overcome, for example, by providing the OCST-test-case with the possibility to communicate a desired resource update to the automated test equipment before activation of the trigger line, such that the automated test equipment may, for example, prepare the intended update configuration under the control of the OCST-test-case. Moreover, by dynamically changing the update configuration that is used in response to an activation of a certain GPO line (or trigger line), a good functionality with a very high timing accuracy can be achieved.

Moreover, the hardware modifications to route the GPO lines to the tester resources are minor in some cases.

As an example, FIG. 19 shows a schematic representation of a tester resource control by GPO-trigger.

In the following, the example of a test resource update flow will be described.

1: The ATE test program (e.g., ATE test program 1924) initializes the target configuration of the respective tester resource (e.g., out of test resources 1920).

2: The OCST test case (e.g., OCST test case 1940) requests a tester resource update by GPO line activation (e.g., by the activation of the GPO trigger line 1940).

3: The preconfigured tester resource settings (e.g., as preconfigured in step 1) are activated by the detection of the GPO-trigger event (wherein, for example, the detection of the GPO-trigger event takes place in a tester resource).

Moreover, it should be noted that this embodiment according to the present invention may optionally be supplemented by any of the features, functionalities and details described herein, both individually and taken in combination.

### 23. Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

In the following, additional embodiments and aspects of the invention will be described which can be used individually or in combination with any of the features and functionalities and details described herein.

A first aspect relates to a device under test 242;260;1930, wherein the device under test is configured to provide to an automated test equipment 240;280;1910 a trigger signal 262;294;1942, to thereby trigger an update of one or more tester resources 288a,288b,288c;1920, via a dedicated trigger line 250;295;1990.

According to a second aspect when referring back to the first aspect, the device under test is configured to provide a command 266;296 defining one or more parameters for the update of the one or more tester resources 288a,288b,288c;1920 to the automated test equipment 240;280;1910, and wherein the device under test is configured to provide the trigger signal 262;294;1942, to thereby trigger an update of one or more tester resources using the one or more parameters.

A third aspect relates to a test setup 1900, wherein the test setup comprises an automated test equipment 240;280;1910 for testing a device under test 242;260;1930, wherein the automated test equipment comprises a trigger line 250;295;1990 which is controllable by the device under test 242;260;1930, wherein the automated test equipment is configured update one or more tester resources 288a,288b,288c; 1920 in response to an activation of the trigger line by the device under test; and a device under test 242;260;1930 according to aspect 1.

A fourth aspect relates to a method for operating an automated test equipment 240;280;1910, which comprises a trigger line 250;295;1990 that is controllable by a device under test 242;260;1930, wherein the method comprises updating one or more tester resources 288a,288b,288c;1920 in response to an activation of the trigger line 250;295;1990 by the device under test.

A fifth aspect relates to a method for testing a device under test 242;260;1930, wherein the method comprises pre-programming one or more tester resources 288a,288b,288c;1920 to one or more respective parameter values, which are to be taken over in response to a trigger signal 262;294;1942, using a test program executor 282;1922; providing a trigger signal 262;294;1942, which causes the one or more tester resources to take over the pre-programmed one or more respective parameter values, directly from the device under test 242;260;1930 to one or more tester resources.

A sixth aspect relates to a computer program for performing the method of aspect 4 or the method of aspect 5, when the computer program runs on one or more computers and/or on one or more microprocessors and/or on one or more microcontrollers.

A seventh aspect relates to a method for operating an automated test equipment 240;280;1990, which comprises a trigger line 250; 295; 1990 that is controllable by a test case 262;19940, wherein the method comprises updating one or more tester resources 288a,288b,288c;1920 in response to an activation of the trigger line by the test case.

An eighth aspect relates to a method for testing a device under test 242;260;1930, wherein the method comprises pre-programming one or more tester resources 288a,288b,288c; 1920 to one or more respective parameter values, which are to be taken over in response to a trigger signal 262;294;1942, using a test program executor 282;1922; providing a trigger signal, which causes the one or more tester resources to take over the pre-programmed one or more respective parameter values, directly from a test case 262;1940 to one or more tester resources.

A ninth aspect relates to a computer program for performing the method of aspect 7 or the method of aspect 8, when the computer program runs on one or more computers and/or on one or more microprocessors and/or on one or more microcontrollers.

1-20. (canceled)

21. An automated test equipment for testing a device under test, the automated test equipment comprising:
a controller;
one or more tester resources coupled with the controller; and
a trigger line which is controllable by the device under test, and
wherein the one or more tester resources are configured to perform an update in response to an activation of the trigger line.

22. The automated test equipment according to claim 21, further comprising:
a test program executor operable to execute a test program; and
wherein the activation of the trigger line directly triggers an update of one or more of the one or more tester resources, bypassing the test program executor executing the test program.

23. The automated test equipment according to claim 21, further comprising:
a test program executor operable to execute a test program; and
wherein an interface couples the one or more tester resources to the test program executor, wherein the interface allows for a programming of one or more characteristics of the one or more tester resources under the control of the test program;
wherein the one or more tester resources are coupled to the trigger line which is controllable by the device under test, and
wherein the one or more tester resources are configured to update a signal characteristic in a manner, which has been pre-programmed under the control of the test program, in response to an activation of the trigger line by the device under test.

24. The automated test equipment according to claim 21, further comprising:
a test program executor configured to pre-program one or more of the one or more tester resources to pre-define a response of the one or more tester resources to the activation of the trigger line by the device under test.

25. The automated test equipment according to claim 24,
wherein the test program executor is configured to pre-program one or more of the one or more tester resources, in accordance with one or more instructions provided in a test program, to pre-define the response of the one or more tester resources to the activation of the trigger line by the device under test.

26. The automated test equipment according to claim 21,
wherein the controller is further configured to receive, from the device under test, a command defining one or more parameters for an update of the one or more tester resources, and
wherein the controller is further configured to pre-program one or more of the one or more tester resources, in accordance with the command received from the device under test, to pre-define a response of the one or more tester resources to the activation of the trigger line by the device under test.

27. The automated test equipment according to claim 21,
wherein the one or more tester resources comprise a trigger mechanism configured to update a signal characteristic in response to the activation of the trigger line by the device under test.

28. The automated test equipment according to claim 21, further comprising:
a test program executor; and
a device-under-test interface; and
wherein the controller comprises an on-chip-system-test controller, and
wherein further the trigger line is a hardware line extending directly from the device-under-test interface of the automated test equipment to one or more of the one or more tester resources, bypassing the on-chip-system-test controller and the test program executor.

29. The automated test equipment according to claim 21,
wherein the one or more tester resources comprise one or more out of the following:
a device power supply;
signal generator module; and
a channel module.

30. The automated test equipment according to claim 28,
wherein an interface couples the one or more tester resources to the test program executor.

31. The automated test equipment according to claim 28,
wherein the one or more tester resources are physically separated from the test program executor.

32. A device under test, comprising:
a processor,
a controller; and
an interface;
wherein the controller is configured to provide a trigger signal to an automated test equipment, to trigger an update of one or more tester resources, via a dedicated trigger line.

33. The device under test according to claim 32, wherein the one or more tester resources comprise one or more out of the following:
a device power supply;
signal generator module; and
a channel module.

34. The device under test according to claim 32,
wherein the controller is further configured to provide the trigger signal under control of a test case which is executed by the processor.

35. An automated test equipment for testing a device under test, the automated test equipment comprising:
a controller;
one or more tester resources coupled with the controller; and
a trigger line which is controllable by a test case, and
wherein the one or more tester resources are configured to perform an update in response to an activation of the trigger line.

36. The automated test equipment according to claim 35, wherein the one or more tester resources comprise one or more out of the following:
a device power supply;
signal generator module; and
a channel module.

37. The automated test equipment according to claim 35,
wherein the controller is further configured to receive, from the test case, a command defining one or more parameters for an update of the one or more tester resources, and
wherein the controller is further configured to pre-program one or more of the one or more tester resources, in accordance with the command received from the test case, to pre-define a response of the one or more tester resources to the activation of the trigger line by the test case.

38. The automated test equipment according to claim 35,
wherein the one or more tester resources comprise a trigger mechanism configured to update a signal characteristic in response to the activation of the trigger line by the test case.

39. The automated test equipment according to claim 35, further comprising:
a test program executor; and
a device-under-test interface; and
wherein the controller comprises an on-chip-system-test controller, and
wherein further the trigger line is a hardware line extending directly from the device-under-test interface of the automated test equipment to one or more of the one or more tester resources, bypassing the on-chip-system-test controller and the test program executor.

40. The automated test equipment according to claim 39,
wherein an interface couples the one or more tester resources to the test program executor.
